(19) United States
(12) Patent Application Publication
(10) Pub. No.: US 2010/0085813 A1
(43) Pub. Date: Apr. 8, 2010

(54) METHOD OF DRIVING A SEMICONDUCTOR MEMORY DEVICE AND A SEMICONDUCTOR MEMORY DEVICE

(75) Inventor: Tomoaki Shino, Kanagawa-Ken (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: KABUSHIKI KAISHA TOSHIBA, Tokyo (JP)

(21) Appl. No.: 12/598,866

(22) PCT Filed: Jun. 25, 2008
(86) PCT No.: PCT/JP08/61940

§ 371 Date: Nov. 4, 2009

(30) Foreign Application Priority Data
Jun. 29, 2007 (JP) 2007-172682
May 23, 2008 (JP) 2008-135671

(51) Int. Cl. G11C 7/00; H01L 29/68; G11C 16/26; G11C 16/10; G11C 16/04

(52) U.S. Cl. 365/185.21; 257/348; 365/185.18; 365/185.23; 257/E29.17

(57) ABSTRACT

This disclosure concerns a driving method of a memory having cells of floating body type which comprises executing, during a write operation, a first cycle of applying a first potential to the bit lines corresponding to the first selected cells and of applying a second potential to the selected word line to write first data; executing, during the write operation, a second cycle of applying a third potential to the bit lines corresponding to a second selected cell among the first selected memory cells and of applying a fourth potential to the selected word line to write second data, wherein the second potential is a potential biased to a reversed side against the polarity of the carriers with reference to potentials of the source and the first potential, and the fourth potential is a biased to same polarity as the polarity of the carriers with reference to the potentials of the source and the third potential.

### CROSS-REFERENCE TO RELATED APPLICATIONS

This application is based upon and claims the benefit of priority from the prior Japanese Patent Applications No. 2007-172682, filed on Jun. 29, 2007, and No. 2008-135671, filed on May 23, 2008, the entire contents of which are incorporated herein by reference.

### BACKGROUND OF THE INVENTION

1. Field of the Invention

The present invention relates to a method of driving a semiconductor memory device and a semiconductor memory device. For example, the present invention relates to a method of driving a memory device storing therein information by accumulating majority carriers in a floating body of each field effect transistor.

2. Related Art

In recent years, there is known an FBC memory device expected as a semiconductor memory device that replaces a 1T (Transistor)-1C (Capacitor) DRAM. The FBC memory device is configured so that FETs (Field Effect Transistors) each including a floating body (hereinafter, also “body”) are formed on an SOI (Silicon On Insulator) substrate, and so that data “1” or data “0” is stored according to the number of majority carriers accumulated in the body of each FET. It is assumed in an FBC constituted by an N-FET, for example, that a state in which the number of holes accumulated in the body is large is data “1” and a state in which the number of holes accumulated in the body is small is data “0”.

If the FBC memory cell is constituted by the N-FET, then a body potential is set lower than a potential of a source and a drain, that is, a pn-junction is reverse biased during data retention time. In other words, a state capable of accumulating more holes in the body is thereby kept during data retention time. Therefore, if holes are gradually accumulated in a “0” cell, a retention failure occurs that the “0” cell changes to a “1” cell.

Further, if data is written to a selected memory cell, opposite data stored in unselected memory cells that share a bit line with the selected memory cell is often deteriorated. This phenomenon is called “bit line disturbance”. For example, if data “1” is written to the selected memory cell, data stored in “0” cells sharing the bit line with the selected memory cell is deteriorated (bit line “1” disturbance”), and if data “0” is written to the selected memory cell, data stored in “1” cells sharing the bit line with the selected memory cell is deteriorated (bit line “0” disturbance“).

Generally, to make the signal difference between data “1” and data “0” sufficiently large, it is necessary to set an amplitude of a bit line potential (a difference between a bit line potential when data “1” is written and that when data “0” is written) high. However, if the amplitude of the bit line potential is set large, influence of the bit line disturbance increases. If the influence of the bit line disturbance is great, it is necessary to frequently perform a refresh operation for recovering from deterioration in memory cell data. This refresh operation may possibly disadvantageously hamper an ordinary read or write operation. Further, if the refresh operation is performed frequently, power consumption disadvantageously increases.

### SUMMARY OF THE INVENTION

A method of driving a semiconductor memory device according to an embodiment of the present invention, the semiconductor memory device includes a plurality of memory cells including sources, drains, and floating bodies in an electrically floating state, the memory cells storing logic data according to number of carriers accumulated in the floating body; a plurality of bit lines connected to the drains; a plurality of word lines intersecting the bit lines; and a sense amplifier reading data stored in a selected memory cell connected to a selected bit line among the plurality of bit lines and connected to a selected word line among the plurality of word lines, or the sense amplifier writing data to the selected memory cell, the method comprising:

executing, during a data write operation, a first cycle of applying a first potential to the bit lines corresponding to the first selected memory cells and of applying a second potential to the selected word line so as to write first logic data indicating that the number of the carriers is large to the first selected memory cells;

executing, during the data write operation, a second cycle of applying a third potential to the bit lines corresponding to a second selected memory cell selected by the bit lines among the first selected memory cells and of applying a fourth potential to the selected word line so as to write second logic data indicating that the number of the carriers is small to the second selected memory cell, wherein

in the first cycle, the second potential is a potential biased to a reversed polarity side as opposed to the polarity of the carriers with reference to a potential of the source and a potential of the first potential, and

in the second cycle, the fourth potential is a potential biased to same polarity as the polarity of the carriers with reference to the potential of the source and the potential of the third potential.

A semiconductor memory device according to an embodiment of the present invention comprises a supporting substrate; a semiconductor layer provided above the supporting substrate; a source layer provided in the semiconductor layer; a drain layer provided in the semiconductor layer; a body including a first body part provided in the semiconductor layer between the source layer and the drain layer and a second body part extending from the first body part in a direction perpendicular to the surface of the supporting substrate, the body being in an electrically floating state and accumulating charges in the body to store logic data or emitting the charges from the body; a gate dielectric film provided on a side surface of the second body part; and a gate electrode provided on the gate dielectric film.

A semiconductor memory device according to an embodiment of the present invention comprises a semiconductor substrate; a semiconductor layer provided above the semiconductor substrate; a source layer provided in the semiconductor layer; a drain layer provided in the semiconductor layer; a body including a first body part provided in the semiconductor layer between the source layer and the drain layer and a second body part extending from the first body part to a surface of the semiconductor substrate in a perpendicular direction, the body being in an electrically floating state and accumulating charges in the body to store logic data or emitting the charges from the body; a gate dielectric film provided on a side surface of the body part; a gate electrode provided to face the gate dielectric film; a plurality of memory cells each including the source layer, the drain layer, and the body; a plurality of bit lines extending in a first direction; and a plurality of isolations put between two semiconductor layers adjacent to each other in the first direction, wherein a distance between two isolations adjacent to each other in the first direction is equal to a width of the gate electrode in the first direction.

### BRIEF DESCRIPTION OF THE DRAWINGS

FIG. 1 is a schematic diagram showing an example of a configuration of an FBC memory device according to a first embodiment of the present invention;

FIG. 2 is a plan view showing a part of the memory cell array MCA; FIG. 3A is a cross-sectional view taken along a line A-A of FIG. 2;

FIG. 3B is a cross-sectional view taken along a line B-B of FIG. 2;

FIG. 3C is a cross-sectional view taken along a line C-C of FIG. 2;

FIGS. 4A and 4B are explanatory diagrams showing a data write operation according to the first embodiment;

FIG. 5 is a timing diagram of voltages applied to the memory cells MCs in the first and second cycles according to the first embodiment;

FIG. 6 is a graph showing the relationship between the bit line potential VBL1 in the first cycle and the drain current difference during the data-read operation according to the first embodiment;

FIG. 7 is a timing diagram of the first cycle and the second cycle at VBL1=VSL and VWL1=−4.2 V according to the first embodiment;

FIG. 8 is an explanatory diagram showing a method of driving an FBC memory device according to a second embodiment of the present invention;

FIG. 9 is a timing diagram of voltages applied to the memory cells MCs in the first and second cycles according to the second embodiment;

FIG. 10 is a graph showing the relationship between the first cycle write time Tw1 and the drain current difference during the data read operation according to the second embodiment;

FIG. 11 is a plan view showing arrangement of wirings in an FBC memory device according to a third embodiment of the present invention;

FIG. 12 is a plan view showing the bodies B in the FBC memory device according to the third embodiment;

FIGS. 13 to 16 are cross-sectional views taken along lines 13-13, 14-14, 15-15, and 16-16 of FIG. 12, respectively;

FIG. 17 is a graph showing body potentials of the “0” cell and the “1” cell of the conventional FBC memory device and those of the “0” cell and the “1” cell of the FBC memory device according to the third embodiment, respectively;

FIGS. 18 to 25 are cross sectional views showing a manufacturing method of a semiconductor memory device according to the third embodiment;

FIGS. 26A to 26C are plan views of an FBC memory device according to a fourth embodiment of the present invention;

FIGS. 27 to 29 are cross-sectional views taken along lines 27-27, 28-28, and 29-29 of FIG. 26, respectively;

FIGS. 30 to 35 are cross sectional views showing a manufacturing method of a semiconductor memory device according to the fourth embodiment;

FIGS. 36 to 39 are cross-sectional views of an FBC memory device according to a fifth embodiment of the present invention;

FIGS. 40 to 49 are cross sectional views showing a manufacturing method of a semiconductor memory device according to the fifth embodiment;

FIG. 50 is a plan view showing wiring arrangement of an FBC memory device according to a sixth embodiment of the present invention;

FIG. 51 is a plan view taken along a line 51-51 of FIG. 56;

FIG. 52 is a plan view taken along a line 52-52 of FIG. 56;

FIGS. 53 to 57 are cross-sectional views taken along lines 53-53, 54-54, 55-55, 56-56, and 57-57 of FIG. 51, respectively;

FIGS. 58 to 68 are cross sectional views showing a manufacturing method of a semiconductor memory device according to the sixth embodiment;

FIGS. 69 and 70 are plan views of an FBC memory device according to a seventh embodiment of the present invention;

FIGS. 71 to 74 are cross-sectional views taken along lines 71-71, 72-72, 73-73, and 74-74 of FIG. 70, respectively;

FIGS. 75 to 80 are cross sectional views showing a manufacturing method of a semiconductor memory device according to the seventh embodiment;

FIGS. 81A to 81C are cross-sectional views taken along lines A-A, B-B, and C-C of FIG. 80, respectively;

FIGS. 82 and 83 are cross-sectional views showing manufacturing steps subsequent to FIGS. 79 and 80, respectively;

FIGS. 84A to 84C are cross-sectional views taken along lines A-A, B-B, and C-C of FIG. 83, respectively;

FIG. 85 is a cross-sectional view of an FBC memory device according to an eighth embodiment of the present invention;

FIG. 86 is a cross sectional view showing a manufacturing method of a semiconductor memory device according to the eighth embodiment;

FIG. 87 is a plan view of an FBC memory device according to a ninth embodiment of the present invention;

FIG. 88 is a cross-sectional view taken along a line 88-88 of FIG. 87;

FIG. 89 is a graph showing the relationship between the first cycle write time Tw1 and the drain current difference during the data read operation according to the tenth embodiment;

FIG. 90 is a timing diagram showing an operation performed by an FBC memory device according to the eleventh embodiment of the present invention;

FIG. 91 is a bird's-eye view of an FBC memory device according to a twelfth embodiment of the present invention;

FIG. 92 is a plan view along the upper surface of the SOI layer 30;

FIG. 93 is a plan view along the bottom surface of the SOI layer 30;

FIGS. 94 to 98 are cross-sectional views taken along lines 94-94, 95-95, 96-96, 97-97, and 98-98 of FIG. 92, respectively;

FIGS. 99 to 106 are cross sectional views showing a manufacturing method of a semiconductor memory device according to the twelfth embodiment;

FIGS. 107 to 109 are cross-sectional views of an FBC memory device according to a modification of the thirteenth embodiment of the present invention;

FIGS. 110 to 111 are cross sectional views showing a manufacturing method of a semiconductor memory device according to the thirteenth embodiment;

FIG. 112 is a schematic diagram showing arrangement of wirings of memory cells MCs according to the fourteenth embodiment;

FIG. 113 is a plan view of the bodies B;

FIGS. 114 to 118 are cross-sectional views taken along lines 114-114, 115-115, 116-116, 117-117, and 118-118 of FIG. 113, respectively;

FIGS. 119 to 125 are cross sectional views showing a manufacturing method of a semiconductor memory device according to the fourteenth embodiment;

FIG. 126 is a schematic diagram showing arrangement of wirings of memory cells MCs according to the fifteenth embodiment;

FIG. 127 is a plan view of the bodies B;

FIGS. 128, 129, and 130 are cross-sectional views taken along lines 128-128, 129-129, and 130-130 of FIG. 127, respectively;

FIGS. 131A to 133C are cross sectional views showing a manufacturing method of a semiconductor memory device according to the fifteenth embodiment; and

FIGS. 134 and 135 are cross-sectional views showing a configuration of an FBC memory device according to a modification of the fifteenth embodiment.

### DETAILED DESCRIPTION OF THE INVENTION

Embodiments of the present invention will be explained below in detail with reference to the accompanying drawings. Note that the invention is not limited thereto.

### First Embodiment

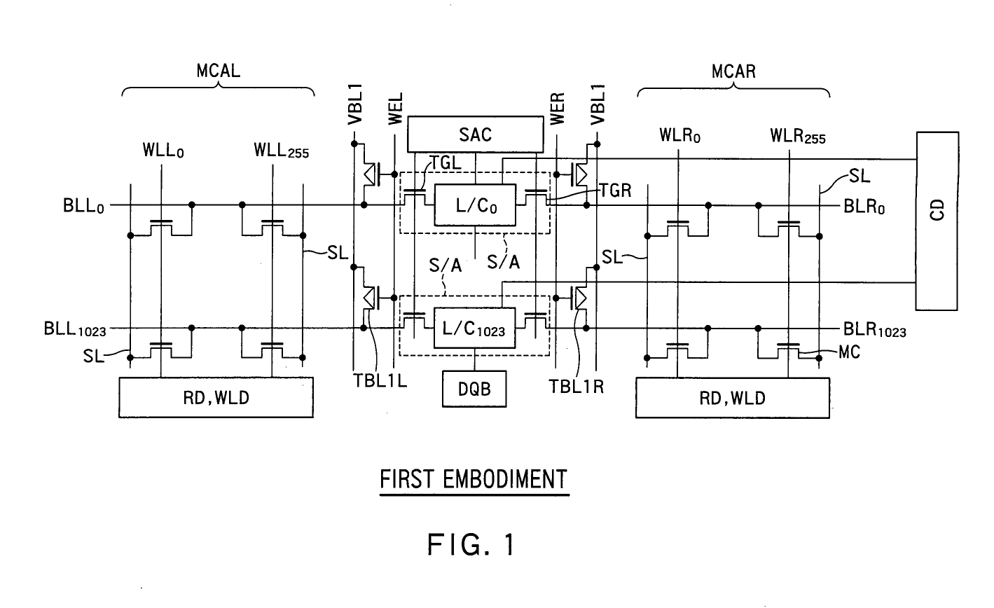

FIG. 1 is a schematic diagram showing an example of a configuration of an FBC memory device according to a first embodiment of the present invention. An FBC memory device 100 includes memory cells MCs, word lines WLL0 to WLL255 and WLR0 to WLR255 (hereinafter, also “WLs”, “WLL” or “WLR”), bit lines BLL0 to BLL1023 and BLR0 to BLR1023 (hereinafter, also “BLs”, “BLL” or “BLR”), sense amplifiers S/As, source lines SLs, a row decoder RD, a word line driver WLD, a column decoder CD, a sense amplifier controller SAC, and a DQ buffer DQB.

The memory cells MCs are two-dimensionally arranged in a matrix and constitute memory cell arrays MCAL and MCAR (hereinafter, also “MCAs”). Each of the word lines WLs extends in a row direction and is connected to a gate of each of the memory cells MCs. 256 word lines WLs are arranged on each of the left and the right of the sense amplifiers S/As. Each of the bit lines BLs extends in a column direction and is connected to a drain of each of the memory cells MCs. 1024 bit lines BLs are arranged on each of the left and the right of the sense amplifiers S/As. The word lines WLs are orthogonal to the bit lines BLs and the memory cells MCs are provided at crosspoints between the word lines WLs and the bit lines BLs, respectively. The memory cells MCs are, therefore, referred to as “crosspoint cells”. The row direction and the column direction can be replaced with each other. The source line SLs extends in parallel to the word lines WLs and is connected to a source of each of the memory cells MCs.

During a data-read operation, one of the two bit lines BLL and BLR connected to the left and right of the same sense amplifier S/A, respectively transmits data whereas the other bit line transmits a reference signal. The reference signal is generated by averaging signals of a plurality of dummy cells DCs. Accordingly, the sense amplifier S/A reads data from or writes data to a selected memory cell MC connected to a selected bit line BL and a selected word line WL. Each of the sense amplifiers S/As includes latch circuits L/C0 to L/C1023 (hereinafter, also “LCs”) and can temporarily store therein data of each memory cell MC.

Further, the FBC memory device also includes p transistors TBL1L and TBL1R connected between a bit line potential VBL1 for writing data “1” and the bit lines BLs. The transistors TBL1L and TBL1R are provided to correspond to the bit lines BLs. Gates of the transistors TBL1L and TBL1R are connected to write-enable signals WEL and WER, respectively. The write-enable signals WEL and WER are signals activated when data “1” is written.

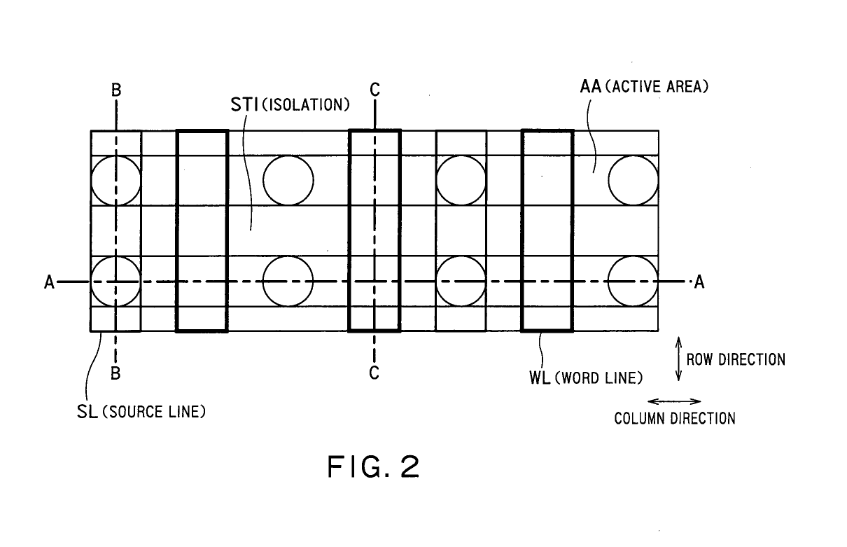

FIG. 2 is a plan view showing a part of the memory cell array MCA. A plurality of active areas AAs extends in the form of stripes in the column direction. An element isolation region STI (Shallow Trench Isolation) is formed between the adjacent active areas AAs. The memory cells MCs are formed in each active area AA.

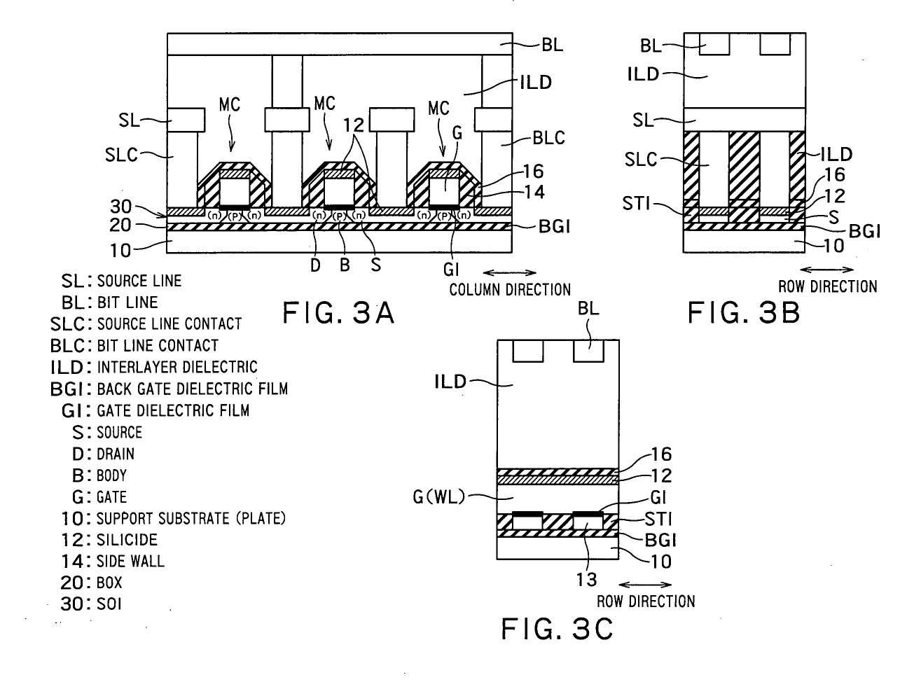

FIG. 3A is a cross-sectional view taken along a line A-A of FIG. 2. FIG. 3B is a cross-sectional view taken along a line B-B of FIG. 2. FIG. 3C is a cross-sectional view taken along a line C-C of FIG. 2. The memory cells MCs are formed on an SOI structure that includes a supporting substrate 10, a BOX (Buried Oxide) layer 20 provided on the supporting substrate 10, and an SOI layer 30 provided on the BOX layer 20.

The BOX layer 20 functions as a back gate dielectric film BGI shown in FIG. 3A. An N-type source S and an N-type drain D are formed on the SOI layer 30 serving as a semiconductor layer. A P-type floating body B (hereinafter, simply “body B”) in an electrically floating state is provided between the source S and the drain D, and accumulates or emits electric charges (hereinafter, “charges”) for storing logic data. The logic data can be binary data “0” or “1” or multilevel data. It is assumed that the FBC memory device according to the first embodiment stores binary data in the memory cells MCs. If the memory cells MCs are, for example, N-FETs, then a memory cell MC accumulating many holes in the body B is defined as a “1” cell and a memory cell MC emitting holes from the body B is defined as a “0” cell.

A gate dielectric film GI is provided on the body B and a gate electrode G is provided on the gate dielectric film GI. A silicide 12 is formed on each of the gate electrodes G, the sources S, and the drains D. Gate resistance and contact resistance are thereby reduced. Each source S is connected to one source line SL via a source line contact SLC. Each drain D is connected to one bit line BL via a bit line contact BLC. The sources S, the drains D, and the bodies B are formed in order of S, B, D, B, S, B, D . . . . Each of the sources S and the drains D is shared between a plurality of memory cells MCs adjacent in the column direction. Likewise, each of the source line contacts SLCs and the bit line contacts BLCs is shared between a plurality of memory cells MCs adjacent in the column direction. The memory cell array MCA is thereby made small in size.

Each gate electrode G extends in the row direction and also functions as one word line WL. A sidewall 14 is formed around the gate electrode G and a liner layer 16 is formed around the sidewall 14. An interlayer dielectric film ILD is filled up between wirings such as the source lines SLs or the bit lines BLs. FIG. 3A is a cross-sectional view along one bit line BL. The gate electrodes G (word lines WLs) and the source lines SLs extend in the row direction (vertical direction of a sheet of FIG. 3A) and are orthogonal to the bit lines BLs.

With reference to FIG. 3B, one source line SL connected to the sources S via the source line contacts SLCs extend in the row direction. With reference to FIG. 3C, the gate electrode G extends in the row direction and functions as one word line WL.

Referring back to FIG. 3A, a bottom of the SOI layer 30 faces a plate via the back gate dielectric film BGI. The plate is a well formed in the supporting substrate 10. By applying an electric field to the body B of each FBC from the plate and the gate electrode G, the body B can be made fully depleted. The FBC of this type is referred to as a fully depleted FBC (“FD-FBC”). In the FD-FBC, a positive voltage is applied to the gate electrode G during a data-read operation, a channel (an inversion layer) is formed on a surface of the body B, and the body B is made fully depleted. At this time, a negative voltage is applied to the plate so as to be capable of retaining holes on a bottom of the body B. The FBC according to the first embodiment can be a partially depleted FBC (“PD-FBC”). In the PD-FBC, if a channel is formed by applying a positive voltage to the gate electrode, the body B is partially depleted. At this time, a neutral region in which holes can be accumulated remains in the body B. Since the holes are retained in the neutral region, the negative voltage applied to the plate can be low.

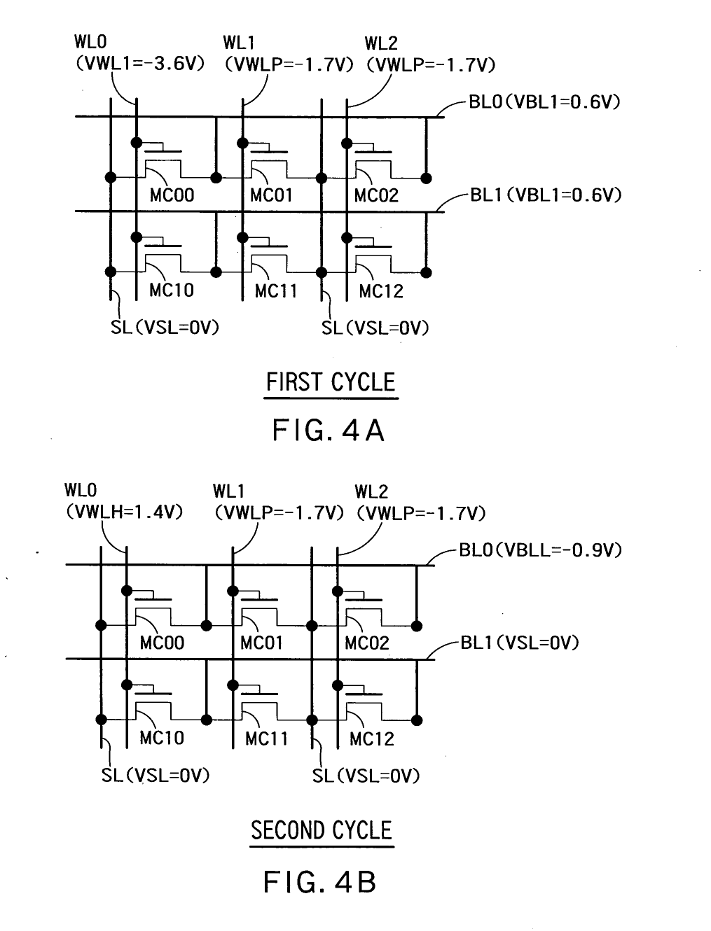

FIGS. 4A and 4B are explanatory diagrams showing a data-write operation according to the first embodiment. The data-write operation according to the first embodiment includes two steps, i.e., a first cycle and a second cycle.

In the first cycle shown in FIG. 4A, holes generated by GIDL (Gate Induced Drain Leakage) are accumulated in memory cells MC00 and MC10 so as to write data “1” to all the memory cells MC00 and MC10 connected to a selected word line WL0.

The GIDL means a leakage current generated by biasing a word line potential to a reversed polarity with respect to a polarity of majority carriers accumulated in the memory cells MCs with reference to a source line potential and by biasing the word line potential to a reversed polarity with respect to the polarity of the majority carriers with reference to a bit line potential. The polarity of holes is plus (+) and that of electrons is minus (−).

More specifically, if the word line potential is set lower than the source line potential and the bit line potential, electron-hole pairs are generated by band-to-band tunneling near an overlap region in which one drain D, one source S, and one gate electrode G overlap one another. If the FBC is the n-FBC, the GIDL is generated if the holes in the electron-hole pairs flow into the body B and the electrons in the electron-hole pairs flow to the drain D and the source S. In a data retention state, the word line potential is set lower than the source line potential and the bit line potential so as to retain the hole accumulated in the “1” cell. In the data retention state, the number of holes accumulated in the “0” cell is gradually increased due to the GIDL current. Generally, therefore, the GIDL changes the “0” cell to the “1” cell and adversely influences the signal difference between the data “0” and the data “1” if the data is read after being retained for long time. Nevertheless, since the holes can be accumulated in each memory cell MC, the GIDL can be used to write data “1”. A method of writing data using the GIDL will be referred to as “GIDL writing”.

In the first cycle according to the first embodiment, data “1” is written to all the memory cells MC00 and MC10 connected to the selected word line WL0 using the GIDL writing. More specifically, a first potential VBL1 (e.g., 0.6 V) is applied to bit lines BL1 and BL0 in all columns. A second potential VWL1 (e.g., −3.6 V) lower than a source line potential VSL (e.g., ground potential (0 V)) and the first potential VBL1 is applied to the selected word line WL0. An absolute value (4.2 V) of a gate-drain voltage and an absolute value (3.6 V) of a gate-source voltage in the first cycle are greater than absolute values (1.7 V) of the gate-drain voltage and the gate-source voltage in the data retention state. Due to this, GIDL is generated and holes are accumulated in the body B lower in potential than the source S and the drain D. As a result, the data “1” is written to the all the memory cells MC00 and MC10 connected to the selected word line WL0.

In the second cycle shown in FIG. 4B, data “0” is written to the memory cell MC00 connected to the selected word line W0 and a selected bit line BL0. At this time, a potential of the selected word line WL0 is a potential biased to the same polarity as that of majority carriers in the memory cells MCs with reference to the source line potential, and is a potential biased to the same polarity as that of majority carriers in the memory cell MCs with reference to the bit line potential. More specifically, a third potential VBLL (e.g., −0.9 V) lower than the source line potential VSL is applied to the selected bit line BL0. A potential of an unselected bit line BL1 is set to 0 V equal to the source line potential VSL. A fourth potential VWLH (e.g., 1.4 V) higher than the source line potential VSL (e.g., 0 V) and the third potential VBLL is applied to the selected word line WL0. By doing so, a forward bias is applied to a pn junction between the body B and the drain D of the memory cell MC00 and the holes accumulated in the body B are drawn out (eliminated) to the drain D. Since the potential of the bit line BL1 is equal to the same ground potential as the source line potential VSL, the memory cell MC10 retains data “1”.

A fourth potential VWLH and the third potential VBLL are set so that a potential level of the source line potential VSL is between potential levels of the fourth potential VWLH and the third potential VBLL. Namely, with reference to the source line potential VSL, the fourth potential VWLH and the third potential VBLL are reversed in polarity with respect to each other. Further, the second potential VWL1 is a negative potential reversed in polarity with respect to the holes serving as majority carriers, and the fourth potential VLWH is a positive potential identical in polarity to the holes. Accordingly, in the first embodiment, data “1” is written to the memory cells MCs in all the columns connected to the selected word line WL by the GIDL writing in the first cycle, and data “0” is written to the selected memory cell MC connected to the selected word line WL and the selected bit line BL in the subsequent second cycle. It is thereby possible to write desired logic data to the memory cell MC connected to the word line WL.

In the specification, “selection” and “activation” mean “turning on or driving an element or a circuit” and “non-selection (unselected)” and “deactivation” mean “turning off or stopping an element or a circuit”. Accordingly, it is to be noted that a HIGH (high potential level) signal can be a selected signal or an activated signal on one occasion and that a LOW (low potential level) signal can be a selected signal or an activated signal on another occasion. For example, an NMOS transistor is selected (activated) by setting a gate HIGH. A PMOS transistor is selected (activated) by setting a gate LOW.

In the conventional GIDL writing, only the memory cell to which data “1” is to be written is selected from among the memory cells connected to the selected word line, and the GIDL writing is executed only to the selected memory cell. In this case, a potential lower than the source line potential VSL is applied to the selected word line and the potential VBL higher than the source line potential is applied to the selected bit line. This potential VBL is the bit line potential for writing data “1”. Among the memory cells connected to the selected word line, the memory cell to which data “0” is to be written has a drain potential equal to the source line potential VS. Due to this, the threshold voltage difference (signal difference) between a “0” cell and a “1” cell greatly depends on the magnitude of the potential VBL used to write data “1” relative to the source line potential VSL. Namely, it is necessary to set the potential VBL of the selected bit line high so as to provide a great threshold voltage difference between the “0” cell and the “1” cell. However, to set the potential VBL of the selected bit line high causes an influence of the bit line “1” disturbance on the unselected memory cells connected to the selected bit line. This disadvantageously makes data retention time of the unselected memory cells connected to the selected bit line short. If the data retention time is short, it is required to set the execution frequency of a refresh operation high. Conversely, if the potential VBL of the selected bit line is set low, the bit line “1” disturbance is suppressed. However, the threshold voltage difference between the “0” cell and the “1” cell is made small.

The refresh operation includes can be performed through a sense amplifier refresh in which data is read from a memory cell MC once, the read data is latched in a sense amplifier S/A, and the same logic data as this data is written back to the same memory cell. Alternatively, the refresh operation can be performed through an autonomous refresh of simultaneously recovering the both of the “0” cell and the “1” cell using the body potential difference between the “0” cell and the “1” cell.

In the data writing method according to the first embodiment, the first voltage VBL1 applied to the drain D in the first cycle is the bit line potential for writing data “1” and is common to the memory cells MCs in all the columns. To generate necessary holes for writing data “1” to a memory cell MC, the second potential VWL1 applied to the selected word line WL0 can be set low instead of setting the first potential VBL1 high. At this time, holes are accumulated in bodies B of all the memory cells MC00 and MC10 connected to the selected word line WL0 by the GIDL. However, data “0” is written to the memory cell MC00 in the next second cycle, so that no problem occurs even if the holes are accumulated in the first cycle. However, before accumulating holes by the GIDL, data “0” is saved into sense amplifiers S/A. Due to this, the sense amplifiers S/As are provided to correspond to each of the bit line BLs.

In the second cycle, data “0” is written to the memory cell MC00. At this time, a potential applied to the drain of the memory cells MC00 is different from that of the memory cell MC10. Namely, the same potential as the source line potential VSL is applied to the drain D of the memory cell MC10 and the third potential VBLL lower than the source line potential VSL is applied to the memory cell MC00. Therefore, the threshold voltage difference between the “0” cell and the “1” cell greatly depends on the third potential VBLL used to write data “0”. Due to this, in the first embodiment, the threshold voltage difference between the “0” cell and the “1” cell can be increased by setting the absolute value of the third potential VBLL with reference to the source line potential VSL high even if the first potential VBL1 used to write the data “1” s made closer to the source line potential VSL. This means that the threshold voltage difference between the “0” cell and the “1” cell can be increased while suppressing the bit line “1” disturbance.

While the first potential VBL1 is set to 0.6 V in FIG. 4A, the first potential VBL1 can be made further close to the source line potential VSL. Moreover, the first potential VBL1 can be set equal to the source line potential VSL. In this case, the potential VWL1 of the selected word line WL0 can be set lower and the threshold voltage difference between the “0” cell and the “1” cell can be increased as will be described later.

With reference to FIG. 1, the GIDL-writing-based operation according to the first embodiment is further described. First, latch circuits L/Cs of the sense amplifiers S/As latch data read from the memory cells MCs in all the columns connected to the selected word line. If the selected word line is, for example, WLL0, the latch circuits L/Cs latch the data in all the memory cells MCs connected to the word line WLL0. At this time, each of the sense amplifiers S/As receives a reference signal from the memory cell array MCAR. Next, transfer gates TGL and TGR in each sense amplifier S/A are turned off, thereby separating each latch circuit L/Cs in the sense amplifier S/A from the bit line BL corresponding to the sense amplifier S/A. A transistor TBL1L in each sense amplifier S/A is turned on, thereby connecting the first potential VBL1 to all the bit lines BLL within the memory cell array MCAL. As a result, data “1” is written to the memory cells MCs in all the columns connected to the selected word line WLL0 (in the first cycle). Moreover, the data “0” written to each latch circuit L/C is written back to the memory cells MCs (“0” cells) (in the second cycle).

In the data-write operation, data received from an outside via the DQ buffer DQB is temporarily stored in each latch circuit L/C. At this time, it takes certain time to store the data from the DQ buffer DQB in the latch circuit L/C. If the first cycle is executed using this time, the two-step GIDL writing according to the first embodiment can be executed without increasing entire cycle time.

Furthermore, it takes longer time to perform the operation for accumulating holes in the body B by the GIDL than the operation for extracting holes from the body B. If the first cycle is short (e.g., 10 nanoseconds (ns) or less), sufficient holes are not accumulated in the body B and the body potential does not turn into a steady state. In this case, the threshold voltage difference between the data “1” and the data “0” cannot be made sufficiently large. However, if the write time of writing data from the DQ buffer DQ to the latch circuit L/C is used for the first cycle, the holes can be sufficiently accumulated in the body B and the threshold voltage difference between the data “1” and the data “0” can be made sufficiently large. Since the operation for extracting holes from the body is performed at high speed, data “0” can be written to the memory cell MC sufficiently in 10 ns.

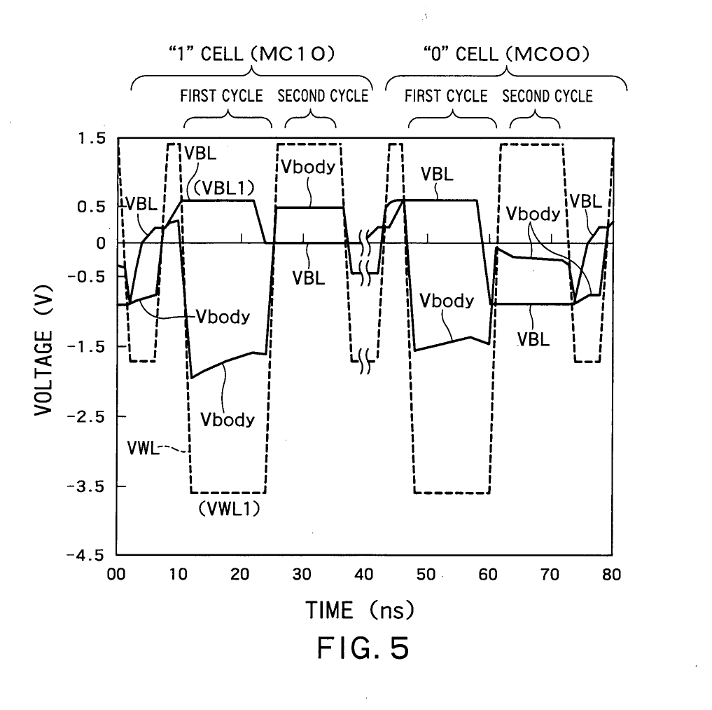

FIG. 5 is a timing diagram of voltages applied to the memory cells MCs in the first and second cycles according to the first embodiment. A period from 10 ns to 36 ns is a first cycle execution period. A period from 46 ns to 72 ns is a second cycle execution period. Since the two memory cells MC10 and MC00 are connected to the same selected word line WL0, 10 ns is actually equivalent to 46 ns and 36 ns is actually equivalent to 72 ns. Namely, an actual first cycle execution duration and an actual second cycle execution duration are about 26 ns.

In this simulation, it is assumed that a thickness of the SOI layer 30 is 21 nanometers (nm), a thickness of the gate dielectric film GI is 5.2 nm, a gate length is 75 nm, a thickness of the BOX layer 20 is 12.5 nm, and a P-impurity concentration of the body B is 1×10¹⁷ cm⁻³. It is also assumed that fixed voltages of 0 V and −2.4 V are applied to the source S and the plate (the supporting substrate 10), respectively. In a period from 10 ns to 12 ns and that from 46 ns to 48 ns, the potential of the selected word line WL0 is lowered to the second potential VWL1 and the bit line potential in all the columns is raised to the first potential VBL1. Since the second potential VWL1 is as low as −3.6 V, the body potential Vbody is also low by capacitive coupling between the body B and the gate electrode G. In a period from 12 ns to 22 ns and that from 48 ns to 58 ns, data “1” is written to the memory cells MC00 and MC10 (in the first cycle). Since the gate voltage relative to the drain D is quite low, an electric field in the overlap region in which the drain D and the gate electrode G overlap each other (the region in which the drain D and the gate electrode G overlap each other from the top view is high. Accordingly, the GIDL flows and data “1” is written to the memory cells MC00 and MC10. A band-to-band tunneling current at 12 ns is 12.6 nA/μm.

In a period from 22 ns to 24 ns and that from 58 ns to 60 ns, the potential of the selected word line WL0 is raised to a fourth potential VWLH. Since the potential of the selected word line WL0 is raised, the body potential Vbody is raised by the capacitive coupling between the body B and the gate electrode G. At the same time, the bit line BL corresponding to the memory cell MC10 to which data “0” is not to be written is lowered to the source line potential VSL. Since there is no potential difference between the drain D and the source S of the memory cell MC10, the data “0” is not written to the memory cell MC10. The bit line BL corresponding to the memory cell MC00 to which data “0” is to be written is lowered to the third potential VBLL lower than the source line potential VSL. The potential difference between the drain D and the source S of the memory cell MC00 is thereby generated and data “0” is written to the memory cell MC00, accordingly. In a period from 62 ns to 72 ns, the data “0” is written to the memory cell MC00.

In a period from 36 ns to 38 ns and that from 72 ns to 74 ns, the bit line potential returns to 0 V. In a period from 38 ns t 40 ns and that from 74 ns to 76 ns, the potential of the word line WL changes to the data retention state potential (−1.7 V). As a result, in a period from 40 ns to 76 ns, the memory cells MC00 and MC10 turn into data retention states (pause states).

In a period from 44 ns to 80 ns, a data-read operation is executed. At this time, the word line potential is 1.4 V and the bit line potential is 0.2 V. A drain current difference during the data read operation is 58.5 μA/μm.

If the potential difference between the gate G and the drain D is set large, the GIDL increases. Therefore, a data “1” write speed is accelerated and the threshold voltage difference between the data “0” and the data “1” is increased. Meanwhile, if the potential difference between the gate G and the drain D is increased, the electric field in the gate dielectric film GI increases. The increase in the electric field in the gate dielectric film GI deteriorates immunity against TDDB (Time Dependent Dielectric Breakdown) of the gate dielectric film GI. That is, the potential difference between the gate G and the drain D is preferably large in light of the data write speed and the signal difference but preferably small in light of reliability of the gate dielectric film GI.

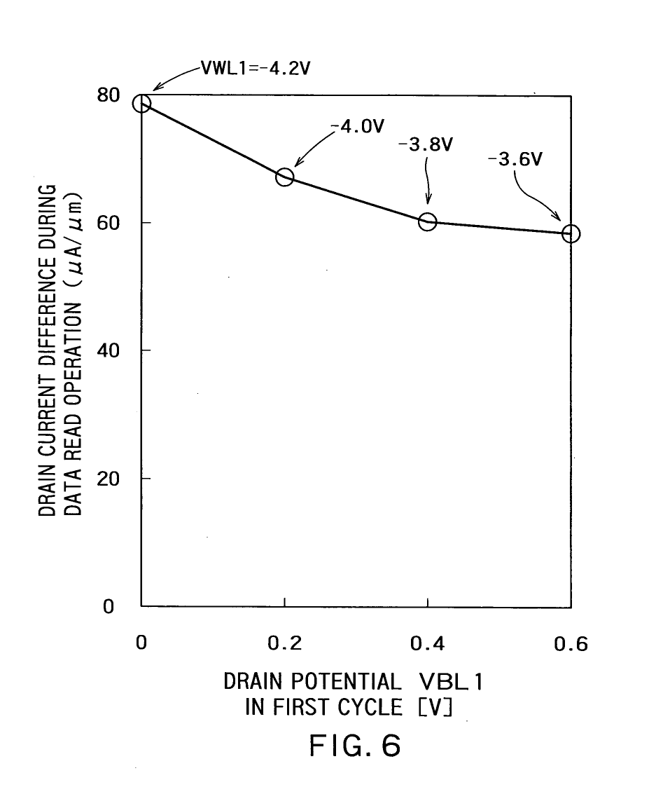

FIG. 6 is a graph showing the relationship between the bit line potential VBL1 and the drain current difference during the data read operation in the first cycle according to the first embodiment. In the first embodiment, the bit line potential is 0.6 V and the word line potential VWL1 is −3.6 V. If the first potential VBL1 is lowered while keeping the potential difference between the gate G and the drain D to −4.2 V, it is clear that the drain current difference during the data-read operation rises as shown in FIG. 6. To increase the drain current difference during the data-read operation means the increase in the signal difference between the data “1” and the data “0”. Since the potential difference between the gate G and the drain D is fixed, the reliability of the gate dielectric film GI is kept almost constant.

Accordingly, as evident from the graph of FIG. 6, it is possible to increase the signal difference between the data “1” and the data “0” while maintaining the reliability of the gate dielectric film GI by making the bit line potential (first potential) VBL1 in the first cycle closer to the source line potential VSL. This is because the GIDL in the overlap region in which the source S and the gate electrode G overlap each other increase if the bit line potential VBL1 is made closer to the source line potential VSL. The band-to-band tunneling current at 12 ns is 18.0 nA/μm if the bit line potential (first potential) VBL1 in the first cycle is −4.2 V.

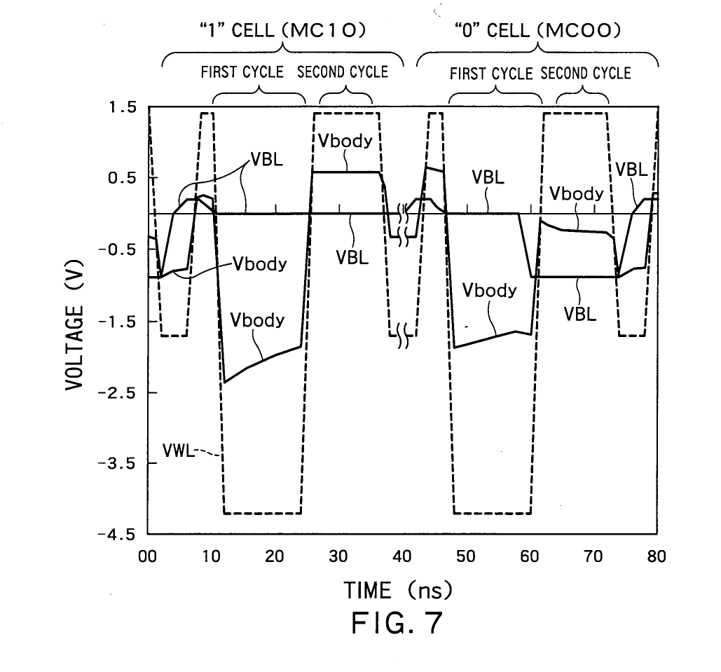

FIG. 7 is a timing diagram of the first cycle and the second cycle at VBL1=VSL and VWL1=−4.2 V according to the first embodiment. The operation shown in FIG. 7 differs from that shown in FIG. 5 in that the bit line potential VBL1 is equal to the source line potential VSL (ground potential) and that the word line potential VWL1 is −4.2 V. Other operations shown in FIG. 7 are similar to those shown in FIG. 5. In the operation shown in FIG. 7, the drain current difference during the data-read operation is 78.5 μA/μm as indicated in FIG. 6.

In the data-write operation shown in FIG. 7, the bit line potential VBL1 in the first cycle is equal to the source line potential VSI. Due to this, no bit line “1” disturbance occurs to the memory cells MCs connected to the unselected word lines WLs at all. As a result, the refresh operation execution frequency of the FBC memory device using the data-write operation shown in FIG. 7 can be set lower than that using the data-write operation shown in FIG. 5. This can eventually reduce overall power consumption of the FBC memory device.

In the data-write operation using the impact ionization current according to the conventional technique, the amplitude of the bit line potential needs to be equal to or higher than 1.5 V. For example, the bit line potential VBL1 for writing data “1” is set to 1.1 V and the bit line potential VBLL for writing data “0” is set to −0.4 V. In this case, the drain current difference is about 41 μA/μm at most.

With a driving method shown in FIG. 7, by contrast, the drain current difference is as large as 78.5 μA/μm although the amplitude of the bit line potential is as low as 0.9 V. Therefore, the GIDL writing method according to the first embodiment can secure a larger signal difference than that according to the conventional technique even if power consumption for driving the bit lines BLs is set low.

In FIGS. 5 and 7, after the data “0” is written, the timing of changing the bit line potential to the data retention state can be set either earlier or later than that of changing the word line potential to the data retention state.

### Second Embodiment

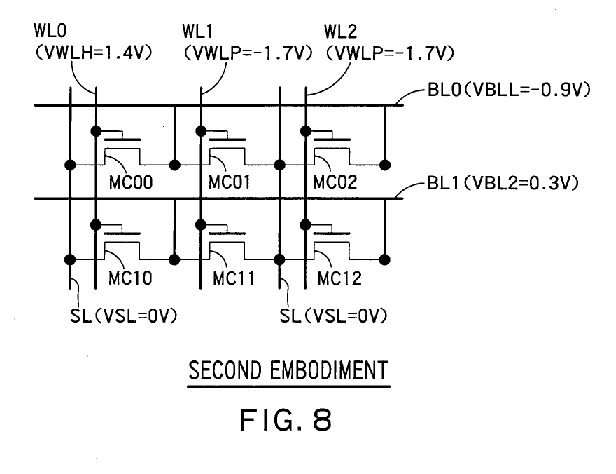

FIG. 8 is an explanatory diagram showing a method of driving an FBC memory device according to a second embodiment of the present invention. The second embodiment differs from the first embodiment in the second cycle. Since the first cycle according to the first embodiment is the same as that according to the first embodiment, it will not be described herein.

In the second cycle according to the second embodiment, holes are extracted from the selected memory cell MC00 out of the memory cells MC00 and MC10 connected to the selected word line WL0. Data “0” is thereby written to the selected memory cell MC00. Holes in small quantity are extracted from the unselected memory cell MC10 out of the memory cells MC00 and MC10 connected to the selected word line WL0. Data “1” is thereby written to the unselected memory cell MC10.

In the second cycle, the potential of the selected word line WL0 is a potential biased to the same polarity as that of majority carriers in the memory cells MCs with reference to the source line potential. In the second cycle the potential of the selected bit line BL0 is a potential biased to a reversed polarity with respect to the polarity of majority carriers with reference to the source line potential and the potential of the unselected bit lines is a potential biased to the same polarity as that of majority carriers with reference to the source line potential. More specifically, as shown in FIG. 8, the fourth potential VWLH (e.g., 1.4 V) higher than the source potential VSL is applied to the selected word line WL0. The third potential VBLL (e.g., −0.9 V) lower than the source line potential VSL is applied to the selected bit line BL0. A forward bias is thereby applied to the pn junction between the drain D and the body B of the selected memory cell MC00 to eliminate holes. A fifth potential VBL2 (e.g., 0.3 V) higher than the source line potential VSL is applied to the unselected bit line BVL1. A weak forward bias is thereby applied to the pn junction between the source S and the body B of the unselected memory cell MC10. Holes in small quantities are thereby eliminated from the unselected memory cell MC10.

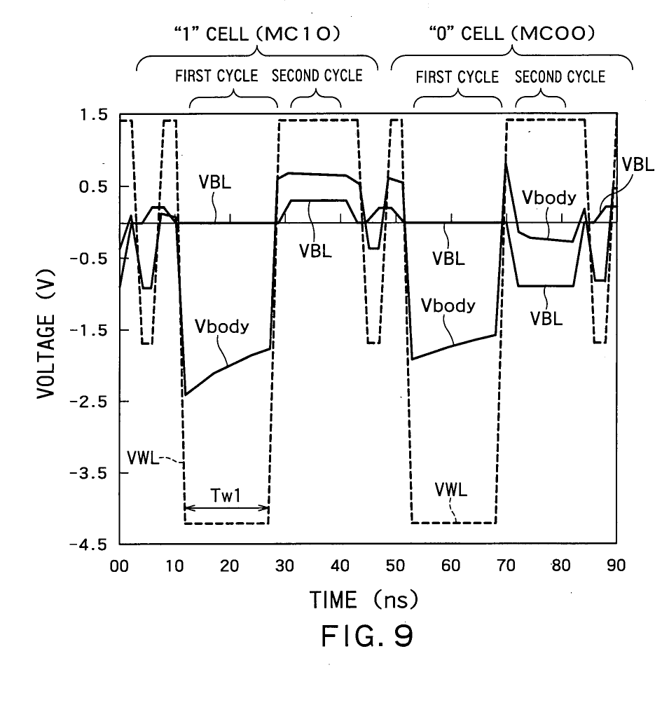

FIG. 9 is a timing diagram of voltages applied to the memory cells MCs in the first and second cycles according to the second embodiment. Fixed voltages of 0 V and −2.4 V are applied to the source S and the plate (supporting substrate 10), respectively. In the second cycle, a potential of 0.3 V is applied to the bit line BL1 corresponding to the unselected memory cell MC10. The holes in small quantities accumulated in the unselected memory cell MC10 are eliminated. Other operations according to the second embodiment are similar to those according to the first embodiment. In a data write operation according to the second embodiment, the drain current difference between the “1” cell and the “0” cell during the data-read operation is 64.2 μA/μm.

The reason for eliminating the holes in small quantities from the unselected memory cell MC10 connected to the selected word line WL0 in the second cycle is described. Generally, memory cells MCs have a fluctuation in drain current. The fluctuation in the drain current among the memory cells MCs mainly result from a fluctuation in threshold voltage among the memory cells MCs. If the fluctuation in the drain current is large, the number of defective bits in the FBC memory device increases. For example, memory cells MCs low in threshold voltage out of the “0” cells and those high in threshold voltage out of the “1” cells are defective bits. To attain high yield, therefore, it is important to not only make the threshold voltage difference between the “0” cell and the “1” cell large but also to make the fluctuation in the threshold voltage among the memory cells MCs small per se.

As described above, in the GIDL writing for about 10 ns, the body potential does not saturate and does not turn into a steady state. This means that “1” cells have fluctuation in threshold voltages if write time Tw1 in the first cycle (hereinafter, “first cycle write time Tw1”) is fluctuated among the “1” cells. Furthermore, since the writing of the data “1” to each memory cell MC is finished before the body potential turns into a steady state. Therefore, the “1” cells have fluctuation in threshold voltages according to the number of writes (overwrites) of data “1”. If the GIDL is has a fluctuation, the fluctuation in the threshold voltages among the “1” cells is further increased.

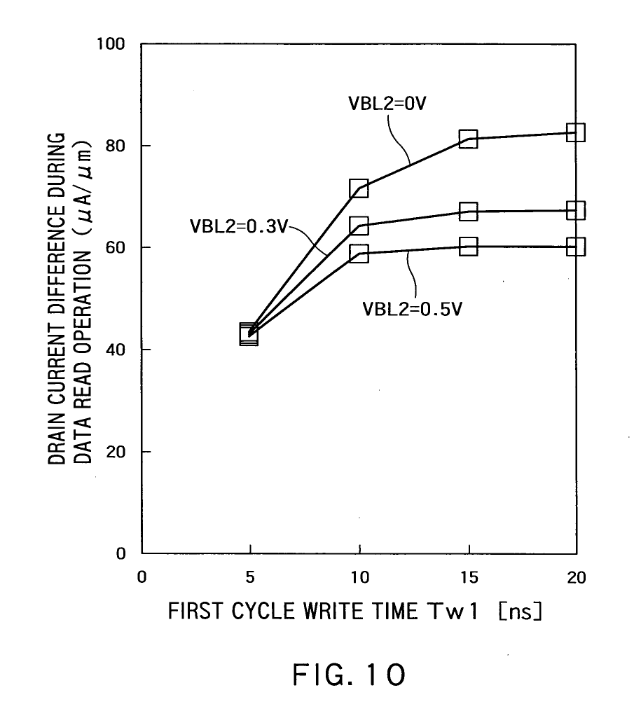

FIG. 10 is a graph showing the relationship between the first cycle write time Tw1 and the drain current difference during the data-read operation according to the second embodiment. FIG. 10 shows a result of changing the bit line potential (fifth potential) VBL2 relative to the “1” cell in the second cycle to 0 V, 0.3 V, and to 0.5 V. At VBL2=0 V, the drain current difference greatly depends on the first cycle write time Tw1. However, as the bit line potential (fifth potential) VBL2 rises to 0.3 V and to 0.5 V, the dependence of the drain current difference on the first cycle write time Tw1 is reduced. If the first cycle write time Tw1 is long, more holes are accumulated in the body B of the “1” cell for the following reason. If more holes are accumulated in the body B, the more holes are eliminated in the second cycle. Namely, even if there is a fluctuation in the number of holes accumulated in the “1” cell in the first cycle, the holes by as much as the fluctuation are eliminated from the “1” cell in the second cycle. In this way, in the second cycle according to the second embodiment, a feedback operation can be performed to reduce the fluctuation in the number of holes accumulated in the “1” cell.

In the second embodiment, while the number of holes in the body B decreases in the second cycle, the fluctuation in signal difference resulting from the first cycle write time Tw1 is reduced by the feedback operation in the second cycle. Accordingly, the threshold voltage difference increases between the memory cells MC low in threshold voltage out of the “0” cells and those high in the threshold voltage out of the “1” cells, thereby improving the yield.

In the second embodiment, after the data “1” is written in the first cycle, the potential of the word line WL0 is raised and then those of the bit lines BLs are changed in the second cycle. As a result, a voltage between the gate G and the drain D in a transition period from the first cycle to the second cycle is set to be equal to or lower than that in the first cycle. In other words, an electric field in the gate dielectric film GI of the memory cell MC in the transition period from the first cycle to the second cycle is set to be equal to or lower than that in the first cycle. It is, therefore, possible to prevent deterioration in the reliability of the gate dielectric film GI in the transition period from the first cycle to the second cycle.

### Third Embodiment

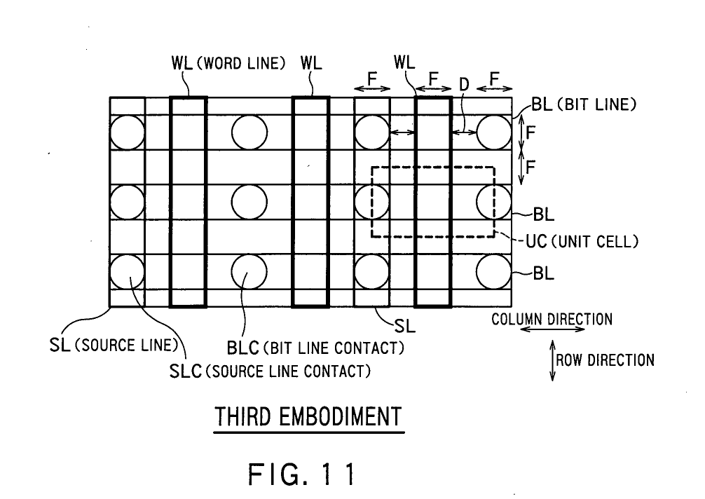

FIG. 11 is a plan view showing arrangement of wirings in an FBC memory device according to a third embodiment of the present invention. Bit lines BLs extend in the column direction. Word lines WLs and the source lines SLs extend in the row direction orthogonal to the bit lines BLs. Memory cells MCs are arranged at crosspoints between the bit lines BLs and the word lines WLs, respectively. Each of the bit lines BLs is connected to the drain D of each memory cell MC via a bit line contact BLC. The word lines WLs also function as the gate electrode G of each of the memory cells MCs. Each of the source lines SLs is connected to the source S of each memory cell MC via a source line contact SLC.

In view of a positional deviation between bit line contacts BLCs and the source line contacts SLCs, a margin between one word line WL and one bit line contact BLC and that between one word line WL and one source line contact SLC are set to a distance D. The distance D is gradually reduced according to progress of technology. If the bit line contacts BLCs and the source line contacts SLCs are formed using self-aligned contacts, the distance D is zero. At this time, an area of a unit cell UC is 4 F². The symbol F is a minimum size of a resist pattern that can be formed by lithographic technique in a certain generation.

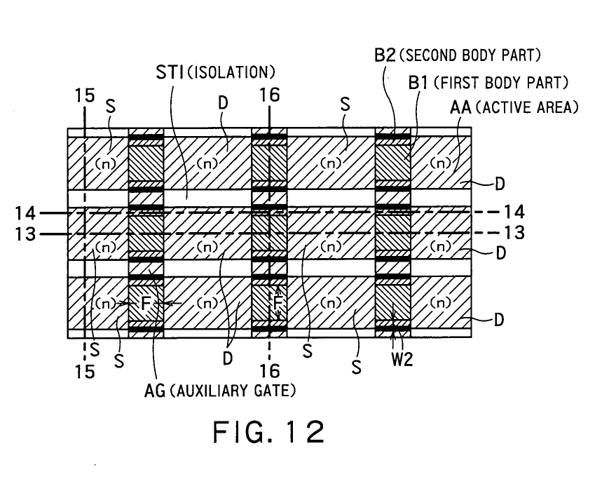

FIG. 12 is a plan view showing the bodies B in the FBC memory device according to the third embodiment. The body B of each memory cell MC according to the third embodiment includes a first body part B1 and a second body part B2. The first body part B1 and the second body part B2 are made of the same material. The second body part B2 is connected to an upper surface of the first body part B1 and is a semiconductor layer continuous to the first body part B1. The first body part B1 is provided between the source S and the drain D in the column direction.

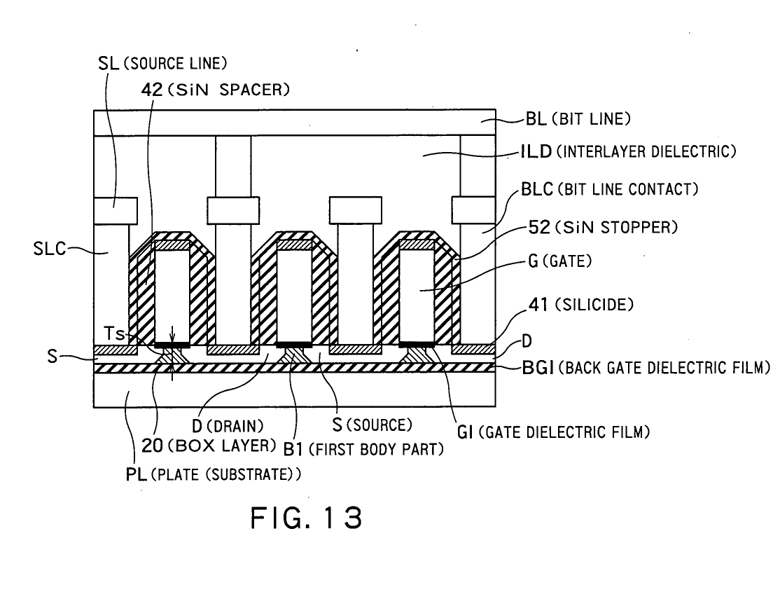

FIGS. 13 to 16 are cross-sectional views taken along lines 13-13, 14-14, 15-15, and 16-16 of FIG. 12, respectively. Cross sections of the first body parts B1 appear in FIG. 13. The upper surface (first surface) of each first body part B1 faces the gate electrode G via the gate dielectric film GI. A bottom surface (second surface) of the first body part B1 faces a plate PL via the back gate dielectric film BGI.

Each memory cell according to the second embodiment is an FD-FBC. In this case, by applying a positive voltage to the gate electrode G of the FBC during the data-read operation, a channel is formed on the surface of the body B and the body B is made fully depleted. A maximum depleted layer width is, therefore, equal to or larger than a thickness Ts of the body B. The thickness Ts is that of the first body part B1 between the first surface and the second surface. During the data-read operation, a negative potential is applied to the plate PL so as to be able to accumulate holes in the second surface of the first body part B1.

If the threshold voltage difference between the “0” cell and the “1” cell is denoted as ΔVth, the threshold voltage difference ΔVth is expressed by an equation ΔVth=Csi/Cfox×ΔVbs. In the equation, Csi denotes a capacitance of a depleted layer formed in the body B per unit area, Cfox denotes a capacitance of the gate dielectric film GI per unit area, and ΔVbs denotes a body potential difference between the “0” cell and the “1” cell. A ratio Csi/Cfox is also rephrased to 3×Tfox/Ts, where Tfox denotes the thickness of the gate dielectric film GI. To make the threshold voltage difference ΔVth large, the ratio of Tfox to Ts is set high, or, ΔVbs is set large. The body potential means herein a body potential of the bottom (second surface) of the first body part B1 during the data-read operation.

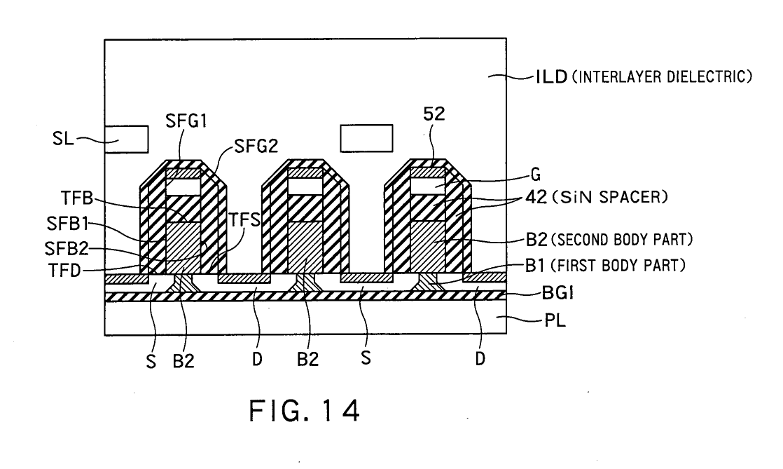

FIG. 14 is the cross-sectional view taken along the line 14-14 of FIG. 12 and shows a part of the FBC memory device including active areas AAs adjacent to element isolation regions

STI along the column direction. Cross sections of the second body parts B2 appear in FIG. 14. A top surface TFB of each second body part B2 is located at a higher position than that of a top surface TFS of the source S and that of a top surface TFD of the drain D. In other words, the second body part B2 extends in a third direction (an upward direction) perpendicular to both the word lines WLs and the bit lines BLs. As is clear from FIG. 16, the second body part B2 extends upward relative to the first body part B1.

As shown in FIG. 16, the second body part B2 of each memory cell MC has two side surfaces (a third surface S3 and a fourth surface S4) directed in the row direction. The surfaces S3 and S4 face the word line WL via the gate dielectric film GI. More specifically, a side surface of the gate electrode G formed on the first body part B1 faces the third surface S3 of the second body part B2 via the gate dielectric film GI. A side surface of an auxiliary gate AG formed on each STI region faces the fourth surface S4 of the second body part B2 via the gate dielectric film GI.

The second body part B2 is an auxiliary body part for increasing the capacitive coupling between the body B and the word line WL. Since the second body part B2 extends in the third direction, the size of each memory cell MC is not increased. However, since an area of the second body part B2 opposed to the word line WL is larger than that of a conventional flat body, the capacitive coupling between the body B and the word line WL can be increased. The auxiliary gate AG is a gate part formed integratedly with the gate electrode G to serve as a part of the gate electrode G. The auxiliary gate AG is formed on each STI and controlled to be equal in potential to the gate electrode G.

As shown in FIG. 14, in the cross-sectional view along the column direction, the top surface TFS of the source S and the top surface TFD of the drain D are lower in position than the top surface TFB of the second body part B2. In other words, the second body part B2 has two side surfaces SFB1 and SFB2 oriented in the column direction. The side surfaces SFB1 and SFB2 are not in contact with the source S and the drain D, respectively. The side surfaces SFB1 and SFB2 of the second body part B2 do not form pn junctions with the source S or the drain D. On the other hand, a lower portion of the second body part B2 (a portion of the second body part B2 located at the same height as that of the top surface TFS of the source S and that of the top surface TFD of the drain D, respectively) is adjacent to the source S and the drain D in the perpendicular (third) direction. Namely, the lower portion of the second body part B2 forms pn junctions with the source D and the drain D, respectively but the side surfaces SFB1 and SFB2 thereof do not form pn junctions with the source D and the drain D, respectively. The lower portion of the second body part B2 is also connected to the first body part B1. It is to be noted that the side surfaces SFB1 and SFB2 of the second body part B2 are flush with side surfaces SFG1 and SFG2 of the gate electrode G oriented in the column direction, respectively. Since the distance between the side surfaces SFG1 and SFG2 corresponds to a gate length, a width of the second body part B2 in the column direction is equal to the gate length. With this structure, the capacitive coupling between the body B and the drain D and that between the body B and the source S are either the same as those of the conventional structure or slightly increases from those of the conventional structure despite an increase in the capacitive coupling between the body B and the word line WL. Therefore, a ratio Cb (WL)/Cb (total) of a body-gate capacitance Cb (WL) to a total body capacitance Cb (total) is high.

As shown in FIG. 16, a distance W2 between the side surfaces S3 and S4 of the second body part B2 is reduced so as to reduce the size of the memory cell MC, that is, smaller than a twofold of the maximum depleted layer width. Due to this, during the data-read operation, the second body part B2 the two surfaces S3 and S4 of which are put between the gate electrode G is fully depleted and cannot accumulate therein holes. As a result, during the data-read operation, the holes are moved to the bottom of the first body part B1. The number of holes in the first body part B1 has an influence on the threshold voltage near the top surface of the first body part B1. It is, therefore, preferable that the hole accumulation layer (the bottom of the first body part B1) and the inversion layer (the top surface of the first body part B1) are parallel as described in the third embodiment. The reason is as follows. The degree of the influence is inversely proportional to the thickness Ts of the first body part B1 and is uniform. Due to this, the threshold voltage difference can be effectively increased by making the thickness Ts of the first body part B1 small.

However, the influence of the number of holes present on the hole accumulation layer (bottom of the first body part B1) on the inversion layer formed on the side surface of the second body part B2 is reduced according to the distance between the hole accumulation layer and the inversion layer. The threshold voltage of the inversion layer formed on the upper portion of the second body part B2 the distance of which from the hole accumulation layer (bottom of the first body part B1) is large, in particular, is hardly influenced by the number of holes on the bottom of the first body part B1. It is, therefore, important to set a channel current flowing near the top surface of the first body part B1 higher than a parasitic channel current flowing on the side surfaces of the second body part B2 so as to increase the drain current difference during the data-read operation.

In the third embodiment, the side surfaces SFB1 and SFB2 of the second body part B2 are not in contact with the source S and the drain D, respectively, so that the parasitic channel current flowing on the upper portion of the second body part B2 is low. As described above, this parasitic channel current does not depend on the data “0” and the data “1”. Accordingly, even if the second body part B2 is provided, the drain current difference between the data “0” and the data “1” during the data read operation is not so reduced.

An SiN spacer 42 is formed on the top surface of the second body part B2. The SiN spacer 42 prevents a high electric field from the gate electrode G from being applied to upper corners of the second body part B2. This can prevent breakdown of the gate dielectric film GI.

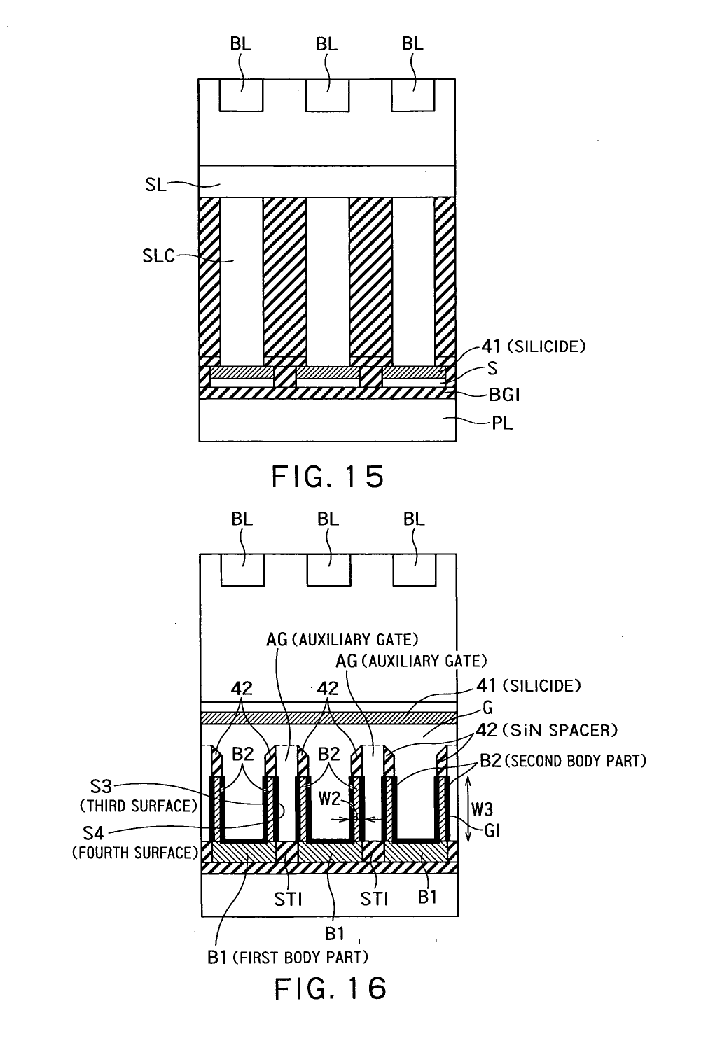

FIG. 15 is the cross-sectional view along one source line SL. In the cross section shown in FIG. 15, the semiconductor layer extending upward is not formed. Although not shown, the semiconductor layer extending upward is not formed on the drain D either. This means that the semiconductor layer extending upward (second body part B2) is formed only in the body B.

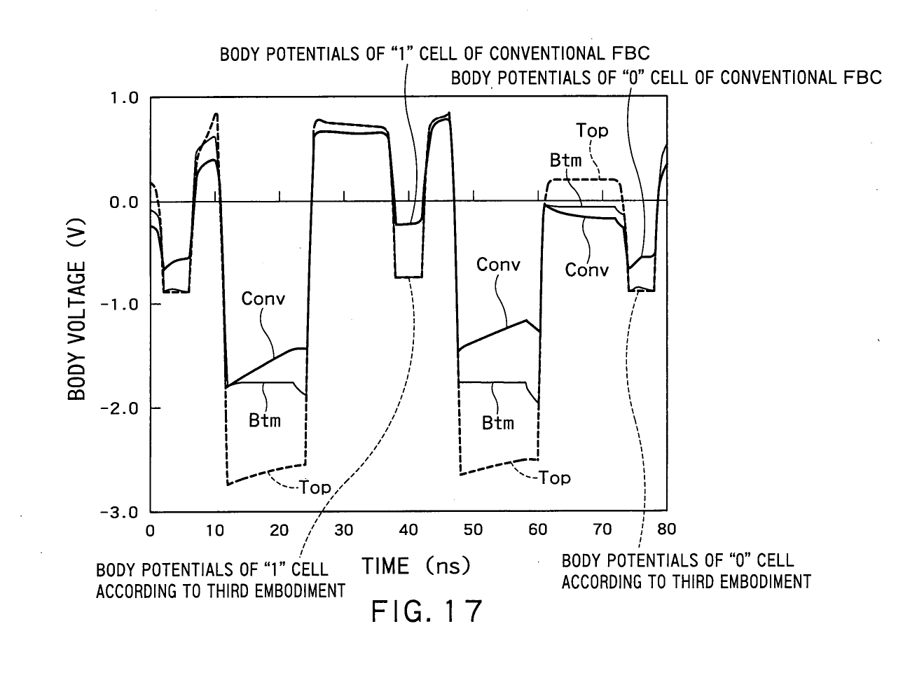

In the third embodiment, the gate electrode G faces the top surface of the first body part B1 and the side surfaces S3 and S4 of the second body part B2 as well. The side surfaces SFB1 and SFB2 of the second body part B2 do not form pn junctions with the source S and the drain D, respectively. Therefore, the ratio Cb (WL)/Cb (total) of the body-gate capacitance Cb (WL) to the total body capacitance Cb (total) is high. Further, by providing the second body part B2, the total body capacity Cb (total) can be increased without increasing the size of the memory cell MC. These effects are described with reference to FIG. 17.

FIG. 17 is a graph showing body potentials of the “0” cell and the “1” cell of the conventional FBC memory device and those of the “0” cell and the “1” cell of the FBC memory device according to the third embodiment, respectively. The graph of FIG. 17 shows a three-dimensional simulation result of executing the GIDL writing shown in FIG. 5. In this case, the body potential of the conventional memory cell is a potential on the bottom surface of the SOI layer and denoted by Conv in FIG. 17. The body potential on the bottom surface of the SOI layer in the memory cell MC according to the third embodiment is denoted by Btm and that on the top surface of the second body part B2 is denoted by Top in FIG. 17. It is assumed in the third embodiment that that the minimum size F is 80 nm, a thickness of the gate dielectric film GI is 5 nm, a thickness of the SOI layer 30 is 20 nm, a thickness of the BOX layer 20 is 15 nm, and a P-impurity concentration of the body B is 1×10¹⁷ cm⁻³. It is also assumed in the third embodiment that a width W2 of the second body part B2 is 20 nm, a height W3 thereof is 80 nm, and a P-impurity concentration thereof is 1×10¹⁷ cm³. Potentials applied to the respective electrodes of the memory cell MC are identical to those shown in FIG. 5.

In a period from 10 ns to 12 ns and that from 46 ns to 48 ns, the potential of the selected word line WL0 is lowered to the second potential VWL1. The capacitive coupling between the body B and the gate electrode G is large, so that the body potential according to the third embodiment changes sensitively corresponding to the word line potential as compared with the conventional technique. The body potential on the top surface of the second body part B2 according to the third embodiment is, therefore, lower than that according to the conventional technique.

In a period from 12 ns to 22 ns and that from 48 ns to 58 ns, data “1” is written to the memory cells MCs in all the columns. Since the body potential according to the third embodiment is lower than that according to the conventional technique, the GIDL according to the third embodiment is higher than that according to the conventional technique. Namely, the number of holes accumulated in the body B according to the third embodiment is larger than that according to the conventional technique. Since the total body capacitance Cb (total) according to the third embodiment is larger that according to the conventional technique, a change in the body potential in this 10 ns period is smaller on the top surface of the second body part B2 according to the third embodiment than that according to the conventional technique.

In a period from 62 ns to 72 ns, data “0” is written to the memory cells MCs. Since the body potential according to the third embodiment is higher than that according to the conventional technique, more holes are eliminated in the third embodiment. Since the total body capacitance Cb (total) according to the third embodiment is larger that according to the conventional technique, a change in the body potential in this 10 ns period is also smaller on the top surface of the second body part B2 according to the third embodiment than that according to the conventional technique. In a period from 38 ns to 40 ns and that from 74 ns to 76 ns, a state of the memory cell MC is changed to a data retention state. In these periods, the body potential is lowered by the capacitive coupling between the body B and the gate G. The ratio Cb (WL)/Cb (total) of the body-gate capacitance Cb (WL) to the total body capacitance Cb (total) according to the third embodiment is higher than that according to the conventional technique. Due to this, a change of the body potential according to a change in the word line potential according to the third embodiment is larger than that according to the conventional technique. Further, since the total body capacitance Cb (total) is large in the third embodiment, the body potential difference between the “0” cell and the “1” cell is small in the data retention state. For example, the body potential of the “1” cell according to the conventional technique is −0.223 V. The body potential of the “0” cell according to the conventional technique is —0.556 V. The body potential of the “1” cell according to the third embodiment is −0.748 V. The body potential of the “0” cell according to the third embodiment is −0.853 V. These numerical values indicate that the body potential difference between the “0” cell and the “1” cell is relatively small in the data retention state according to the third embodiment.

In the third embodiment, if the gate potential in the data retention state is changed from −1.7 V to −1.2 V, the body potential of the “1” cell is −0.269 V. The body potential of the “0” cell is −0.376 V. These numerical values according to the third embodiment are compared with the body potential (−0.223 V) of the “1” cell and the body potential (−0.556 V) of the “0” cell according to the conventional technique, respectively. A result of this comparison indicates that the body potential of the “0” cell according to the third embodiment can be set larger than that according to the conventional technique while keeping the body potential of the “1” cell lower than that according to the conventional technique. In other words, according to the third embodiment, the potential difference between the body B and the source S of the “0” cell can be made smaller than that according to the conventional technique while making the potential difference between the body B and the source S of the “1” cell larger than that according to the conventional technique. This signifies that the FBC memory device according to the third embodiment can reduce the electric field and GIDL in the “0” cell while sufficiently retaining the holes accumulated in the “1” cell.

The increase in the ratio Cb (WL)/Cb (total) will further be described. If the height W3 of the second body part B2 shown in FIG. 16 is large, areas of the side surfaces S3 and S4 of the second body part B2 are large. Due to this, the ratio Cb (WL)/Cb (total) of the body-gate capacitance Cb (WL) to the total body capacitance Cb (total) according to the third embodiment increases. Generally, in the data retention state, the word line potential (gate potential) is set far lower than the source line potential and the bit line potential so as to retain the holes accumulated in the body B of the “1” cell. In this case, however, the GIDL in the “0” cell increases and the data retention time for the “0” cell is reduced, accordingly. If the ratio of the body-gate capacitance Cb (WL) to the total body capacitance Cb (total) is higher, the body potential follows the word line potential more sensitively. Therefore, if the ratio Cb (WL)/Cb (total) is high as described in the third embodiment, there is no need to set the word line potential far lower than the source line potential and the bit line potential as seen in the conventional technique. In other words, the word line potential can be set close to the source line potential. By setting the word line potential close to the source line potential, the data retention time for the “0” cell can be increased while retaining the holes accumulated in the body B of the “1” cell similarly to the conventional technique. Namely, if the height W3 of the second body part B2 is made large to increase the body-gate capacitance Cb (WL), the word line potential can be made close to the source line potential in the data retention state and data retention characteristics of the “0” cell can be, therefore, improved. It is to be noted that the width W2 of the second body part B2 in the row direction has a great influence on a body-drain capacitance Cb (d) and a body-source capacitance Cb (s) but a small influence on the body-gate capacitance Cb (WL). Conversely, the height W3 of the second body part B2 has a great influence on the body-gate capacitance Cb (WL) but no influence on the body-drain capacitance Cb (d) and the body-source capacitance Cb (s).

The P-impurity concentration of the second body part B2 is set higher than that of the first body part B1. By so setting, threshold voltages to form an inversion layer on the third surface S3 and the fourth surface S4 are higher. As a result, it is difficult to form channels on the third surface S3 and the fourth surface S4, thereby increasing the capacitive coupling between the second body part B2 and the word line WL.

According to the third embodiment, since the ratio of the body-gate capacitance Cb (WL) to the total body capacitance Cb (total) is high, the body potential is sensitive to follow the word line potential. It is, therefore, possible to reduce the difference between the word line potential and the source line potential in the data retention state. This signifies that the GIDL in the “0” cell can be lowered while sufficiently retaining the holes accumulated in the body B of the “1” cell.

If the body potential difference between the “0” cell and the “1” cell is small in the data retention state, the threshold voltage difference (or drain current difference) can possibly be reduced between the data “0” and the data “1”. However, the body potential in the data retention state differs in behavior from that in the data-read operation. Due to this, it is possible to suppress deterioration in the data “0” while maintaining the drain current difference between the data “0” and the data “1” sufficiently. According to the simulation, the drain current difference during the data-read operation according to the conventional technique is 5.96 μA, and that according to the third embodiment is 5.84 μA in the case of P-impurity concentration of the second body part B2 equal to 1×10¹⁷ cm⁻³.

According to the third embodiment, it is possible to improve data retention time for both the “0” cell and the “1” cell. Furthermore, according to the third embodiment, the number of holes accumulated in the body B due to the GIDL increases despite the small body potential difference in the data retention state. Due to this, the fluctuation in the drain current during the data-read operation resulting from the fluctuation in the number of holes can be made small. This can improve the yield. Moreover, since the amplitude of the word line voltage can be reduced, the specification related to the breakdown voltages of transistors constituting a word line driver is relaxed. Moreover, according to the third embodiment, the dependence of the drain current difference during the data-read operation on the first cycle write time Tw1 is small as shown in FIG. 10. Since the ratio of the body-gate capacitance Cb (WL) to the total capacitance Cb (total) is high, the third embodiment is suited for the GIDL writing according to the first and second embodiments.

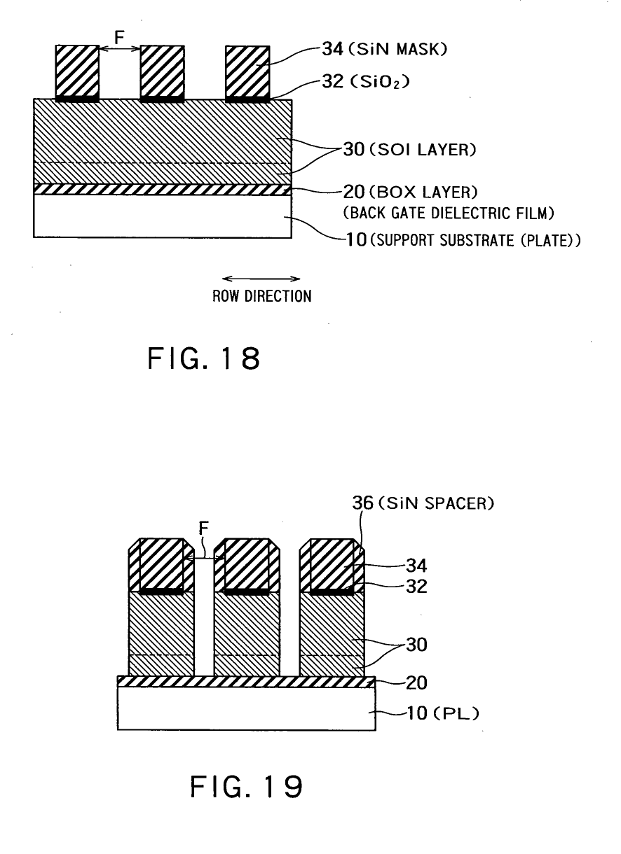

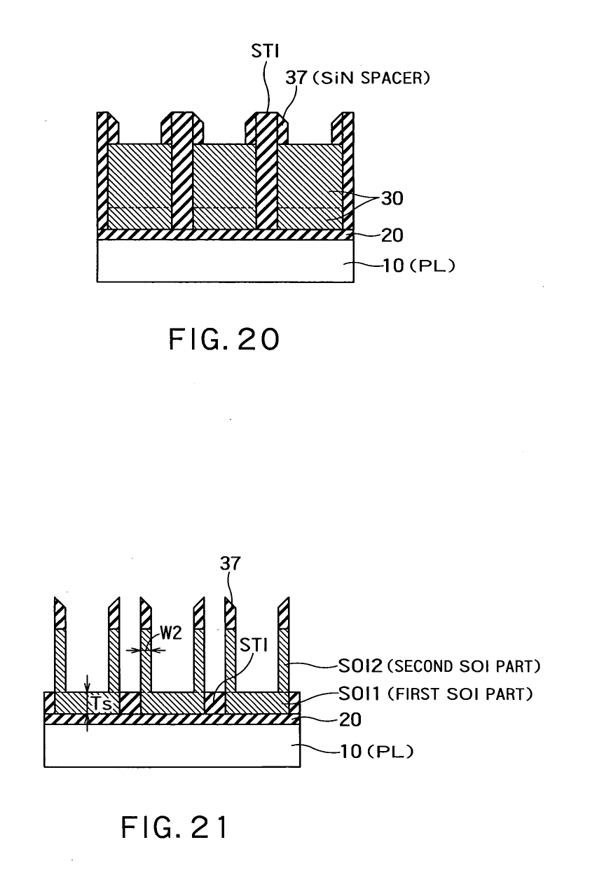

A method of manufacturing the FBC memory device according to the third embodiment is described. FIGS. 18 to 21 are cross-sectional views corresponding to FIG. 16. First, the SOI substrate is prepared. The thickness of the BOX layer 20 is about 15 nm and that of the SOI layer 30 is about 100 nm. Ions such as boron ions are implanted into an upper portion of the SOI layer 30. The P-impurity concentration of the upper portion of the SOI layer 30 is thereby set to about 1×10¹⁸ cm⁻³. As shown in FIG. 18, a silicon oxide layer 32 is formed on the SOI layer 30 and a mask material made of a silicon nitride film is deposited on the silicon oxide film 32. The mask material and the silicon oxide film 32 present in the STI regions are removed by anisotropic etching. An SiN mask 34 is thereby formed on the active areas AA.

A silicon nitride film is deposited on the SOI layer 30 and the SiN mask 34 and is then anisotropically etched. As a result, as shown in FIG. 19, an SiN spacer 36 is formed on a sidewall of the SiN mask 34. Using the SiN mask 34 and the SiN spacer 36 as a mask, the SOI layer 30 is anisotropically etched. By using the SiN spacer 36, the STI regions smaller in width than F can be formed.

An STI material made of a silicon oxide film is deposited and then flattened by CMP (chemical-mechanical polishing). At this time, a top surface of the STI material is located at a higher position than that of the top surface of the SOI layer 30. The SiN mask 34 and the SiN spacer 36 are removed by a hot phosphoric acid solution. Further, an SiN spacer 37 is formed on side surfaces of the STI material on the SOI layer 30. A width of the SiN spacer 37 defines the width W2 of the second body part B2.

As shown in FIG. 21, the SOI layer 30 is anisotropically etched by as much as a thickness of 80 nm using the SiN spacer 37 and the STI material as a mask. The thickness Ts of a first SOI part SOI1 (first body part B1) is controlled by an etch amount of this anisotropical etching. The first SOI part SOI1 becomes the first body part B1, the source S, and the drain D of each memory cell MC after all process steps. Next, the STI material is etched by wet etching. A height of a top surface of the STI material is set almost equal to that of a top surface of the first SOI part SOI1. In this manner, a second SOI part SOI2 extending in the perpendicular direction (third direction) to the surface of the supporting substrate 10 is formed. The second SOI part SOI2 becomes the second body part B2 after all process steps. At this stage, the second SOI part SOI2 extends in the column direction.

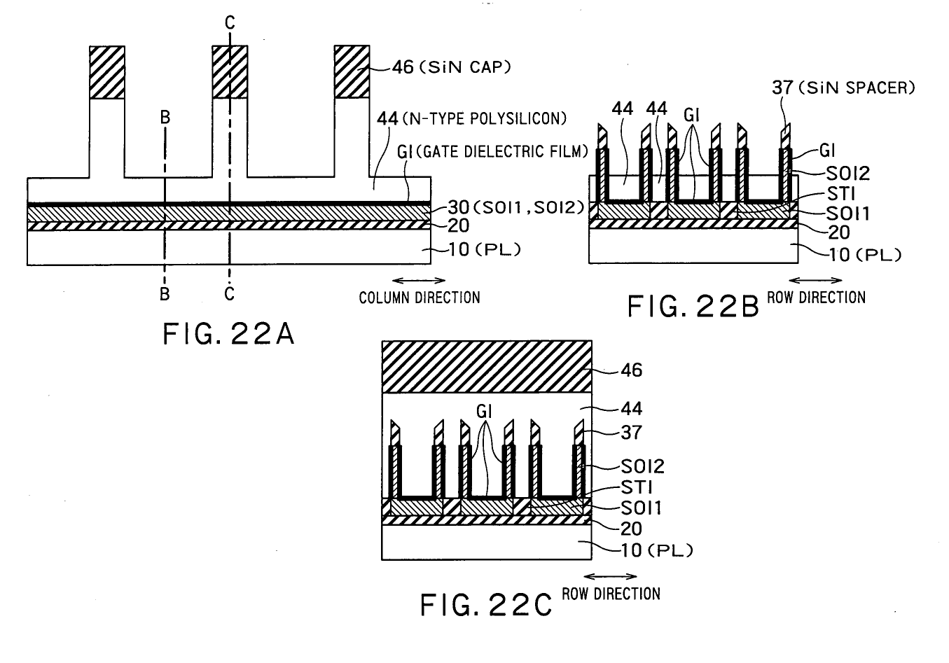

Next, P-impurities at a concentration of 1×10¹⁷ cm⁻³ to 1×10¹⁸ cm⁻³ are introduced into the SOI layer 30. By thermally oxidizing the SOI layer 30, the gate dielectric film GI is formed on the SOI layer 30 as shown in FIGS. 22A to 22C. An N polysilicon 44 and an SiN cap 46 are deposited sequentially. The SiN cap 46 is patterned into a gate electrode pattern (word line wiring pattern). Using the SiN cap 46 as a mask, the N polysilicon 44 is anisotropically etched. Each of etched top surfaces of the N polysilicon 44 is located almost at an intermediate position of each second SOI part SOI2. As a result, a structure shown in FIGS. 22A to 22C is obtained. FIG. 22A is a cross sectional view of the SOI layer 30 along the column direction (cross-sectional view corresponding to FIG. 13). FIGS. 22B and 22C are cross-sectional views taken along lines B-B and C-C of FIG. 22A, respectively.

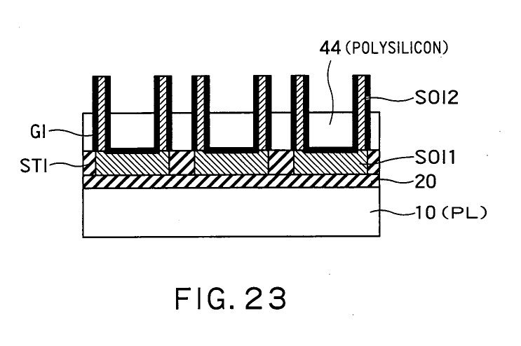

The SiN spacer 37 is anisotropically etched. At this time, a thickness and etching time of the SiN cap 46 are set so that the SiN cap 46 remains. Therefore, the cross section shown in FIG. 22C is left almost unchanged even at this stage. FIG. 23 shows a cross section subsequent to the cross section shown in FIG. 22B. Through this step, the top surface of the second SOI part SOI2 that is not covered with the SiN cap 46 and the polysilicon 44 (word line) in each source formation region and each drain formation region is exposed.

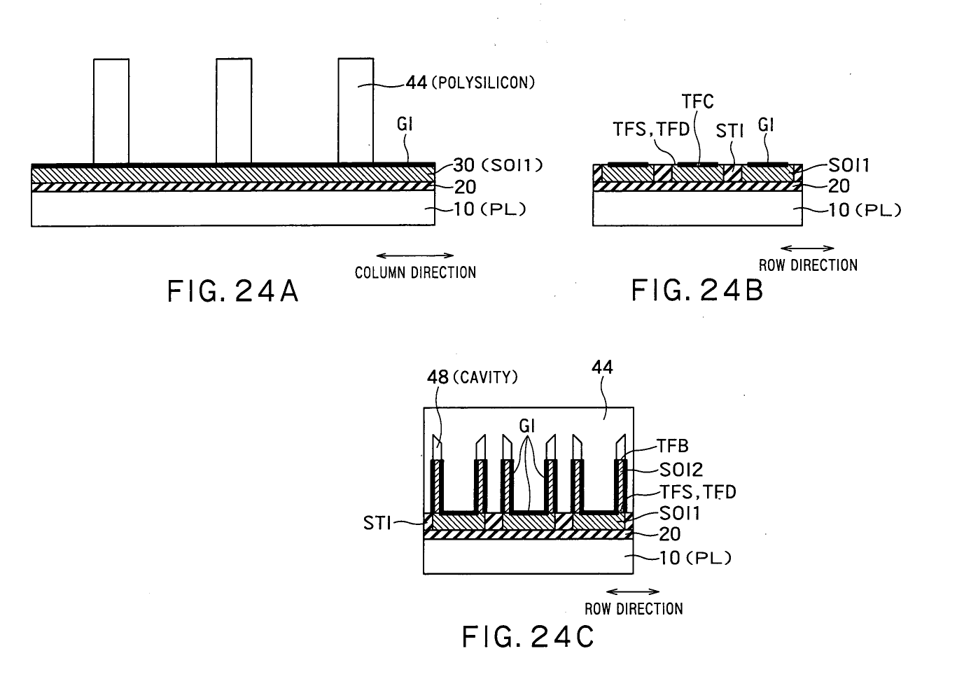

Using the SiN cap 46 as a mask, the second SOI part SOI2 and the polysilicon 44 are simultaneously etched in each source formation region and each drain formation region. As a result, as shown in FIGS. 24A to 24C, only the first SOI part SOI1 remains out of the SOI layer 30 in each source formation region and each drain formation region. In regions covered with the SiN cap 46 and the polysilicon 44 (word line), the first SOI parts SOI1 and the second SOI parts SOI2 remain. In this way, the word lines WLs, the first SOI parts SOI1, and the second SOI parts SOI2 are formed in a self-aligned fashion.

As shown in FIGS. 24B and 24C, in the cross section along the row direction in each source formation region and each drain formation region, the top surfaces TFS and TFD of the active areas AAs adjacent to the STI regions are formed lower in position than the top surface TFB of the second body part B2. If the top surfaces TFS and TFD are lower than the top surface TFB of the second body part B2, an area of the parasitic pn junction is smaller. However, even if the top surfaces TFS and TFD are formed at a higher position than that of the top surface TFC of a central portion of each active area AA, the advantages of the third embodiment are not lost.

Next, the SiN cap 46 shown in FIG. 22A and the SiN spacer 37 shown in FIG. 22C are removed. As a result, a structure shown in FIGS. 24A to 24C is obtained. As shown in FIG. 24C, a cavity 48 is formed on each second SOI part SOI2 and below the polysilicon where the SiN spacer 37 is present.

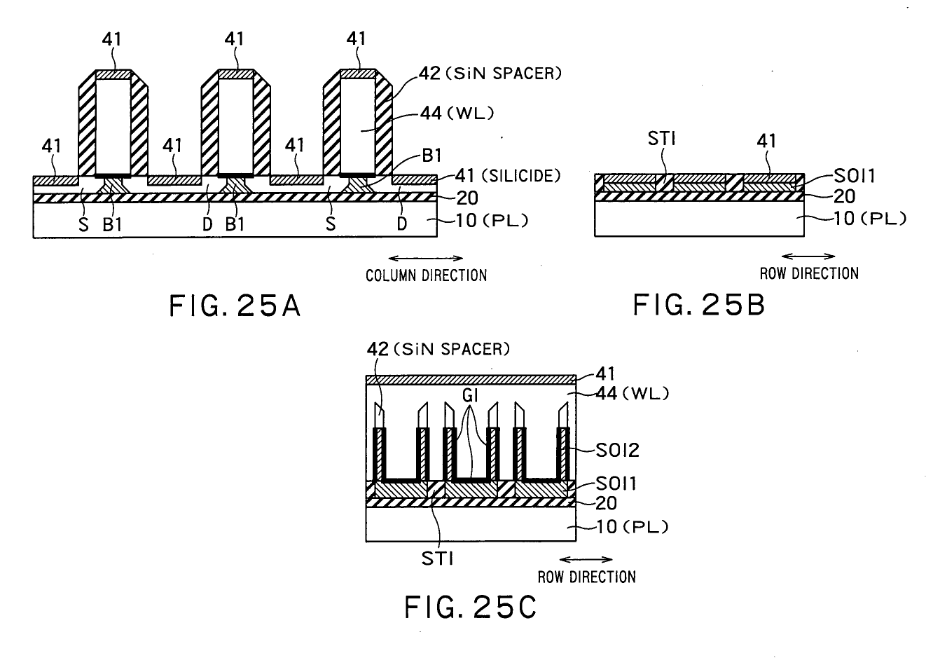

Using the word lines WLs as a mask, N-impurity ions are implanted into the source formation region and the drain formation region in each first SOI part SOI1. An extension layer is thereby formed. An SiN spacer 42 is formed on a side surface of each word line WL. At this time, the SiN spacer 42 is also buried in the cavity 48 on each second SOI part SOI2. Using the word lines. WLs and the SiN spacer 42 as a mask, N-impurity ions are implanted into the source formation region and the drain formation in each first SOI part SOI1. As a result, as shown in FIG. 25A, sources S and drains D are formed and the first body part B1 is defined between each source S and each drain D. As shown in FIGS. 25A to 25C, a silicide 41 is formed on surfaces of the word lines WLs, the sources S, and the drains D.

Thereafter, as shown in FIGS. 13 and 14, the SiN stopper 52 and the interlayer dielectric film ILD are deposited and then flattened by the CMP. Further, the source line contacts SLCs, the bit line contacts BLCs, the source lines SLs, and the bit lines BLs are formed out of such a metal material as copper, aluminum or tungsten. As a result, the FBC memory device shown in FIGS. 13 and 14 is completed.

Alternatively, the SiN cap 46 can be left on the gate electrodes G. In this alternative, the cavity 48 is not formed on the upper surface of each second SOI part SOI2 and the SiN spacer 38 remains.

With the manufacturing method according to the third embodiment, the semiconductor layer extending in the perpendicular direction (third direction) is formed, the gate electrode material is deposited to face the side surface of the semiconductor layer, and the semiconductor layer extending in the perpendicular direction and the gate electrode material in regions other than the word line regions are etched using the mask material in the word line pattern as a mask. The second body parts B2 and the word lines WLs are thereby formed in a self-aligned fashion. This manufacturing method can suppress the fluctuation in memory cell characteristics resulting from lithographic misalignment or particularly suppress the fluctuation in the body-gate capacitance.

### Fourth Embodiment

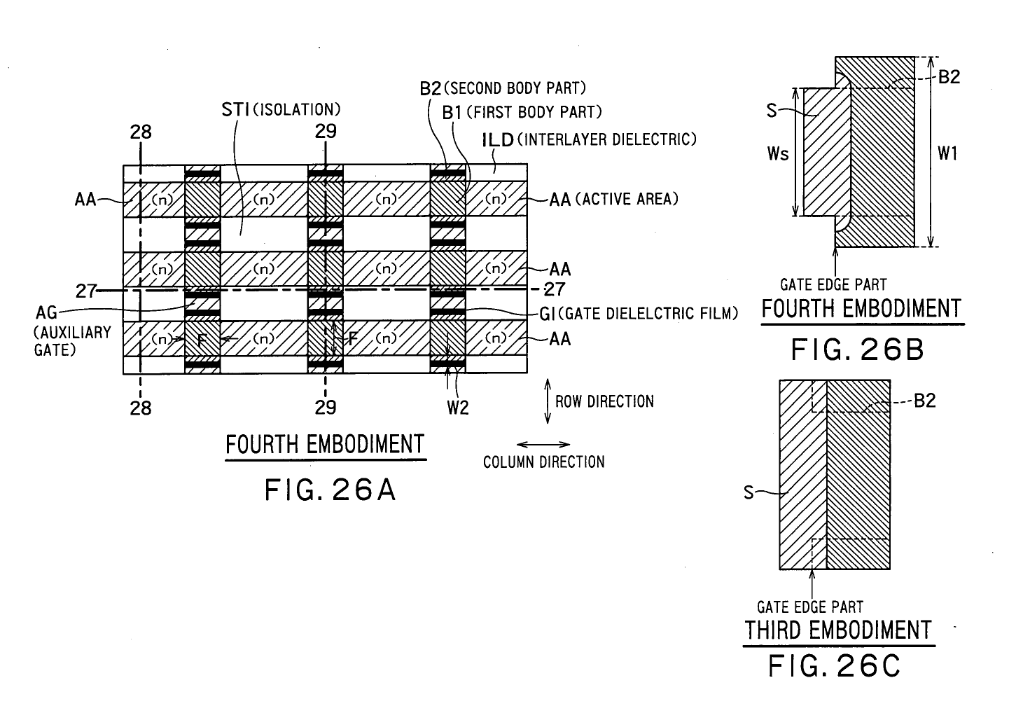

FIG. 26A is a plan view of an FBC memory device according to a fourth embodiment of the present invention. The fourth embodiment differs from the third embodiment in that the width of each of the sources S and the drains D in the row direction is smaller than that of the first body part B1. As shown in FIGS. 26B and 26C, an area of an overlap region in which the second body part B2 overlaps the source S is smaller than that according to the third embodiment. In FIGS. 26B and 26C, a region surrounded by a dotted line is a region of the second body part B2 and the area of the overlap region in which the dotted-line region overlaps the source S corresponds to the area of the pn junction formed between the second body part B2 and the source S. By setting a width Ws of the source S along the row direction smaller than a width W1 of the second body part B2 along the row direction, the area of the overlap region in which the source S overlaps the second body part B2 is made smaller as shown in FIG. 26B. The same thing is true for an area of an overlap region in which the drain D overlaps the second body part B.

To effectively perform the GIDL writing, it is preferable to form an extension layer (ends of the source S and the drain D) and to overlap the extension layer with the gate electrode G. In this case, if the extension layer reaches a heavily P-doped region in the second body part B2, a pn junction capacitance and a pn junction leakage current can be possibly increased.

In the fourth embodiment, the junction between the body B and the source S and that between the body B and the drain D are smaller in area than those according to the third embodiment. Due to this, the body-source capacitance and the body-drain capacitance are reduced, so that the ratio Cb (WL)/Cb (total) of the body-gate capacitance Cb (WL) to the total body capacitance Cb (total) is made high. As a result, the body potential according to the fourth embodiment is more sensitive to follow the word line potential than that according to the third embodiment. It is to be noted that the width of each of the source S and the drain D is F.

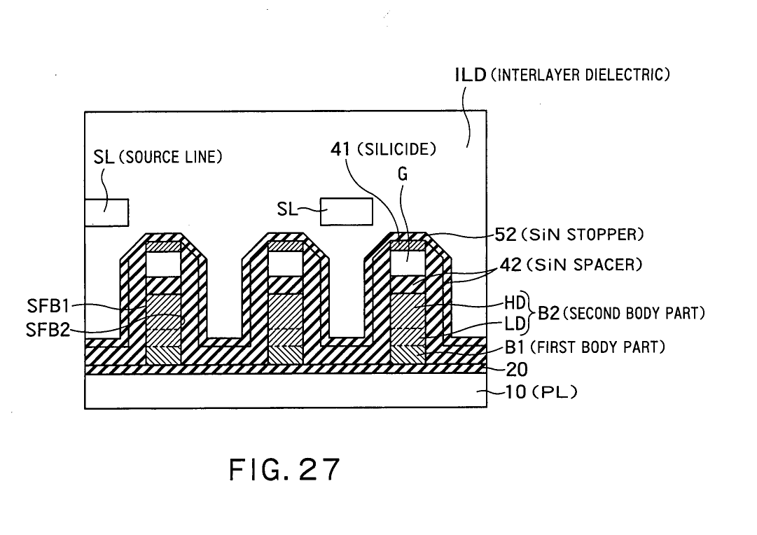

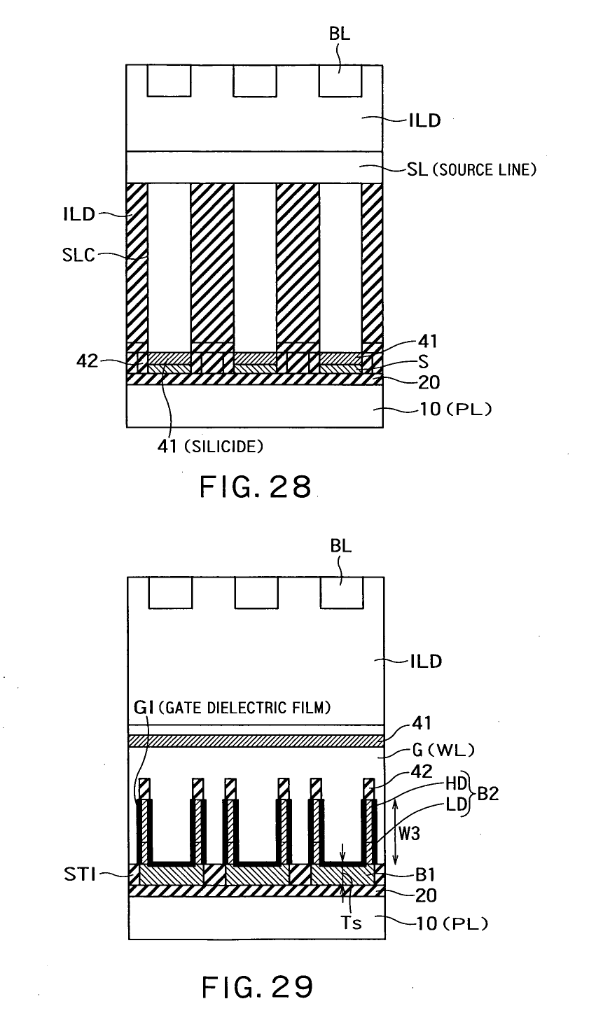

FIGS. 27 to 29 are cross-sectional views taken along lines 27-27, 28-28, and 29-29 of FIG. 26, respectively. In the fourth embodiment, only the P-impurity concentration of the upper portion of the second body part B2 is set high. As shown in FIG. 27, the second body part B2 includes a heavily doped region HD containing more P-impurities and a lightly doped region LD lower in impurity concentration than the region HD. The heavily doped region HD is formed at a higher position farther from the source S and the drain D of each memory cell MC than the lightly doped region LD. Due to this, the extension layer faces the lightly doped region LD and the pn junction capacitance and the pn junction leakage current are reduced, accordingly. The FBC memory device according to the fourth embodiment can, therefore, further reduce the GIDL in the “0” cell and the pn junction leakage current while sufficiently retaining holes accumulated in the body B of the “1” cell.

In the fourth embodiment, the heavily doped region HD is made of HSG (Hemispherical Grained) silicon. By using the HSG silicon, a surface area of the heavily doped region HD increases to further increase the capacitance between the body B and the word line WL.

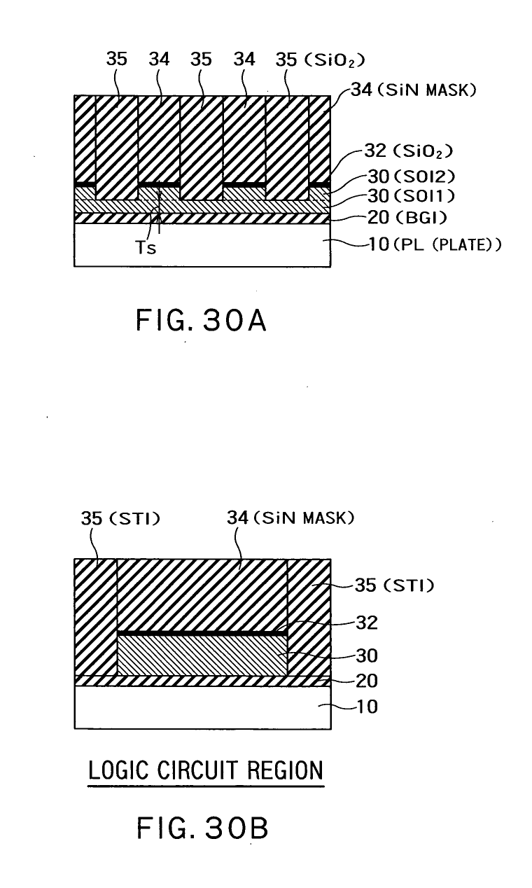

A method of manufacturing the FBC memory device according to the fourth embodiment is described. First, the SOI substrate is prepared. The thickness of the BOX layer 20 is about 15 nm and that of the SOI layer 30 is about 50 nm. Similarly to the third embodiment, a silicon oxide layer 32 and an SIN mask 34 are formed on the SOI substrate. The SiN mask 34 and the silicon oxide film 32 present in the active areas AAs are removed. In a logic circuit region, a trench is formed in each element isolation region. At this time, as shown in FIG. 30A, the upper surface of the SOI layer 30 in the active area AA is etched by anisotropic etching to thereby make the thickness of the SOI layer 30 in the region 20 nm. The thickness Ts of the first SOI part SOI1 (first body part B1) is controlled by an etch amount of this anisotropic etching.

After only the SOI layer 30 in the element isolation regions in the logic circuit region are selectively etched, a silicon oxide film 35 is filled up on the active areas AA in a memory region and in the element isolation regions in the logic circuit region. As a result, a structure shown in FIGS. 30A and 30B is obtained.

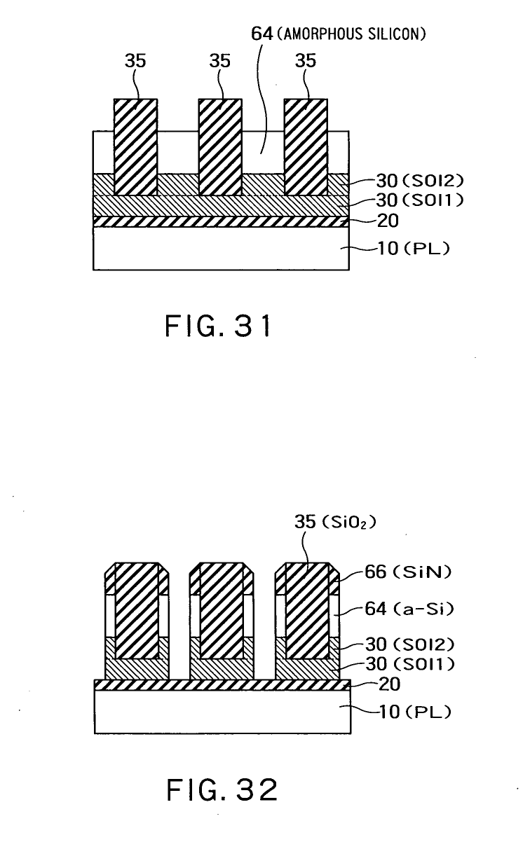

After removing the SiN mask 34 on the element isolation regions in the memory region, amorphous silicon 64 is deposited on the SOI layer 30. The amorphous silicon 64 is etched back to a lower level than a top surface of the silicon oxide film 35. At this time, a thickness of the amorphous silicon 64 is about 50 nm. As a result, a structure shown in FIG. 31 is obtained. At this time, the logic circuit region has a structure shown in FIG. 30B.

An SiN spacer 66 is formed on the amorphous silicon 64 and the side surface of the silicon oxide film 35. A width of the SiN spacer 66 decides the width W2 of the second body part B2. Using the SiN spacer 66 and the silicon oxide film 35 as a mask, the amorphous silicon 64 and the SOI layer 30 are anisotropically etched. As a result, trenches are formed on the element isolation regions as shown in FIG. 32.

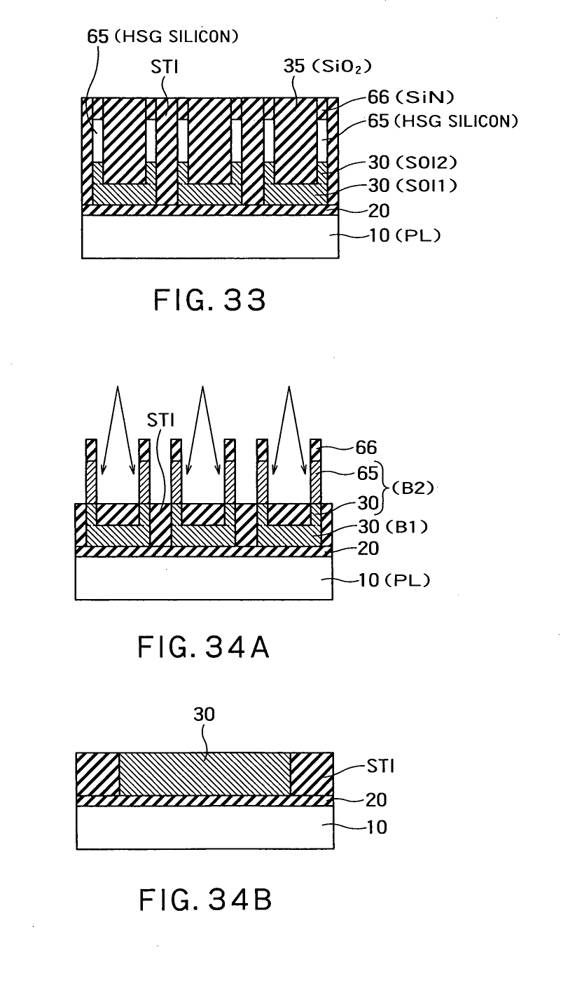

Next, annealing is performed in high vacuum at 550° C., thereby transforming the amorphous silicon 64 to silicon in an intermediate state between amorphous silicon and polysilicon. The silicon in this intermediate state is called “HSG silicon” since it is formed in a hemispherical grained state. The amorphous silicon 64 is transformed to HSG silicon 65. An STI material is filled up in the trenches on the element isolation regions by HDP (High Density Plasma). As a result, a structure shown in FIG. 33 is obtained. At this time, the logic circuit region has a structure shown in FIG. 30B.

Upper portions of the STI material and the silicon oxide film 35 are etched by wet etching. The HSG silicon 65 exposed by the wet etching becomes the heavily doped region HD. Therefore, after this etching treatment, top surfaces of the STI material and the silicon oxide film 35 are higher in position than the upper surface of the first SOI part SOU as shown in FIG. 34A. At this time, as shown in FIG. 34B, the SiN mask 34 and the silicon oxide film 32 are removed in the logic circuit region. Next, as indicated by arrows shown in FIG. 34A, P-impurity ions such as boron ions are implanted into the HSG silicon 65.

The STI material is further etched by the wet etching to set the top surface of the STI material almost equal in height to that of the first SOI part SOI1. In the memory region, boron at a concentration of 1×10¹⁷ cm⁻³ is introduced into the bodies B to adjust the threshold voltage. Likewise, impurities are appropriately introduced into the active areas in the logic circuit region to adjust the threshold voltage. It is assumed herein that the thickness of an SOI film in a channel portion in the logic circuit region is 50 nm.

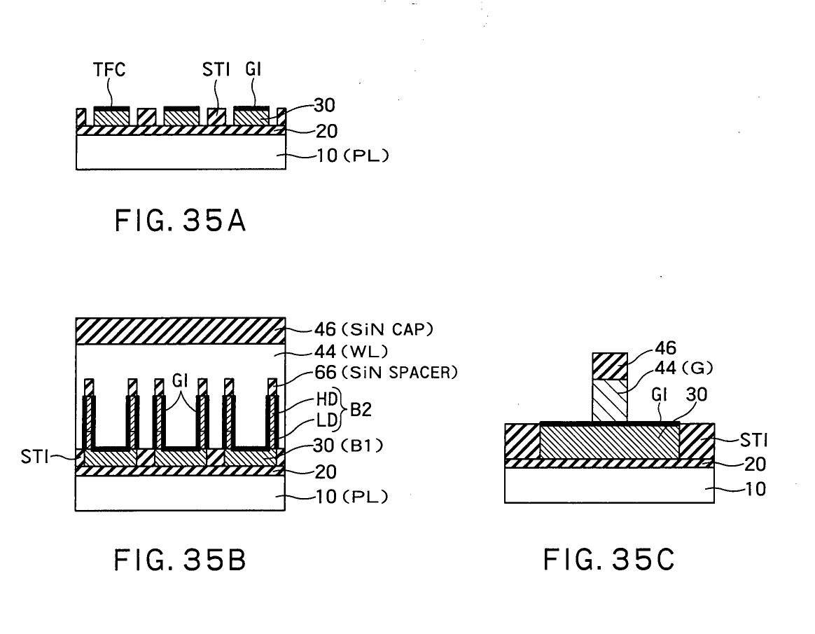

After executing similar steps as those according to the third embodiment, the gate dielectric film GI is formed and the polysilicon 44 and the SiN cap 46 are deposited. The SiN cap 46 is patterned into a gate electrode pattern (word line wiring pattern). Using the SiN cap 46 as a mask, the polysilicon 44 is anisotropically etched. In the memory region, the polysilicon is etched halfway. At this time, in the logic circuit region, the gate G made of the polysilicon 44 is formed as shown in FIG. 35C. Thereafter, the logic circuit region is covered with a resist and the polysilicon 44 and the SOI layer 30 in the memory region are etched simultaneously. The SOI layer 30 in each source formation region and each drain formation region is made equal in height to the first body part B1. In the fourth embodiment, a portion of the SOI layer 30 which portion is not covered with the gate dielectric film GI in each source formation region and each drain formation region is further etched. As a result, a structure shown in FIG. 35A is obtained. If the structure shown in FIG. 35A is compared with that shown in FIG. 24B, the difference between the third and fourth embodiments is clear. As shown in FIG. 35B, in a portion (body B) of the SOI layer 30 which portion is covered with the polysilicon 44 and the SiN spacer 66, the first body part B1 and the second body part B2 remain as they are. Thereafter, by executing the step shown in FIG. 25 in the third embodiment, the FBC memory device according to the fourth embodiment is completed.

In the fourth embodiment, the SOI substrate including the thin SOI layer 30 can be used. It is thereby possible to reduce an etch amount of the SOI layer 30. This can suppress the fluctuation in the thicken Ts of the first body part B1 shown in FIG. 29 and suppress the fluctuation in the drain current during the data-read operation.

In the fourth embodiment, the SiN mask 34 covering up the element isolation regions in the memory region and the SiN mask 34 covering up the active areas in the logic circuit region are formed at the common step. The silicon oxide film 35 filled up in the active areas in the memory region and the silicon oxide film 35 filled up in the element isolation regions in the logic circuit region are formed at the common step. In the fourth embodiment, therefore, the number of additional manufacturing steps is small.

### Fifth Embodiment

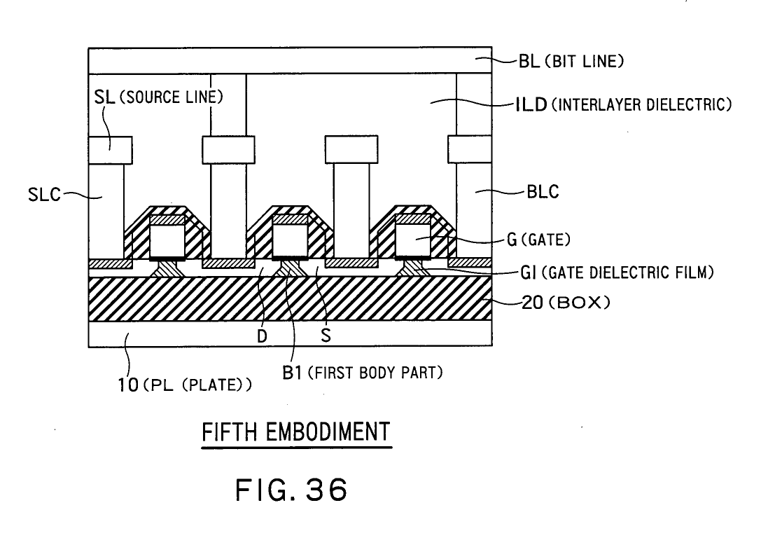

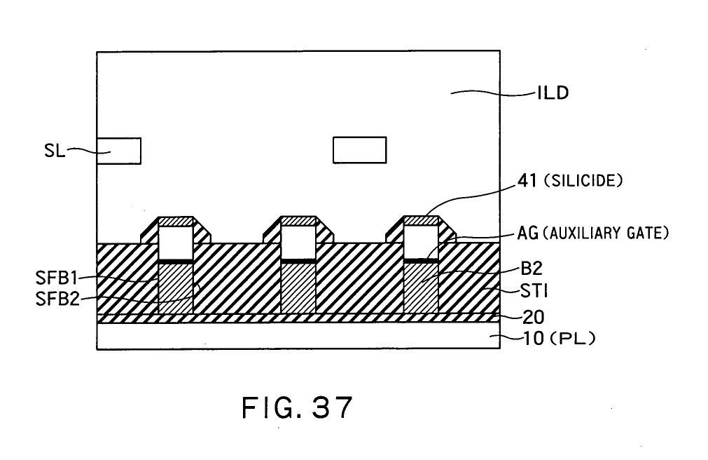

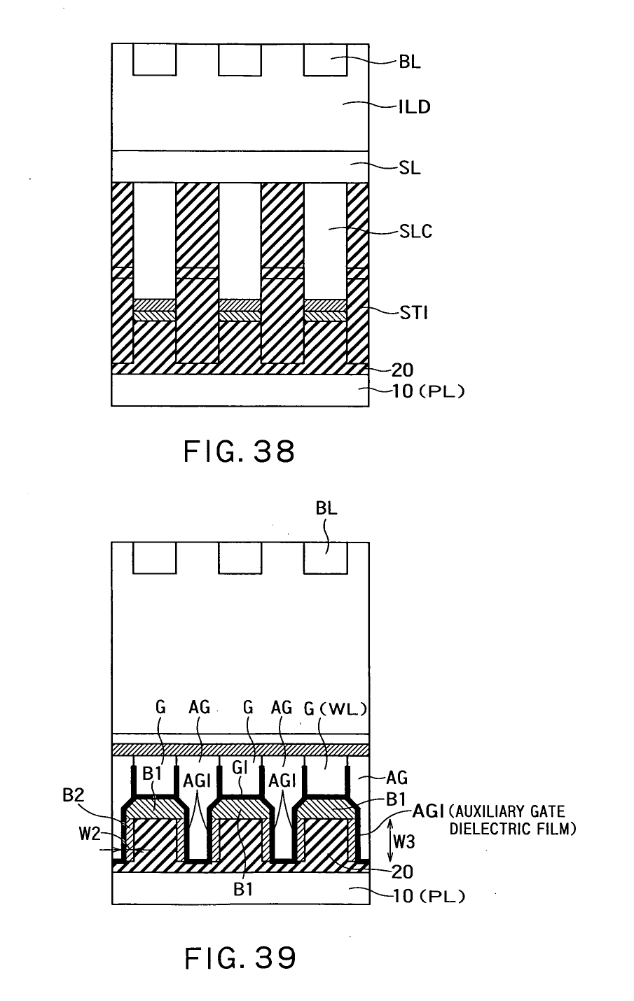

FIGS. 36 to 39 are cross-sectional views of an FBC memory device according to a fifth embodiment of the present invention. FIGS. 36 to 39 are cross-sectional views corresponding to FIGS. 13 to 16, respectively. As shown in FIG. 39, the fifth embodiment differs from the fourth embodiment in that the second body part B2 extends downward from the first body part B1. A plan view of the FBC memory device according to the fifth embodiment is similar to that shown in FIG. 26. Therefore, a region of the first body part B1 present just on the second body part B2 does not face the source S and the drain D. Due to this, similarly to the fourth embodiment, the ratio Cb (WL)/Cb (total) is high according to the fifth embodiment.

One side surface of the second body part B2 faces the auxiliary gate AG via an auxiliary gate dielectric film AGI. The other side surface of the second body part B2 faces the BOX layer 20. The top surface of the first body part B1 faces the gate electrode G (word line WL) via the gate dielectric film GI. The bottom of the first body part B1 faces the BOX layer 20. The auxiliary gate AG is connected to the gate electrode G (word line W).

In the fifth embodiment, only one side surface of the second body part B2 faces the auxiliary gate AG. Due to this, the ratio Cb (WL)/Cb (total) of the body-gate capacitance Cb (WL) to the total body capacitance Cb (total) is lower than those according to the third and fourth embodiments but higher than that according to the conventional technique.

Corners made of the top surface and side surface of the first body part B1 are rounded. It is thereby possible to prevent a high electric field from being applied from the auxiliary gate AG to the corners of the first body part B1. This can prevent breakdown of the auxiliary gate dielectric film AGI. Further, if the high electric field is generated in the corners of the first body part B1, then corner transistors low in inversion layer threshold voltage are formed and a parasitic channel current increases in the first body part B1. Dependence of the parasitic channel current on the number of holes accumulated in the body B is low. Due to this, if the parasitic channel current increases, it is difficult to discriminate data. By rounding the corners of the first body part B1, the influence of the corner transistor can be lessened. In the fifth embodiment, since the second body part B2 extends downward, the corners of the second body part B2 are formed on the first body part B1. In the third embodiment, by contrast, since the second body part B2 extends upward, it is difficult to form the corner transistors and, even if the corner transistors are formed, the influence of the corner transistors is small.

The memory cell according to the fifth embodiment is a PD-FBC. Therefore, there is no need to apply a negative voltage to the plate PL. Because of the presence of the thick BOX layer 20 between the source S and drain D and the plate PL, a parasitic capacitance between the plate PL and the source S and that between the plate PL and the drain D are small.

As a material of the auxiliary gate AG, either N polysilicon or P polysilicon can be used. If the auxiliary gate AG is made of P polysilicon, then the inversion layer threshold voltage of the second body part B2 is high to make it difficult to form a parasitic channel. The auxiliary gate dielectric film AGI can be a silicon oxide film thinner than the gate dielectric film GI or can be made of a material higher in dielectric constant than silicon oxide film. For example, the auxiliary gate dielectric film AGI can be an ONO film. The P-impurity concentration of the second body part B2 can be set higher than that of the first body part B1.

Although not so conspicuous as the third and fourth embodiments, the fifth embodiment exhibits the advantage of lowering the GIDL for the “0” cell while sufficiently retaining the holes accumulated in the “1” cell.

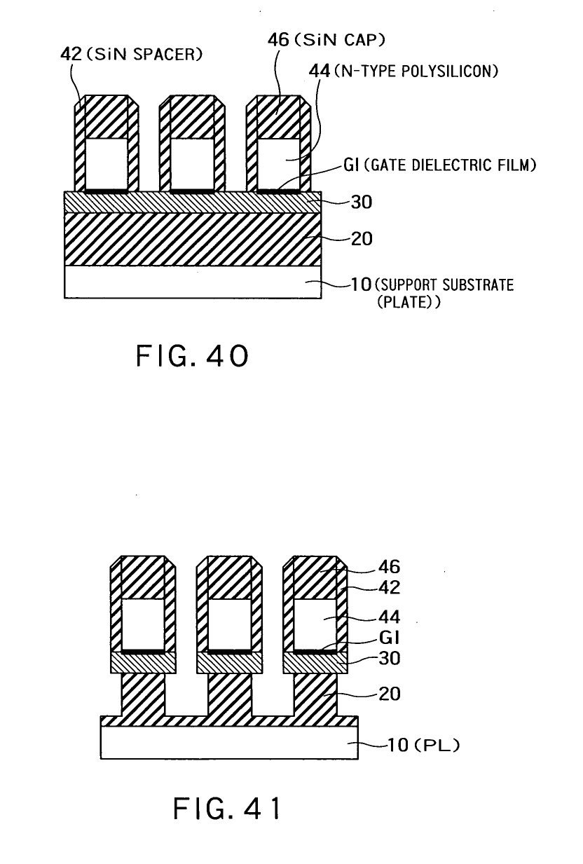

A method of manufacturing the FBC memory device according to the fifth embodiment is described. FIGS. 40 to 44 are cross-sectional views corresponding to FIG. 39. The thickness of the BOX layer 20 and that of the SOI layer of the SOI substrate used in the fifth embodiment are 150 nm and 70 nm, respectively. P-impurities at a concentration of 1×10¹⁸ cm⁻³ are introduced into the SOI layer 30. The gate dielectric film GI is formed on the SOI layer 30 by thermal oxidation. The N polysilicon 44 and the SiN cap 46 are deposited on the gate dielectric film GI. The SiN cap 46 and the polysilicon 44 are patterned into a gate electrode pattern by lithography and RIE (Reactive Ion Etching). The SiN spacer 42 is formed on the side surface of the polysilicon 44. As a result, a structure shown in FIG. 40 is obtained.

As shown in FIG. 41, using the SiN cap 46 and the SiN spacer 42 as a mask, the SOI layer 30 and the BOX layer 20 are anisotropically etched. Trenches between the adjacent gate electrodes G thereby extend in the BOX layer 20. The BOX layer 20 is etched in a horizontal direction by wet etching. An etch amount of the horizontal etching is set to almost identical to the width of the SiN spacer 42.

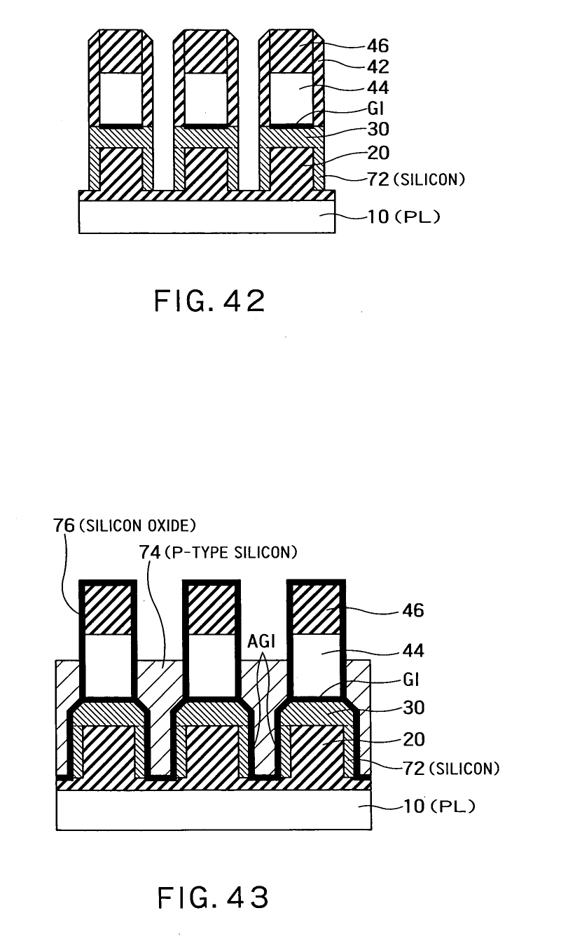

Amorphous silicon is deposited and then annealed in nitrogen atmosphere at 600° C. The amorphous silicon is thereby changed to a silicon layer by solid-phase epitaxial growth. By anisotropically etching the silicon layer, a silicon layer 72 extending downward is formed as shown in FIG. 42. Further, P-impurities at a concentration of 1×10¹⁸ cm⁻³ are introduced into the silicon layer 72. The silicon layer 72 subsequently becomes the second body part B2.

After removing the SiN spacer 42 by a hot phosphoric acid solution, a silicon oxide film 72 serving as the auxiliary gate dielectric film AGI is formed on one side surface of the silicon layer 72. As shown in FIG. 43, P polysilicon 74 as a material of the auxiliary gate AG is deposited in the trenches between the adjacent gate electrodes G. The polysilicon 74 is etched back so that a height of a top surface of the polysilicon 74 is nearly intermediate between heights of top and bottom surfaces of the polysilicon 44.

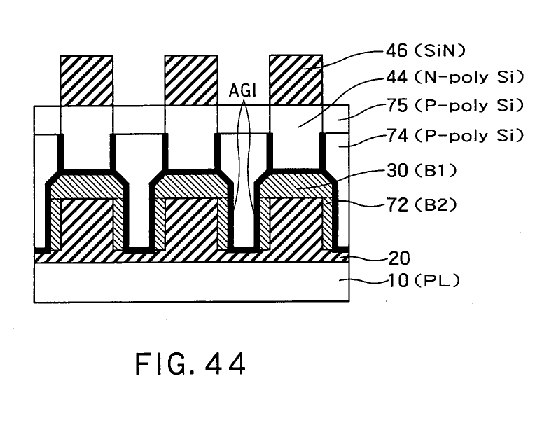

The auxiliary gate dielectric film AGI that is not covered with the polysilicon 74 is removed by wet etching. P polysilicon 75 is further deposited on the polysilicon 74. The polysilicon 75 is etched back so that a top surface of the P polysilicon 75 is equal in height to the top surface of the N polysilicon 44. As a result, a structure shown in FIG. 44 is obtained.

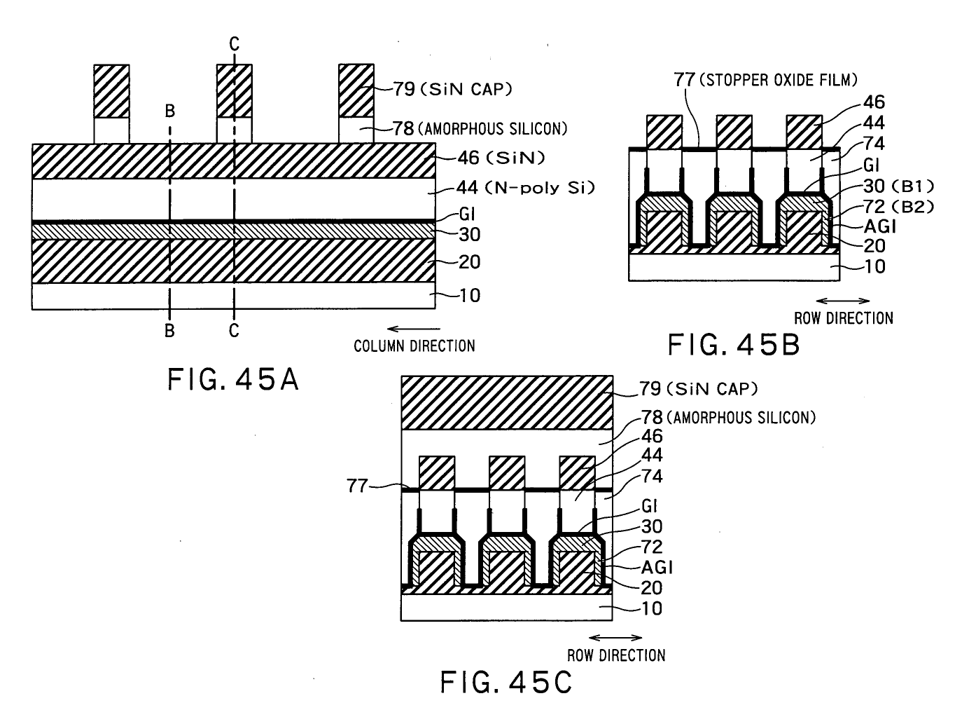

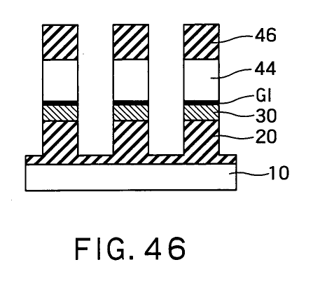

As shown in FIGS. 45B and 45C, a stopper oxide film 77 is formed on a surface of the P polysilicon 74 by thermal oxidation. As shown in FIGS. 45A and 45C, amorphous silicon 78 and an SiN cap 79 are deposited on the stopper oxide film 77 and the SiN cap 46. The SiN cap 79 and the amorphous silicon 78 are patterned into a gate electrode pattern by the lithography and the RIE. Using the SiN cap 79, the amorphous silicon 78, and the SiN cap 46 as a mask, the stopper oxide film 77, the P polysilicon 74, the auxiliary gate dielectric film AGI, and the silicon layer 72 buried in element isolation regions adjacent to source formation regions and drain formation regions are sequentially anisotropically etched. As a result, a structure shown in FIG. 45B is changed to that shown in FIG. 46. It is to be noted that the structure shown in FIGS. 45A and 45C in which the polysilicon 44 is covered with the SiN cap 46 or 79 has no change at this stage.

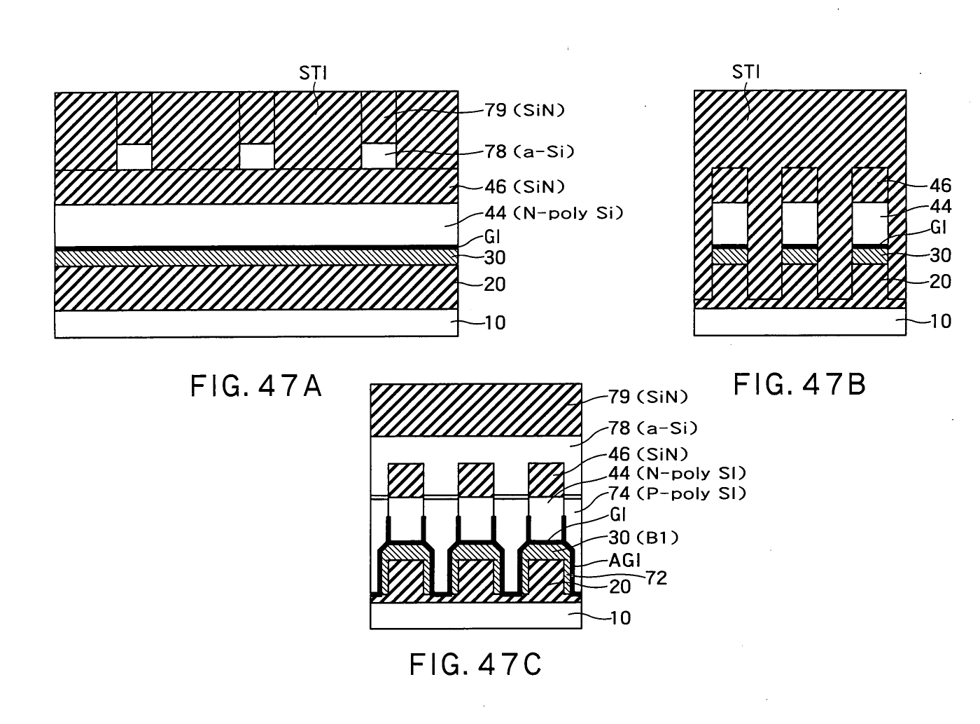

As shown in FIG. 47B, the STI material is deposited in each of the element isolation regions between one source formation region and one drain formation region. Using the SiN cap 79 shown in FIG. 47A as a stopper, the STI material is polished by the CMP.

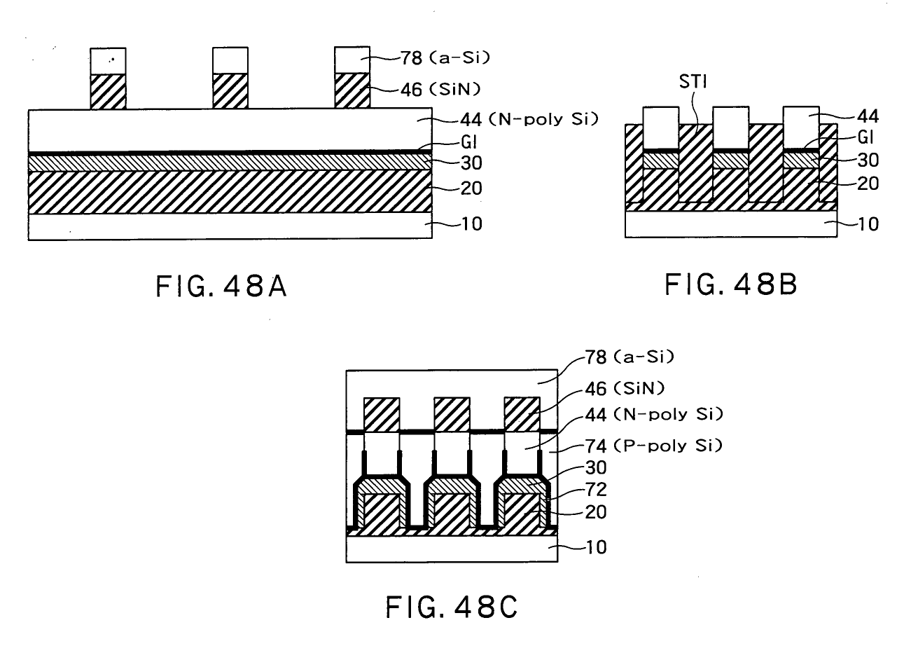

Next, the SiN cap 79 and the STI material are anisotropically etched simultaneously. At this time, as shown in FIG. 48B, the STI material in the element isolation region between each source formation region and each drain formation region is etched so that the top surface of the STI is around an intermediate portion between the top and bottom surfaces of the N polysilicon 44. As a result, the amorphous silicon 78 in a word line pattern remains.

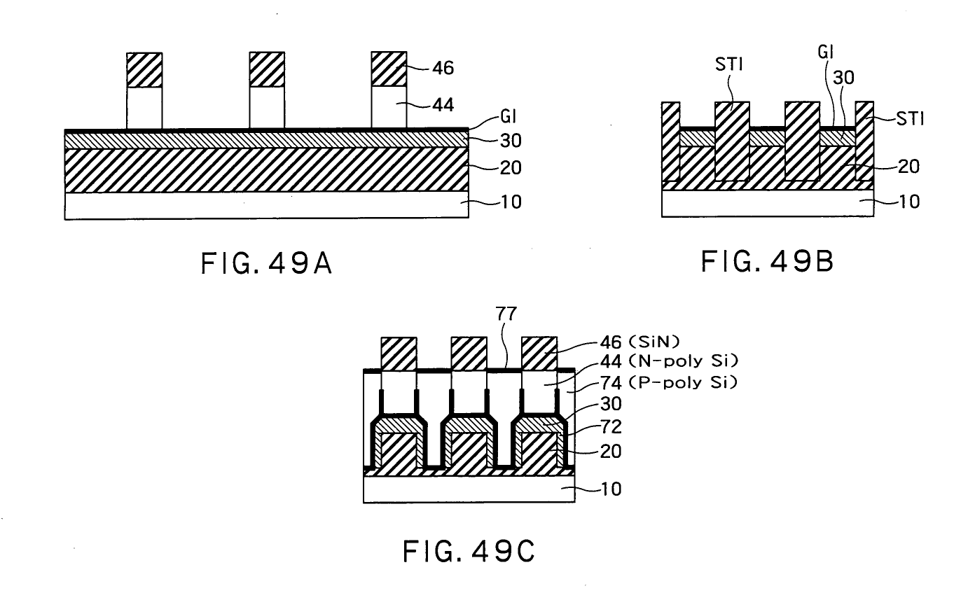

The amorphous silicon 78 and the N polysilicon 44 are then anisotropically etched simultaneously. As a result, the N polysilicon 44, the SiN cap 46, the P polysilicon 74, and the stopper oxide film 77 remain in word line formation regions as shown in FIG. 49C. Thereafter, using the N polysilicon 44 or the SiN cap 46 as a mask, the sources S and the drains D are formed. The SiN cap 46 and the stopper oxide film 77 are removed. After providing an SiN spacer on side surfaces of the polysilicon 44 (word lines WLs), the silicide 41 is formed on the polysilicon 44 (word lines WLs), the sources S, and the drains D. Furthermore, after depositing the interlayer dielectric film ILD, the source line contacts SLCs, the bit line contacts BLCs, the source lines SLs, and the bit lines BLs are formed. As a result, the FBC memory device according to the fifth embodiment is completed.

### Sixth Embodiment

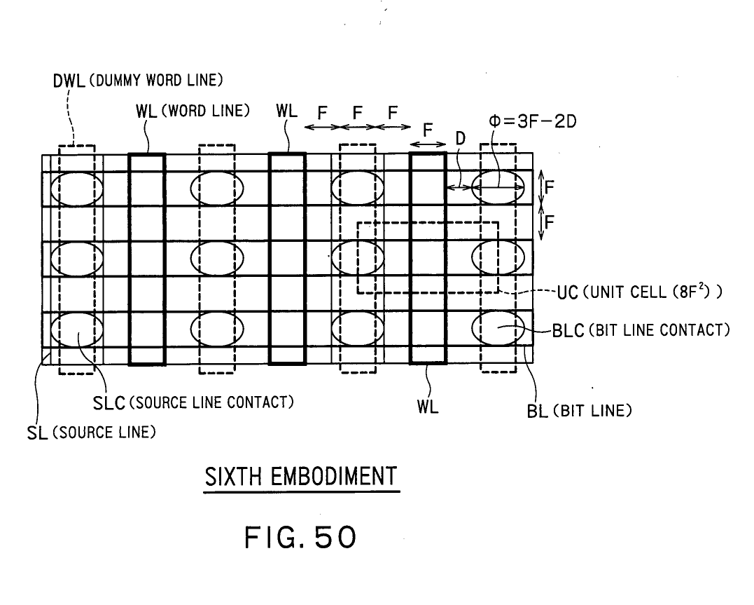

FIG. 50 is a plan view showing wiring arrangement of an FBC memory device according to a sixth embodiment of the present invention. In the sixth embodiment, the source line contacts SLCs and the bit line contacts BLCs are formed into ellipses each having a major axis in the column direction. If the distance between one word line WL and one source line contact SLC or bit line contact BLC is D, the major axis Φ of each of the source line contacts SLCs and the bit line contacts BLCs is expressed as 3F-2D.

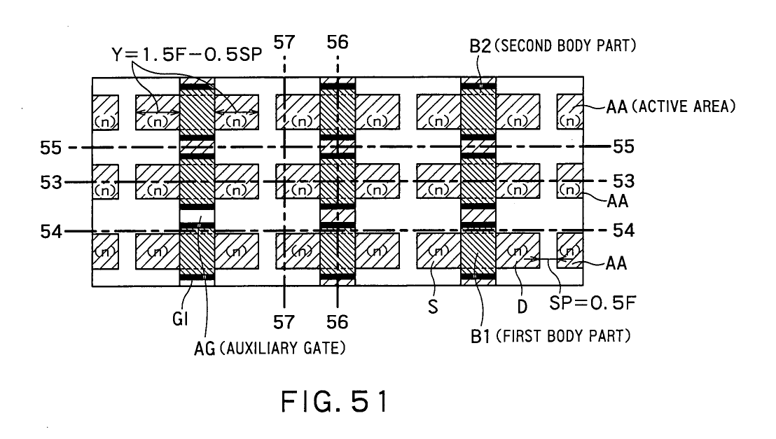

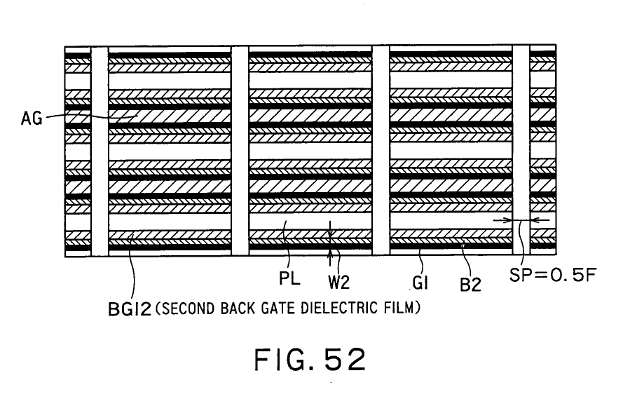

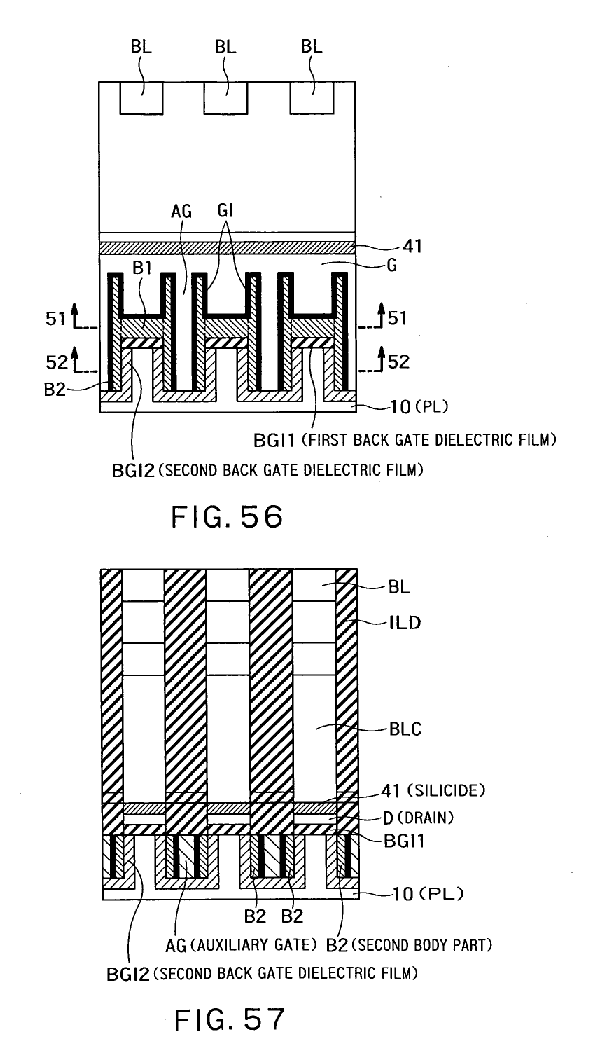

FIG. 51 is a plan view taken along a line 51-51 of FIG. 56. FIG. 52 is a plan view taken along a line 52-52 of FIG. 56. As shown in FIG. 51, the active area AA (SOI layer 30) is cut among the memory cells MCs adjacent in the column direction. A width of a space SP between the two memory cells MCs adjacent in the column direction is, for example, 0.5 F.

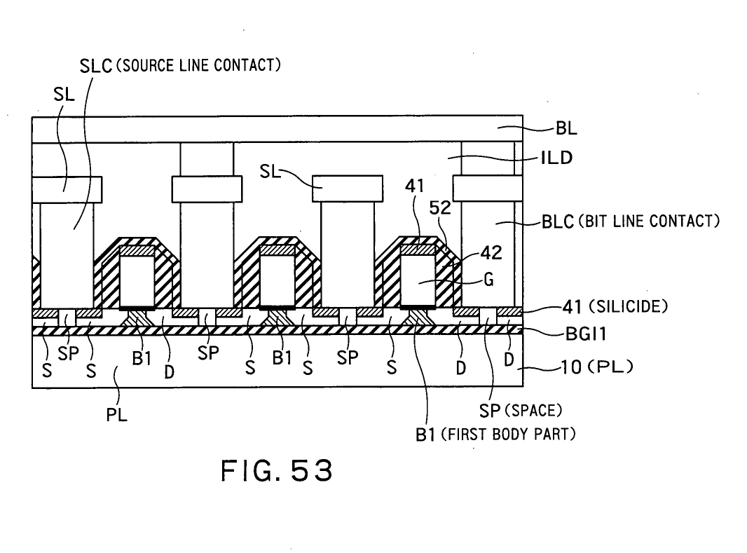

FIGS. 53 to 57 are cross-sectional views taken along lines 53-53, 54-54, 55-55, 56-56, and 57-57 of FIG. 51, respectively. As shown in FIG. 53, according to the sixth embodiment, each space SP is provided between the drain D and the source S of the two memory cells MCs adjacent in the column direction. Due to this, the source S and the drain D are separately provided for each memory cell MC. However, each source line contact SLC or each bit line contact BLC is shared between the two memory cells MCs adjacent in the column direction. This is why the source line contacts SLCs and the bit line contacts BLCs are formed into ellipses each having the major axis in the column direction as shown in FIG. 50 so as to connect a plurality of sources S and drains D separately provided to correspond to the memory cells MCs by common contacts, respectively.

Since the memory cells adjacent in the column direction are separated by the spaces SP, respectively, bipolar disturbance does not occur in the sixth embodiment. The bipolar disturbance is a phenomenon that data is destroyed by passing the holes accumulated in the body B of a certain memory cell MC through the source S or the drain D and flowing into the memory cell MC adjacent to the certain memory cell MC.

Furthermore, in the sixth embodiment, a plane shape of each of the source line contacts SLCs and the bit line contacts BLCs is an ellipse having a major axis in the column direction. Due to this, each source line contact SLC or bit line contact BLC can be connected to a plurality of adjacent source layers S or a plurality of adjacent drain layers D in common at low resistance.

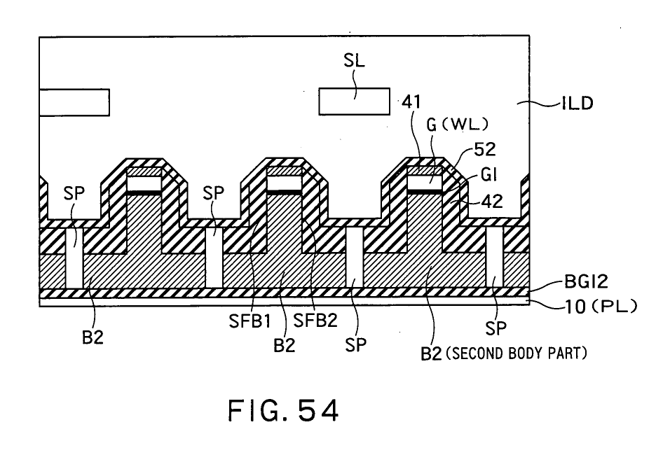

As shown in FIG. 54, each second body part B2 has an inverted-T-shaped cross section in the direction perpendicular to the row direction. A width of the upper portion of the second body part B2 in the column direction is equal to that of each gate electrode G shown in FIG. 53. A width of the lower portion of the second body part B2 is equal to a width of the spaces adjacent in the column direction (width of the active area AA in the column direction).

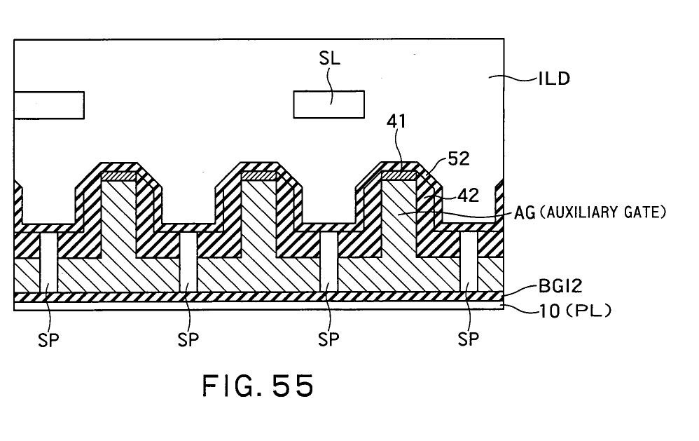

As shown in FIG. 55, each auxiliary gate AG has an inverted T-shaped cross section in the direction perpendicular to the row direction similarly to the second body part B2. A width of a lower portion and a width of an upper portion of the auxiliary gate AG can be set equal to those of the second body part B2, respectively.

As shown in FIG. 56, in the cross section perpendicular to the column direction, each body B has an H shape. More specifically, the first body part B1 of the body B is adjacent to the source S and the drain D in the column direction as shown in FIGS. 51 and 56 and connected to the second body part B2 in the row direction as shown in FIGS. 51 to 56. The second body part B extends in both upward and downward directions of the side surfaces of the first body part B1 oriented in the row direction.

The top surface of the first body part B1 faces one gate electrode (word line WL) via the gate dielectric film GI. The bottom surface of the first body part B1 faces the plate PL via a first back gate dielectric film BGI1. A side surface (fourth surface) of the lower portion of the second body part B2 opposite to the first body part B1 faces the gate electrode G (word line WL) via the gate dielectric film GI. Both side surfaces (third and fourth surfaces) of the upper portion of the second body part B2 face the gate electrode G (word line WL) via the gate dielectric film GI. Another side surface of the lower portion of the second body part B2 oriented in the word line direction faces the plate PL via a second back gate dielectric film BGI2.

As shown in FIG. 57, the lower portion of the second body part B2 extends to downward of the bit line contacts BLCs. One side surface of the lower portion of the second body part B2 entirely faces the auxiliary gates AGs or the gate electrodes Gs. As clear from FIG. 51, each drain D is adjacent to the first body part B1 but separate from the second body part B2. Therefore, the ratio Cb (WL)/Cb (total) increases without increasing the parasitic PN junction capacitance and the pn junction leakage current.

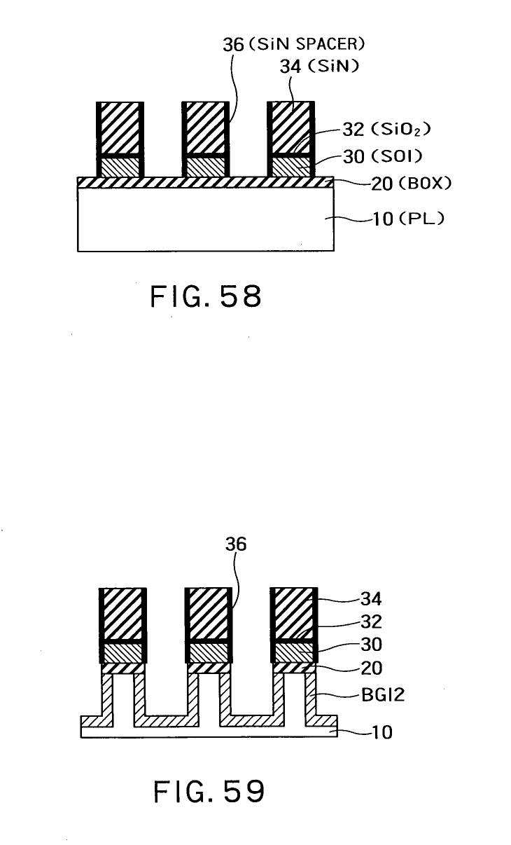

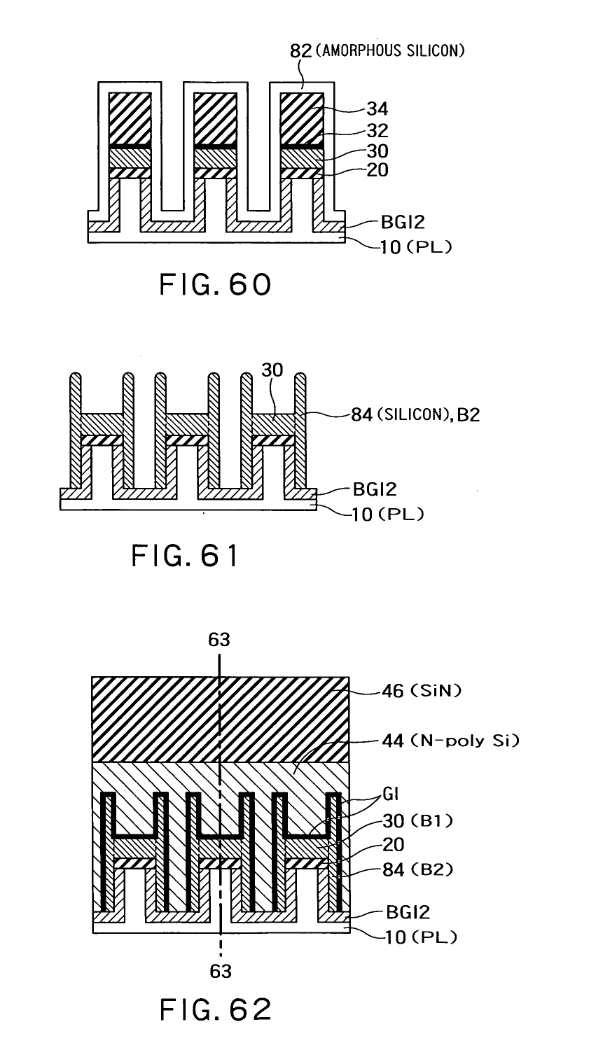

A method of manufacturing the FBC memory device according to the sixth embodiment is described. FIGS. 58 to 62 are cross-sectional views corresponding to FIG. 56. First, the SOI substrate is prepared. The thickness of the BOX layer 20 and that of the SOI layer 30 of the SOI substrate are 15 nm and 20 nm, respectively. The silicon oxide film 32 is formed on the SOI layer 30. The SiN mask 34 is deposited on the silicon oxide film 32. The SiN mask 34, the silicon oxide film 32, and the SOI layer 30 present in element isolation regions are removed by anisotropic etching. As shown in FIG. 58, the SiN spacer 36 is formed on side surfaces of the SiN mask 34, the silicon oxide film 32, and the SOI layer 30.

Using the SiN mask 34 and the SiN spacer 36 as a mask, the BOX layer 20 and the supporting substrate 10 are anisotropically etched. As a result, as shown in FIG. 59, trenches each having a depth of about 80 nm from the surface of the supporting substrate 1 are formed. By thermally oxidizing inside surfaces of the trenches, the second back gate dielectric film BGI2 having a thickness of 15 nm is formed.

After removing the SiN spacer 36, amorphous silicon 82 is deposited on side surfaces of the SOI layer 30, side surfaces of the SiN mask 34, side surfaces of the BOX layer 20, and the back gate dielectric film BGI2. The amorphous silicon 82 is annealed at about 600° C. for a few hours. By doing so, the amorphous silicon 82 is monocrystallized upward and downward from the side surfaces of the SOI layer 30 by solid-phase epitaxial growth. As a result, as shown in FIG. 61, the amorphous silicon 62 is changed to monocrystalline silicon 84 connected to the SOI layer 30. The silicon 84 present on the bottom of the trenches is removed by anisotropic etching to thereby isolate the silicon 84 by STI regions.

After removing the SiN mask 34 and the silicon oxide film 32, annealing is performed in hydrogen atmosphere. Upper corners of the silicon 84 are thereby rounded. Further, P-impurities are introduced into the silicon 84. The SOI layer 30 serves as the first body parts B1 and the silicon 84 serves as the second body parts B2.

As shown in FIG. 62, the gate dielectric film GI is formed on the top surface of the SOI layer 30 and side surfaces of the silicon 84. The N polysilicon 44 and the SiN mask 46 are deposited on the gate dielectric film GI. At this time, the N polysilicon 44 is filled up in the trenches in the element isolation regions. The polysilicon 44 present in the trenches serve as the auxiliary gates AGs.

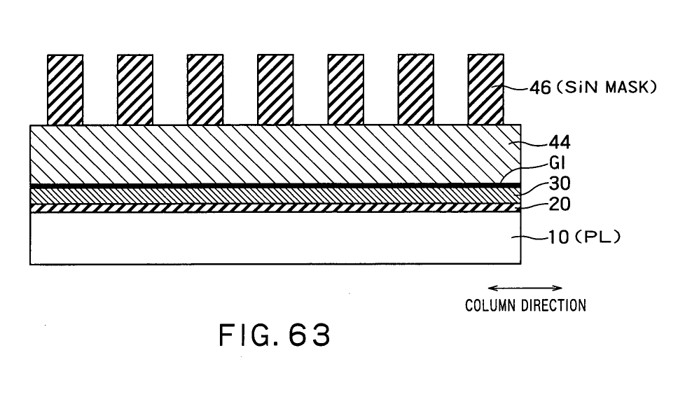

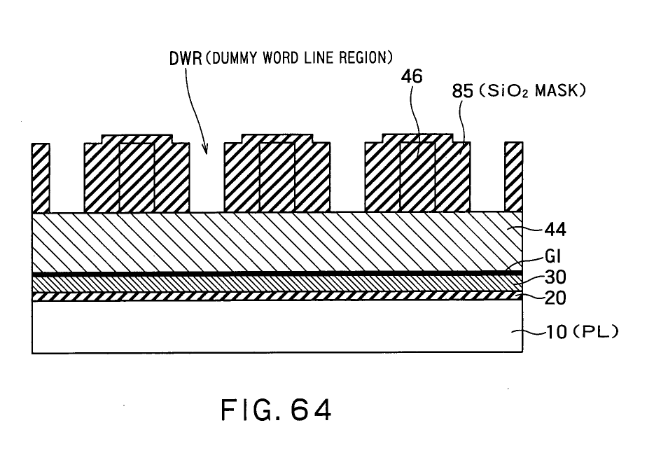

FIG. 63 is a cross-sectional view taken along a line 63-63 of FIG. 62 in the column direction. The SiN mask 46 is patterned into a gate electrode (word line) pattern. An oxide film mask 85 is buried among gaps of the SiN mask 46. The SiN mask 46 present in dummy word line regions DWRs is removed. As a result, a structure shown in FIG. 64 is obtained.

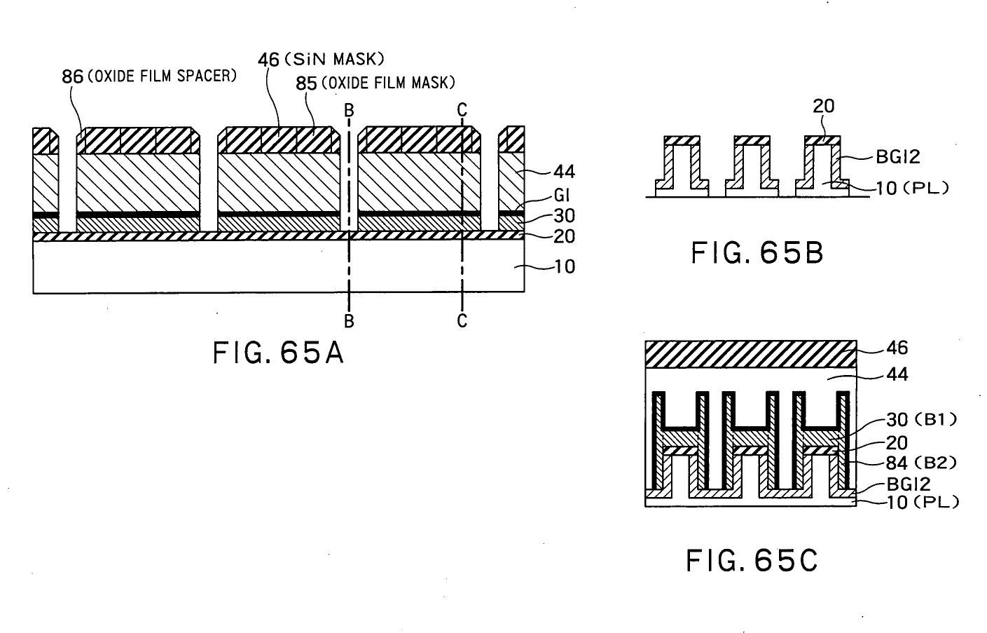

The oxide film mask 85 is flattened by the CMP. Thereafter, as shown in FIG. 65A, an oxide film spacer 86 is formed on side surfaces of the oxide film mask 85. A width of the oxide film spacer 86 in the column direction is 0.25 F. Accordingly, a space of each dummy word line region DWR is 0.5 F. Using the oxide film mask 85, the oxide film spacer 86, and the SiN mask 46 as a mask, the polysilicon 44, the gate dielectric film GI and the SOI layer 30 in the dummy word line regions DWR are removed. At this time, cross sections taken along lines B-B and C-C of FIG. 65A are shown in FIGS. 65B and 65C, respectively.

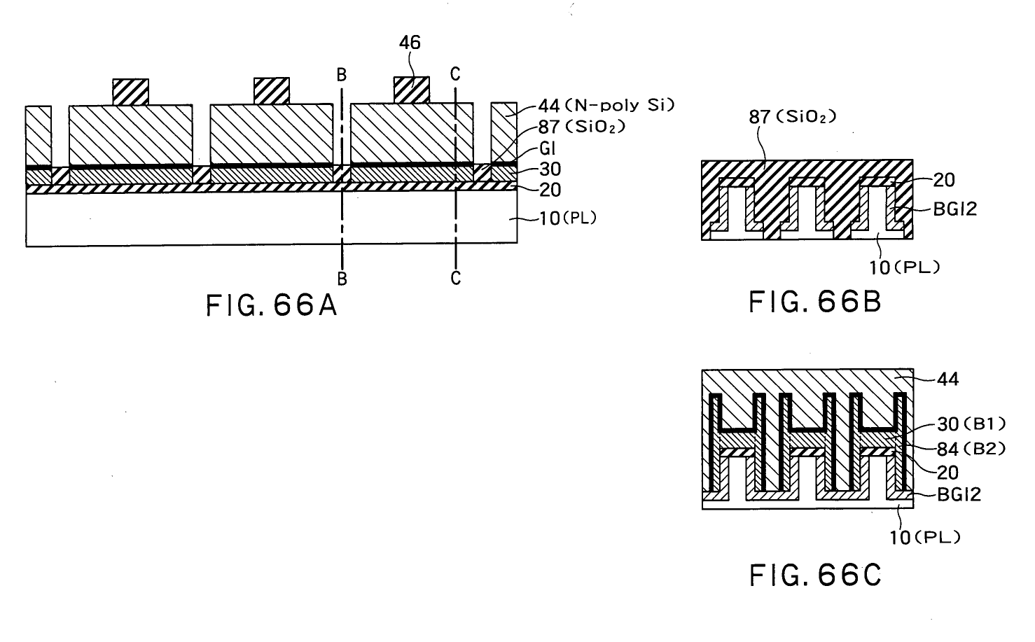

Next, a silicon oxide film 87 is deposited on the dummy word line regions DWRs. By etching back the silicon oxide film 87, the oxide film mask 85 and the oxide film spacer 86 are removed and a top surface of the oxide film 87 is set equal in height to that of the SOI layer 30. As a result, a structure shown in FIGS. 66A to 66C is obtained. FIGS. 66B and 66C are cross-sectional views taken along lines B-B and C-C of FIG. 66A, respectively. With reference to FIG. 66B, it is understood that the silicon oxide film 87 is filled up in the dummy word line regions DWRs.

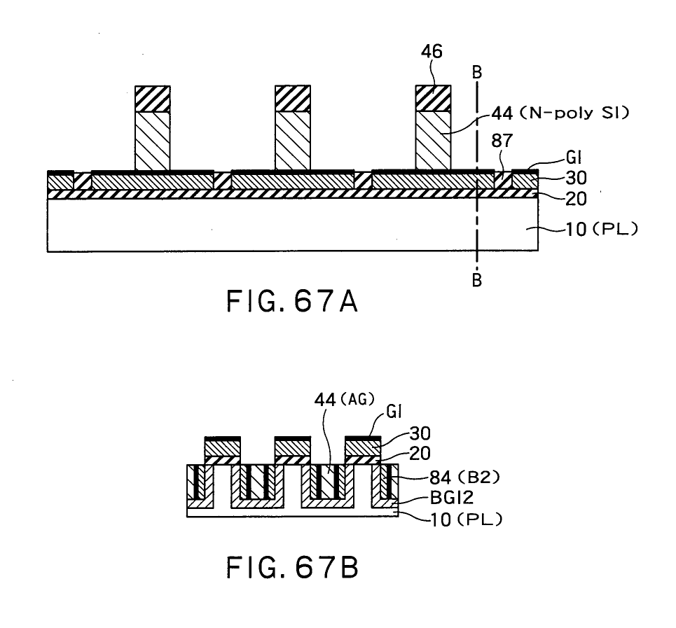

Using the SiN mask 46 as a mask, anisotropic etching is performed in order of polysilicon, oxide film, and polysilicon. FIG. 67A is a cross-sectional view continuous to that shown in FIG. 66A. As shown in FIG. 67A, the polysilicon 44 is patterned into the gate electrode pattern by this three-step anisotropic etching. FIG. 67B is a cross-sectional view taken along a line B-B of FIG. 67A (and subsequent to the cross-sectional view shown in FIG. 66C). First, the polysilicon 44 is etched to a central portion. The gate dielectric film GI on the top surfaces of the second body parts B2 adjacent to the source formation regions and the drain formation regions are exposed. The gate dielectric film GI is removed. As a last step, the polysilicon 44 and the second body parts B2 are etched. The top surfaces of the second body parts B2 in the source formation regions and the drain formation regions are thereby etched to lower positions than those of the bottom surfaces of the first body parts B1. As a result, as shown in FIG. 67B, each second body part B2 is separated from one source S and one drain D. Furthermore, the top surface of each auxiliary gate AG is lower than the bottom surface of each first body part B1.

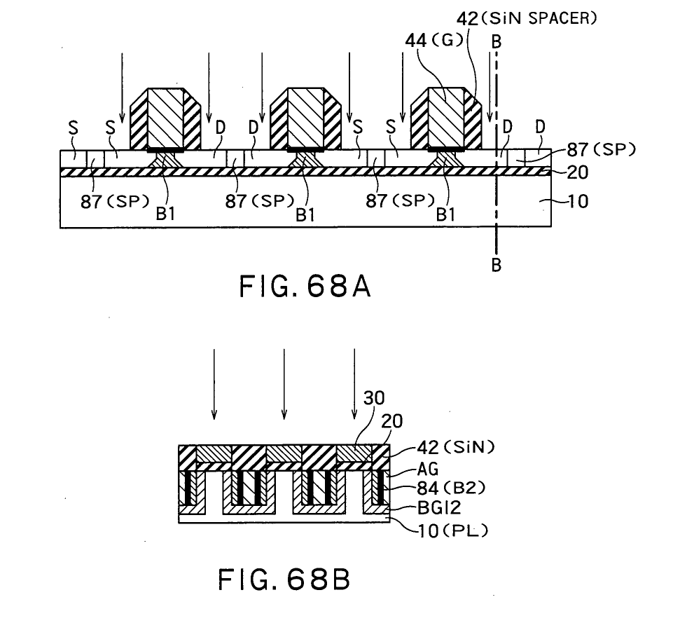

After removing the SiN mask 46, the SiN spacer 42 is formed on sidewalls of the gate electrodes G as shown in FIG. 68A. As shown in FIG. 68B, the SiN spacer 52 is also formed on the second body parts B2 and the auxiliary gates AGs. Using the gate electrodes G and the SiN spacer 42 as a mask, N-impurity ions are implanted. The sources S and the drains D are thereby formed. The N-impurity ions are not implanted into the second body parts B2. Thereafter, the silicide 41 is formed on the polysilicon 44 (word lines WLs), the sources S, and the drains D. After depositing the interlayer dielectric film ILD, the source line contacts SLCs, the bit line contacts BLCs, the source lines SLs, and the bit lines BLs are formed. As a result, the FBC memory device according to the sixth embodiment is completed.

### Seventh Embodiment

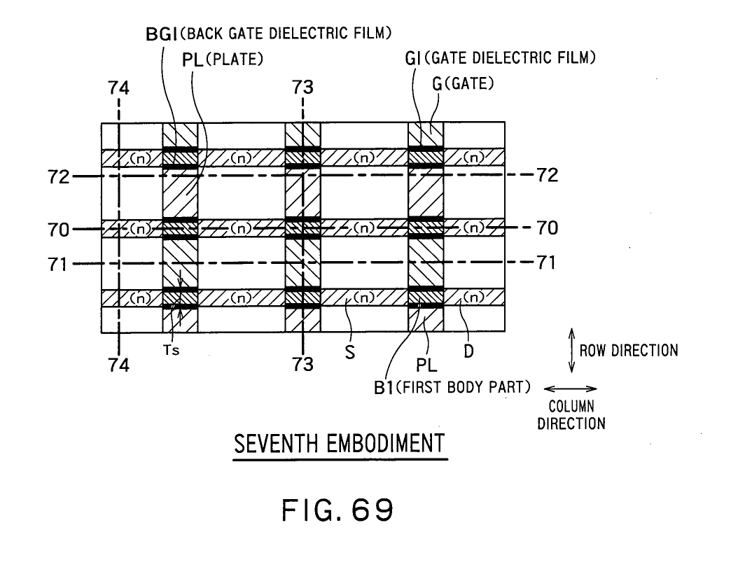

FIG. 69 is a plan view of an FBC memory device according to a seventh embodiment of the present invention. In the seventh embodiment, one side surface (the first surface) of the first body part B1 in the row direction faces one gate electrode G via the gate dielectric film GI and the other side surface (second surface) thereof faces the plate PL via the back gate dielectric film BGI. Side surfaces of the first body part B1 in the column direction face the source S or the drain D.

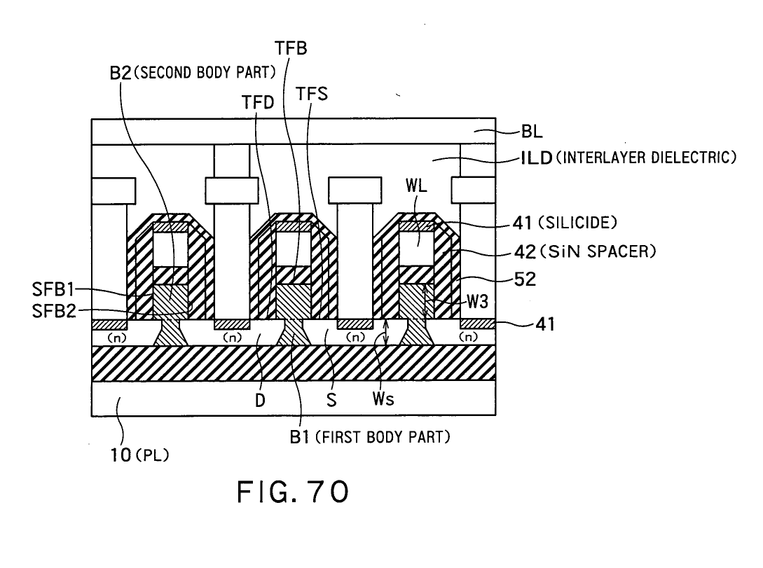

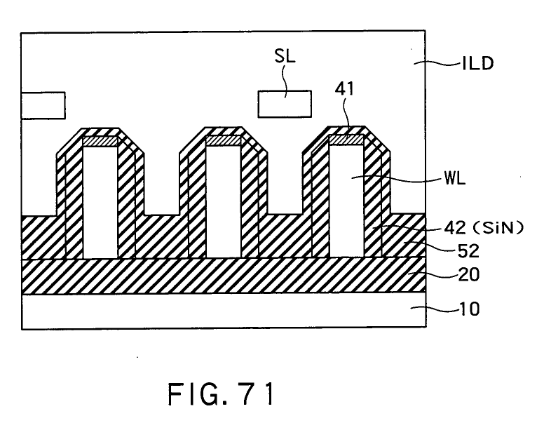

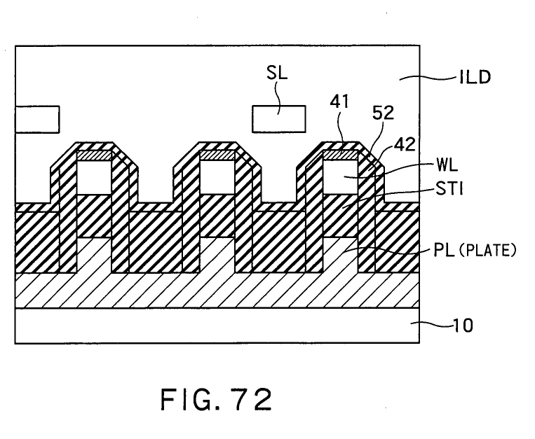

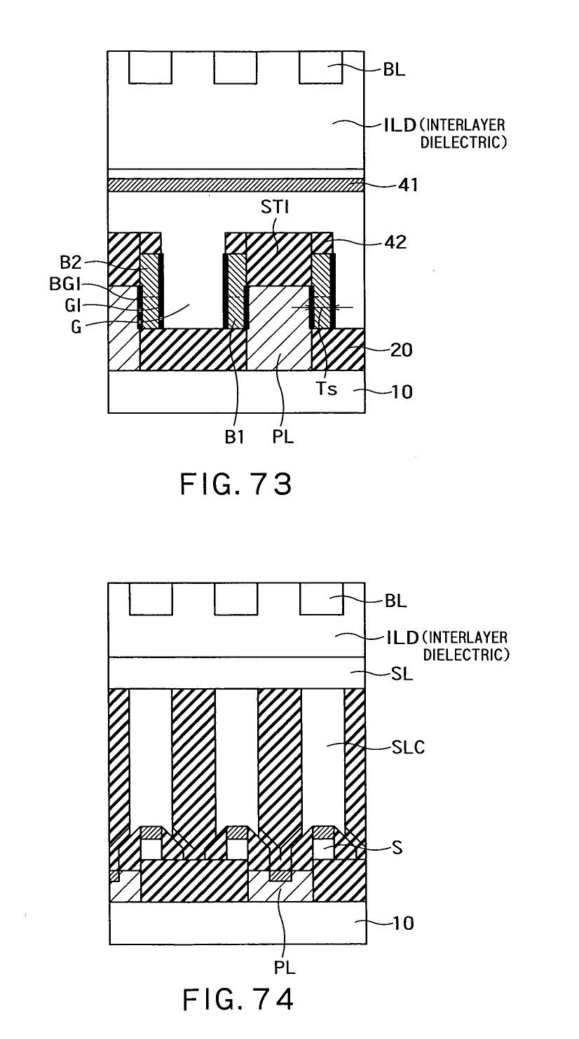

FIGS. 71 to 74 are cross-sectional views taken along lines 71-71, 72-72, 73-73, and 74-74 of FIG. 70, respectively. As shown in FIG. 73, one body B is formed into a Fin shape. The top surface of the plate PL is located near an intermediate position between the top and bottom surfaces of the body B. As shown in FIG. 70, the top surface TFB of the body B is located at a higher position than those of the top surface TFS of the source S and the top surface TFD of the drain D. The portion of the body B lower in position than the top surfaces of the source S and the drain D is defined as “first body part B1” and the portion higher than the first body portion is defined as “second body part B2”.

The memory cell according to the seventh embodiment is an FD-FBC. As shown in FIG. 73, a signal amount during the data-read operation increases if the width Ts of the semiconductor layer put between the plate electrode and the gate electrode is reduced.

According to the seventh embodiment, a channel is formed on each side surface of the body B. Due to this, even if a cell size is reduced, a channel width (Ws) can be kept constant. Namely, according to the seventh embodiment, each memory cell MC can be downsized while keeping the drain current difference (signal difference) between the data “0” and the data “1”. The height (W3+Ws) of the body B can be set larger if the size of each memory cell MC is smaller. The drain current is thereby increased, thus making it possible to realize a high-speed data-read operation.

If the number of holes accumulated in the body B decreases, the problem occurs that the fluctuation in the threshold voltages of the “0” cell and the “1” cell increases among the memory cells MCs. However, the Fin transistors can ensure a channel width without increasing the cell size and, therefore, suppress the fluctuation in the threshold voltages. Alternatively, one memory cell can be constituted by two Fin transistors. If a height of the Fin is set larger, then a difference in height is larger between regions in which the Fin structure is formed and those in which the Fin structure is not formed, and degrees of difficulty of etching and lithography increase. By constituting one memory cell MC by two Fin transistors, the channel width can be increased without increasing the difference in height.

As shown in FIG. 70, the second body part B2 has two surfaces SFB1 and SFB2 oriented in the column direction and the side surfaces SFB1 and SFB2 do not form pn junctions with the source S or the drain D. If the height (W3) of the top surface of the second body part B2 with reference to the top surfaces of the source S and the drain D is set large, the ratio Cb (WL)/Cb (total) can be increased.

As shown in FIGS. 73 and 74, the plate PL penetrates the BOX layer 20 and is connected to the supporting substrate 10. A negative plate potential is applied to the supporting substrate 10 in a peripheral region of the memory cell arrays. As shown in FIG. 73, the plate PL can slightly face the lower portion of the second body part B2. It is to be noted that an area by which the second body part B2 faces the gate electrode G is larger than that by which the second body part B2 faces the plate PL. By so doing, the capacitance between the second body part B2 and the gate electrode G is substantially larger than that between the second body part B2 and the plate PL.

The advantage of the structure in which the lower portion of the second body part B2 is set to slightly face the plate PL is as follows. If a positive voltage is applied to the gate electrode G to read data, an inversion layer is also formed on the surface (third surface) on which the side surface of the second body part B2 faces the gate electrode G. The drain current during the data-read operation includes two components, i.e., a channel current flowing on the inversion layer of the first body part B1 and a channel current going around and flowing on the third surface. The latter component mainly flows on the lower portion of the second body part B2. Due to this, the latter component is modulated depending on the number of holes attracted to the plate PL. As a result, the drain current difference increases during the data-read operation.

Furthermore, P-impurities at high concentration can be introduced into the upper portion of the second body part B2. This can crease the capacitive coupling between the body B and the word line WL without increasing the parasitic pn junction capacitance and the pn junction leakage current.

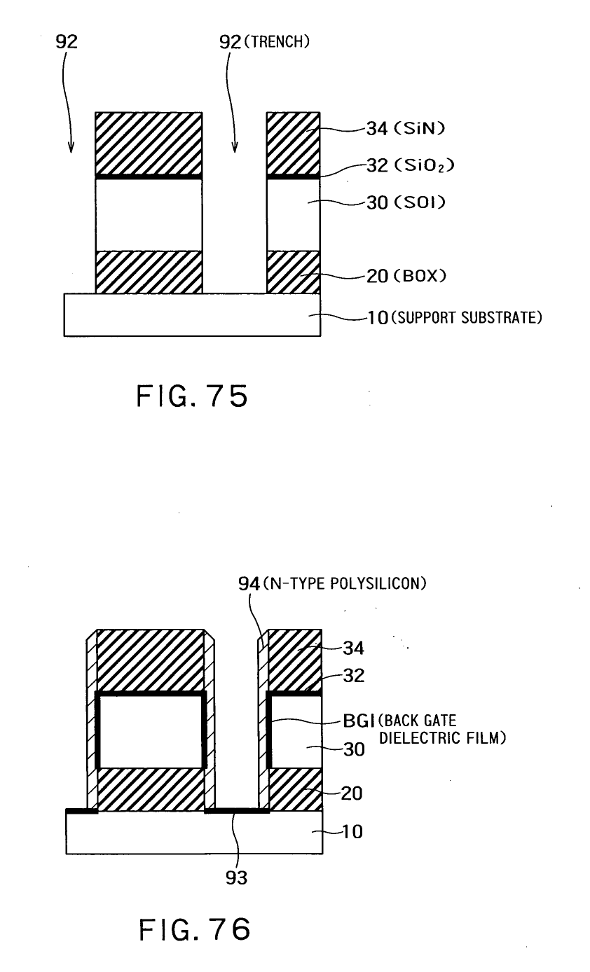

A method of manufacturing the FBC memory device according to the seventh embodiment is described. FIGS. 75 to 79 are cross-sectional views corresponding to FIG. 74. First, the SOI substrate is prepared. The thickness of the BOX layer 20 is 80 nm. The thickness of the SOI layer 30 is 80 nm. The silicon oxide film 32 is formed on the SOI layer 30. The SiN mask 34 is deposited on the silicon oxide film 32. As shown in FIG. 75, the SiN mask 34, the silicon oxide film 32, the SOI layer 30, and the BOX layer 20 in plate formation regions are removed by anisotropically etching. Trenches 92 are thereby formed. At the same time, the SiN mask 34, the silicon oxide film 32, and the SOI layer 30 in STI formation regions in a logic circuit region are removed by anisotropic etching. Next, a silicon oxide film is filled up only in the STI formation regions in the logic circuit region by lithography and RIE. At this time, the silicon oxide film deposited in the memory region is removed by RIE.

As shown in FIG. 76, the back gate dielectric film BGI is formed on side surfaces of the SOI layer 30. The thickness of the back gate dielectric film BGI is about 10 nm. At this time, a silicon oxide film 93 is formed on the supporting substrate 10. N polysilicon 94 is deposited on inside surfaces of the trenches 92. The N polysilicon 94 covers up the back gate dielectric film BGI. In this state, the silicon oxide film 93 is removed by etching.

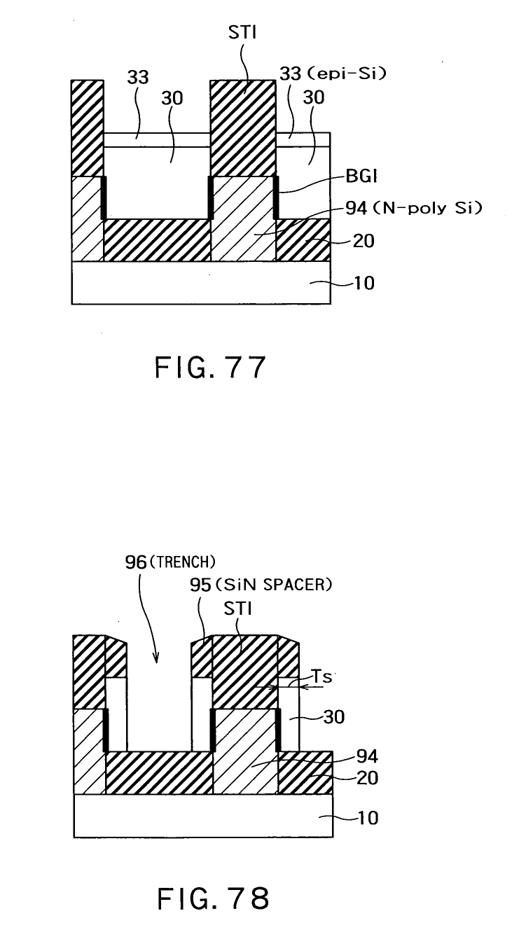

Further, N polysilicon 94 is deposited to fill the N polysilicon 94 in the trenches 92. The N polysilicon 94 is etched back so that the top surface of the N polysilicon 94 is lower than that of the SOI layer 30 by, for example, 20 nm. The STI material is filled up in the trenches 92 so as to be deposited on the N polysilicon 94. This STI material is flatted by CMR The SiN mask 34 is removed by a hot phosphoric acid solution. As shown in FIG. 77, after removing the silicon oxide film 32, a silicon layer 33 having a thickness of 40 nm is deposited on the SOI layer 30 by epitaxial growth. The silicon layer 33 is deposited to adjust the height of the body B. The thickness of the silicon layer 33 is, therefore, arbitrarily adjusted according to need. At this stage, boron ions at a concentration off 1×10¹⁸ cm⁻³ can be implanted into the silicon layer 33.

As shown in FIG. 78, an SiN spacer 95 is formed on the sidewall of the STI material, the top surface of the STI being higher than that of the SOI layer 30. Using the SiN spacer 95 and the STI material as a mask, the silicon layer 33 and the SOI layer 30 are anisotropically etched. The thickness Ts of the body B is decided by a width of the SiN spacer 95 in the row direction (thickness of the SiN spacer 95). The thickness Ts is smaller than F. By etching the SOI layer 30, trenches 96 are formed in the SOI layer 30 between the plates PL.

In the memory region, boron ions at a concentration of 1×10¹⁷ cm⁻³ are implanted into the body B to adjust the threshold voltage. Impurity ions are also appropriately implanted into the active areas AAs in the logic circuit region to adjust the threshold voltage. The thickness of the SOI layer 30 in the channels in the logic circuit region is assumed as 80 nm.

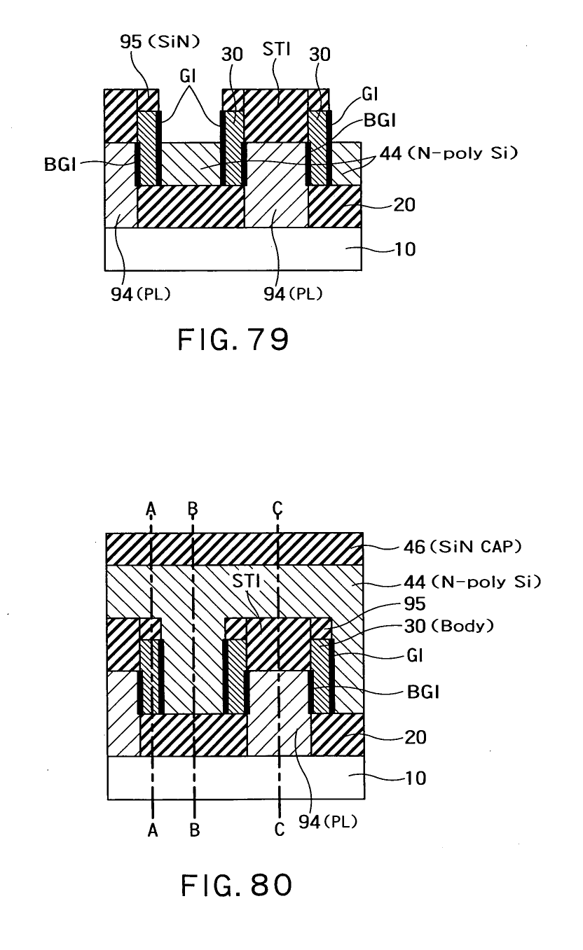

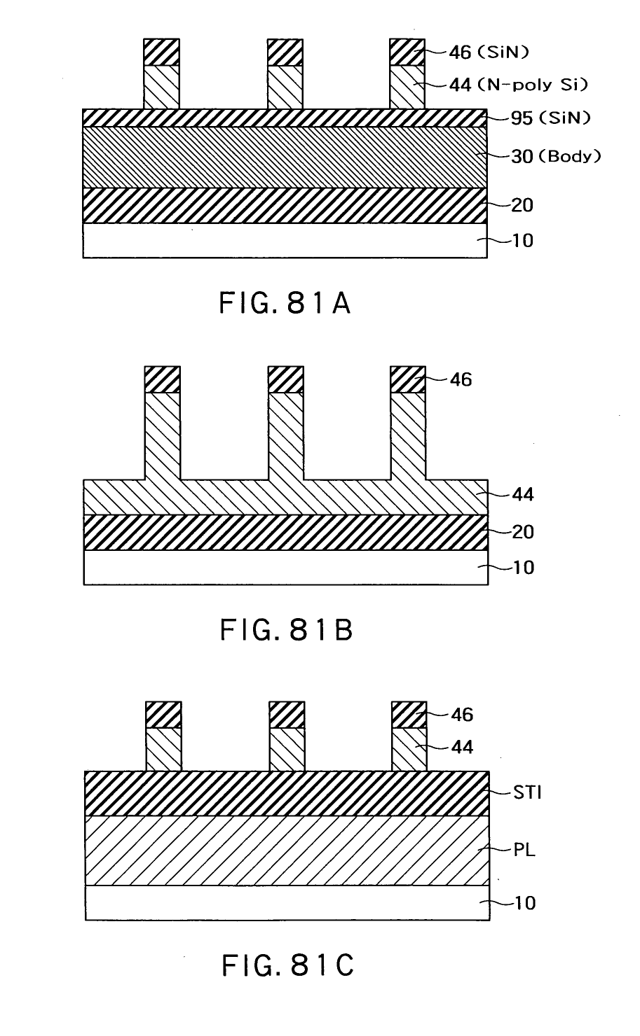

As shown in FIG. 79, the gate dielectric film GI is formed on each side surface of the SOI layer 30 in each trench 96. The thickness of the gate dielectric film GI is about 5 nm. N polysilicon 44 as a word line material is deposited. Further, the SiN cap 46 as a mask material is deposited on the N polysilicon 44. The SiN cap 46 is patterned into a gate electrode (word line) pattern. Using the SiN cap 46 as a mask, the N polysilicon 44 is anisotropically etched. At this time, as shown in FIG. 79, the top surface of the polysilicon 44 to be etched is set to be almost equal in height to that of the plate PL. FIG. 80 is a cross-sectional view corresponding to FIG. 73. FIGS. 81A to 81C are cross-sectional views taken along lines A-A, B-B, and C-C of FIG. 80, respectively. In the logic circuit region, the gate electrodes G formed out of the N polysilicon 44 are formed on the gate dielectric film GI as shown in FIG. 35C.

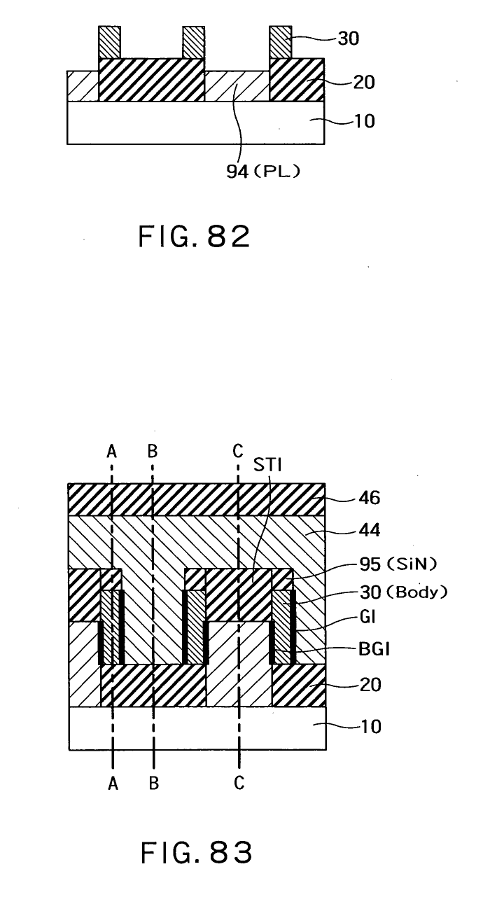

FIGS. 82 and 83 are cross-sectional views showing manufacturing steps subsequent to FIGS. 79 and 80, respectively. First, the STI material and the SiN spacer 95 adjacent to the source formation regions and the drain formation regions that are not covered with the SiN cap 46 and the N polysilicon 44 (gate electrodes G) are removed. At this time, the thickness and the etch time of the SiN cap 46 are set to leave the SiN cap 46. Therefore, the cross section shown in FIG. 80 remains almost unchanged at this stage. Through this step, the upper surfaces of the second body parts B2 in the source formation regions and the drain formation regions that are not covered with the SiN cap 46 and the polysilicon 44 (word lines WLs) are exposed.

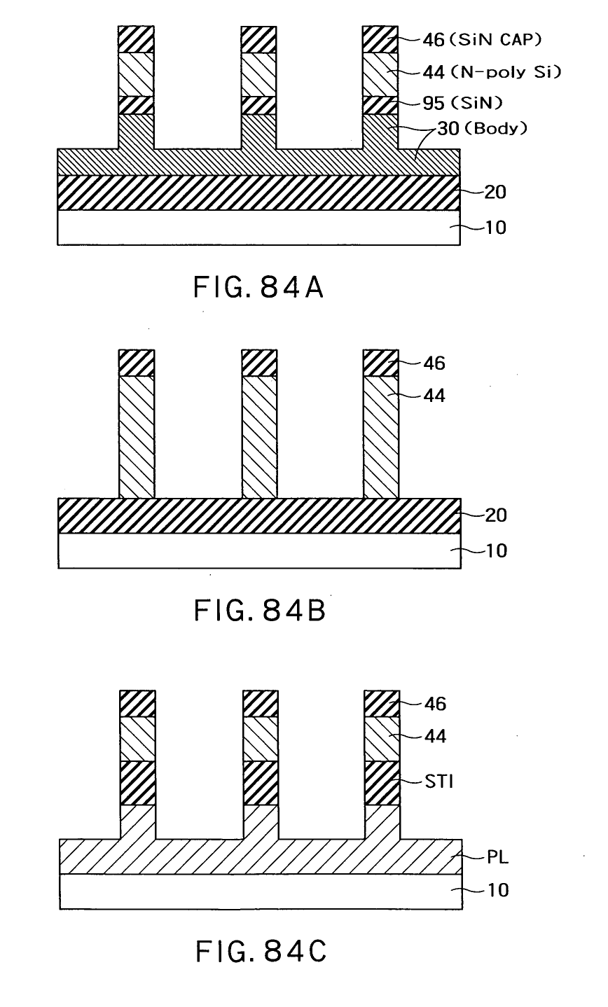

Using the SiN cap 46 as a mask, the SOI layer 30 and the polysilicon 44 are anisotropically etched. The height of the SOI layer 30 in the source formation regions and the drain formation regions is thereby set to, for example, 40 nm. At this stage, the regions covered with the SiN cap 46 are not etched yet. Therefore, the structure shown in FIG. 83 is almost the same as that shown in FIG. 80. FIGS. 84A to 84C are cross-sectional views taken along lines A-A, B-B, and C-C of FIG. 83, respectively. As shown in FIG. 84A, the height Ws of the SOI layer 30 in the source formation regions and the drain formation regions is 40 nm and the height (Ws+W3) of the SOI layer 30 in the body regions is 120 nm. As shown in FIGS. 82 and 84C, the top surface of the plate PL facing the source formation regions and the drain formation regions is etched to be lower than the bottom surface of the SOI layer 30. Since the plate PL does not face the drains D, the parasitic capacitance between the plate PL and the drain D is reduced to make it possible to drive the bit lines BLs at high speed and low power consumption.

Next, using the SiN cap 46 and the polysilicon 44 as a mask, N-impurity ions are implanted. The extension layer (not shown) is thereby formed in the source formation regions and the drain formation regions. By implanting the N-impurity ions from a direction perpendicular to the substrate and performing a heat treatment, the extension layer overlaps each of the gate electrodes G. To prevent the N-impurity ions from being implanted into the side surfaces of the second body parts B2, the ion implantation can be performed using a sidewall spacer. Thereafter, similarly to the third embodiment, the SiN spacer 42 is formed and the sources S and the drains D are formed using the SiN spacer 42 as a mask. After depositing the interlayer dielectric film ILD, the source line contacts SLCs, the bit line contacts BLCs, the source lines SLs, and the bit lines BLs are formed. As a result, the FBC memory device according to the seventh embodiment is completed.

### Eighth Embodiment

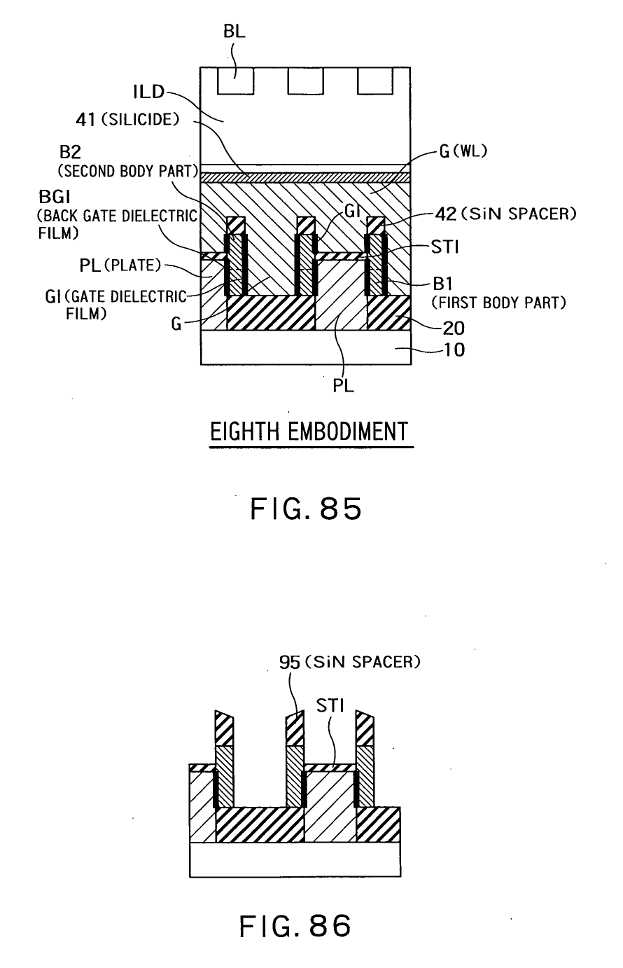

FIG. 85 is a cross-sectional view of an FBC memory device according to an eighth embodiment of the present invention. In the eighth embodiment, each STI is formed thinner than that shown in FIG. 73. By doing so, the gate electrode G faces both side surfaces of each second body part B2 via the gate dielectric film GI. According to the eighth embodiment, therefore, the ratio Cb (WL)/Cb (total) can be made higher than that according to the seventh embodiment. The FBC memory device according to the eighth embodiment can be configured similarly to that according to the seventh embodiment in other aspects.

A method of manufacturing the FBC memory device according to the eighth embodiment is described. Manufacturing steps are similar to those according to the seventh embodiment up to FIG. 77. Next, the SiN spacer 95 is formed on each side surface of the STI material. As shown in FIG. 86, the height of the STI material is reduced by wet etching. Thereafter, using the SiN spacer 95 and the STI material as a mask, the SOI layer 30 is anisotropically etched. After executing the steps shown in FIG. 79 and the following, the FBC memory device according to the eighth embodiment is completed.

### Ninth Embodiment

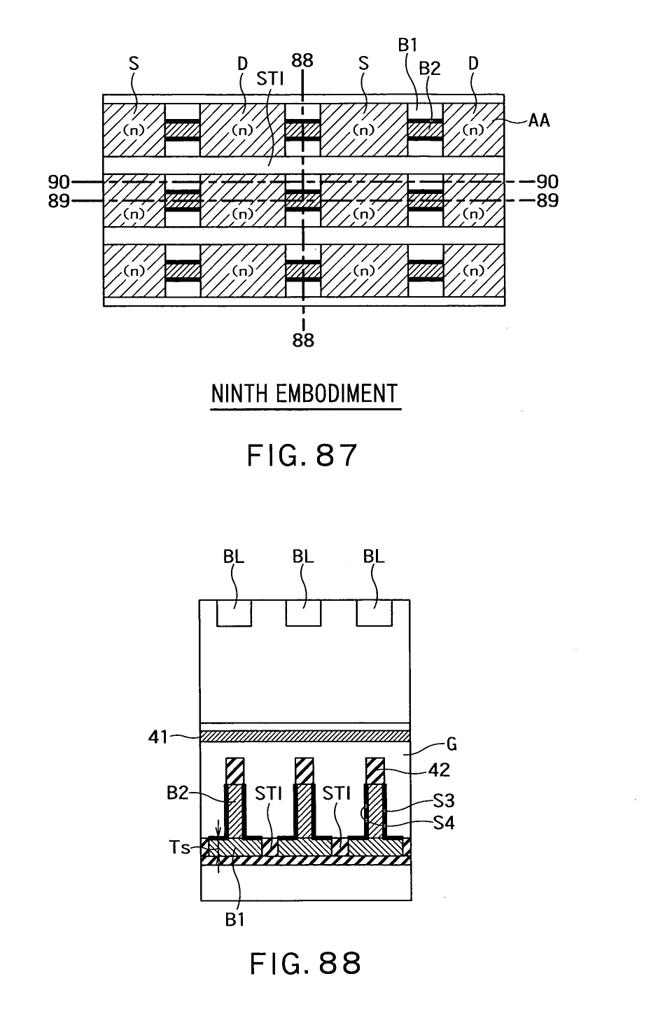

FIG. 87 is a plan view of an FBC memory device according to a ninth embodiment of the present invention. The ninth embodiment differs from the third embodiment in that the second body part B2 is formed not to be adjacent to the element isolation regions but in the central portion of the active area AA in the cross section along one word line WL. In the third embodiment, one memory cell is constituted by two extending portions. In the ninth embodiment, one memory cell is constituted by one extending portion. Therefore, if the cell size is reduced, the FBC memory device according to the ninth embodiment can be manufactured more easily.

FIG. 88 is a cross-sectional view taken along a line 88-88 of FIG. 87. In the ninth embodiment, similarly to the third embodiment, each gate electrode G faces the top surface of one first body part B1 and the side surfaces S3 and S4 of one second body part B2 as well. The cross-sectional view taken along the line 89-89 of FIG. 88 is similar to that shown in FIG. 14. However, differently from FIG. 14, the source line contacts SLCs, the bit lines BLs, and the bit line contacts BLCs are added in the cross section shown in FIG. 88 according to the ninth embodiment. The cross-sectional view taken along the line 90-90 of FIG. 88 is similar to that shown in FIG. 13. However, differently from FIG. 13, the source line contacts SLCs, the bit lines BLs, and the bit line contacts BLCs are omitted in the cross section shown in FIG. 87 according to the ninth embodiment. In the ninth embodiment, each second body part B2 has two side surfaces SFB1 and SFB2 oriented in the column direction and the side surfaces SFB1 and SFB2 do not form pn junctions with the source S or the drain D. The FBC memory device according to the ninth embodiment can, therefore, obtain similar advantages to those of the FBC memory according to the third embodiment.

### Tenth Embodiment

In a method of driving an FBC memory device according to a tenth embodiment of the present invention, similarly to the second embodiment, holes are extracted from the selected memory cell MC00 out of the memory cells MC00 and MC10 connected to the selected word line WL0 in the second cycle. However, the potential of the unselected bit line BL1 according to the tenth embodiment differs from that according to the second embodiment. According to the tenth embodiment, the potential of the selected word line WL0 is a potential biased to the same polarity as that of majority carriers accumulated in the memory cells MCs with reference to the source line potential in the second cycle. In the second cycle, the potential of the selected bit line BL0 and that of the unselected bit line BL1 are potentials biased to a reversed polarity with respect to the polarity of majority carriers accumulated in the memory cells MCs with reference to the source line potential in the second cycle. The potential of the unselected bit line BL1 is larger in absolute value than that of the selected bit line BL0. More specifically, the fourth potential VWLH (e.g., 1.4 V) higher than the source line potential VSL is applied to the selected word line WL0. The third voltage VBLL (e.g., −0.9 V) lower than the source line potential VSL is applied to the selected bit line BL0. By doing so, a forward bias is applied to the pn junction between the drain D and the body B of the selected memory cell MC00 to eliminate the holes from the body B of the selected memory cell MC00. A fifth voltage VBL2 (e.g., −0.2 V) lower than the source line potential VSL is applied to the unselected bit line BL1. A weak forward bias is thereby applied to the pn junction between the source S and the body B of the unselected memory cell MC10. Holes in small quantities are thereby eliminated from the unselected memory cell MC10.

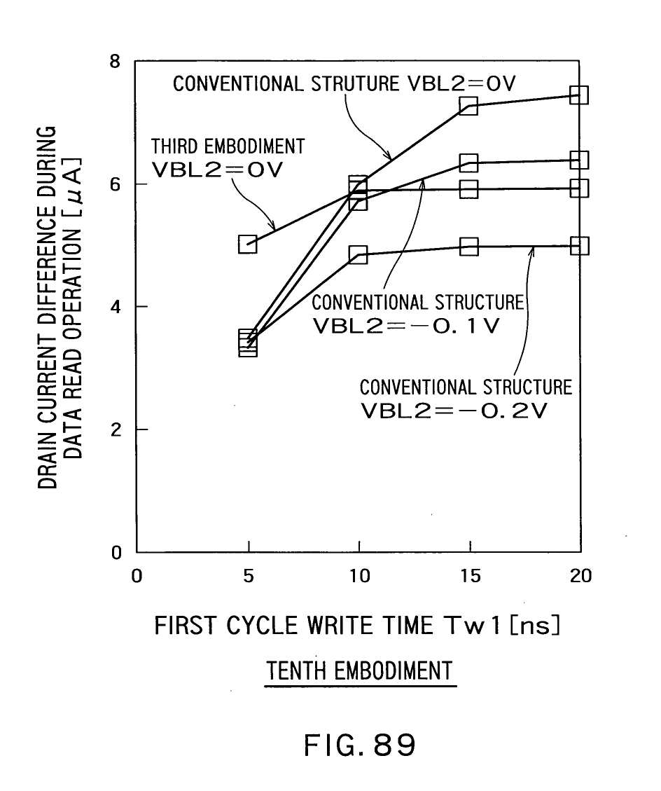

FIG. 89 is a graph showing the relationship between the first cycle write time Tw1 and the drain current difference during the data-read operation according to the tenth embodiment. A structure of a simulation is the same as that used in FIG. 17. Potentials applied to the respective electrodes of the memory cells MCs are almost identical to those shown in FIG. 15. FIG. 89 shows a simulation result if the bit line potential (fifth potential) VBL2 for the “1” cell is changed from 0 V to −0.1 V and to −0.2 V. If the bit line potential (fifth potential) VBL2 is lowered from 0 V to −0.1 V and to −0.2 V, the dependence of the drain current difference on the first cycle write time Tw1 decreases. In the tenth embodiment, while the number of holes of the “1” cell decreases in the second cycle, the fluctuation in the signal difference resulting from the first cycle write time Tw1 is reduced by the feedback operation in the second cycle. Accordingly, the threshold voltage difference between the “0” cell lower in threshold voltage among the “0” cells and the “1” cell higher in threshold voltage among the “1” cells is larger, thus improving yield.

Further, as shown in FIG. 89, if VBL2 is 0 volt (VBL2=0V), the structure including the second body part B2 (the third embodiment) is smaller than the conventional structure in the fluctuation in signal difference resulting from the first cycle write time Tw1. If the first cycle write time Tw1 is as short as 5 ns, the signal difference according to the third embodiment is larger than that of the conventional structure. Even if the potential VBLL of the selected bit line BL0 in the second cycle is set close to the source potential VSL as compared with that of the conventional structure so as to suppress the bit line “0” disturbance (that is, to fully maintain holes in the “1” cell), the threshold voltage difference between the “0” cell and the “1” cell can be kept larger than that according to the conventional technique. Therefore, the structure including the second body part B2 can contribute to suppression of the bit line “0” disturbance (increase in retention time of retaining holes accumulated in “1” cells).

### Eleventh Embodiment

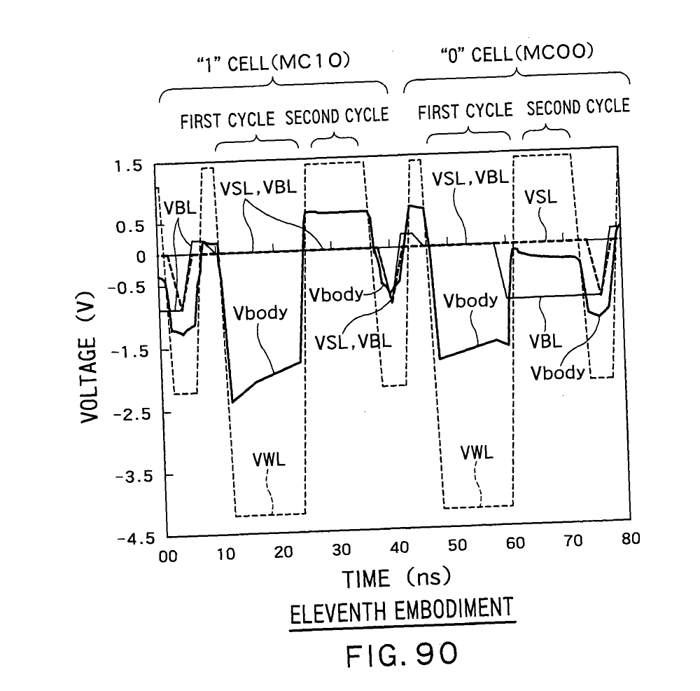

An eleventh embodiment differs from the first embodiment in voltages in the data retention state. FIG. 90 is a timing diagram showing an operation performed by an FBC memory device according to the eleventh embodiment of the present invention. Voltages during the data-write operation are the same as those according to the first embodiment.

It is assumed that a potential of all the bit lines BLs and that of all the source lines SLs in the data retention state is a second potential. It is also assumed that a potential of all the word lines WLs in the data retention state is a seventh potential. Further, it is assumed that a plate potential common to the data-read operation, the data-write operation, and the data retention time is an eighth potential. The sixth potential VBLL (e.g., −0.9 V) is a potential having a reversed polarity with respect to the polarity of holes with reference to the source potential VSL (0 V). A word line potential VWLP (e.g., −2.2 V) that is the seventh potential is a potential having a reversed polarity with respect to the polarity of holes with reference to the sixth potential. A plate line potential VPL (e.g., −2.4 V) that is the eighth potential is a potential having a reversed polarity with respect to the polarity of holes with reference to the sixth potential.

If a voltage difference VDG between the drain D and the gate G and a voltage difference VSG between the source S and the gate G of each memory cell MC in the data retention state are large, an electric field near an interface between the body B and the gate G is high. If a voltage difference VDP between the drain D and the plate P in the data retention state is large, an electric field near an interface between the body B and the plate P is high. The high electric field on the interface between the body B and the gate G and that on the interface between the body B and the plate P cause the GIDL.

Meanwhile, in the eleventh embodiment, the source line and bit line potential VBLL (−0.9 V) in the data retention state is set lower than the reference potential VSL (0 V) during the data-write operation and the data-read operation. If the source voltage and the drain voltage are set to −0.9 V in the data retention state, absolute values of the voltage differences VDG and VSG are 1.3 V and those of the voltage differences VDP and VSP are 1.5 V. Due to this, the electric fields on the interfaces between the body B and the gate G and between the body B and the plate P according to the eleventh embodiment are lower than those according to the first embodiment. As a result, the GIDL in the data retention state is lowered, thereby increasing the data retention time for the “0” cell.

To write data “1” to one memory cell MC, it is necessary to set the difference between the plate voltage VPL (−2.4 V) and the source voltage or drain voltage large to some extent. For this reason, if the source voltage is −0.9 V, the operation for writing data “1” can possibly be insufficiently performed. It is, therefore, preferable to set the source potential to 0 V during the data-write operation. It is thereby possible to accumulate holes in the bottom surface (second surface) of the body B facing the plate electrode (supporting substrate 10). Likewise, during the data-read operation, if holes are accumulated in the bottom surface of the body B, the drain current difference between the data “0” and the data “1” can be increased. Therefore, during the data-write operation and the data-read operation, the potential of the selected source line SL is set to VSL (0 V). Particularly if the FBC memory cell is the FD-FBC, it is important to apply a deep negative potential relative to the source voltage to the plate during the data-write operation and the data-read operation.

Further, when data is retained with the word line potential set to 0 V, the interface between the gate electrode G and the body B turns into a depletion state. If the interface is depleted, leakage current via an interface state considerably increases. It is, therefore, preferable to set the word line potential to the negative potential with reference to the source potential and the drain potential similarly to the plate potential. By so setting, the data can be retained while setting the interface into an accumulation state.

With reference to FIG. 90, in a period from about 36 ns to about 38 ns and that from about 72 ns to about 74 ns after execution of the second cycle, the word line driver WLD lowers the potential of the selected word line WL0 to the word line potential VWLP (−2.2 V) that is the potential in the data retention state. In a period from about 38 ns to about 40 ns and that from about 74 ns to about 76 ns, each of the sense amplifiers S/A and the source line driver SLD lower the bit line potential and the source line potential to the potential VBLL (−0.9 V) that is the potential during the data retention state, respectively. At this time, the bit line potential and the source line potential as the sixth embodiment are almost equal to the body potential of the “1” cell.

In the first embodiment, the bit line potential and the source line potential remain VSL (0 V) in the data retention state. In the eleventh embodiment, by contrast, the bit line potential and the source line potential are lowered to the potential VBLL (−0.9 V) in the data retention state. At about 75 ns, a maximum electric field in the SOI layer of the “0” cell in the data retention state is 0.78 MV/cm. On the other hand, if the bit line potential and the source line potential are kept to VSL (0 V), the maximum electric field of the “0” cell is 1.98 MV/cm. In this way, by causing the source line driver SLD to change the polarity of the source potential to the reversed polarity during a transition from the data-write operation to the data holding state, the maximum electric field of the “0” cell is lower and the data retention time is longer.

### Twelfth Embodiment

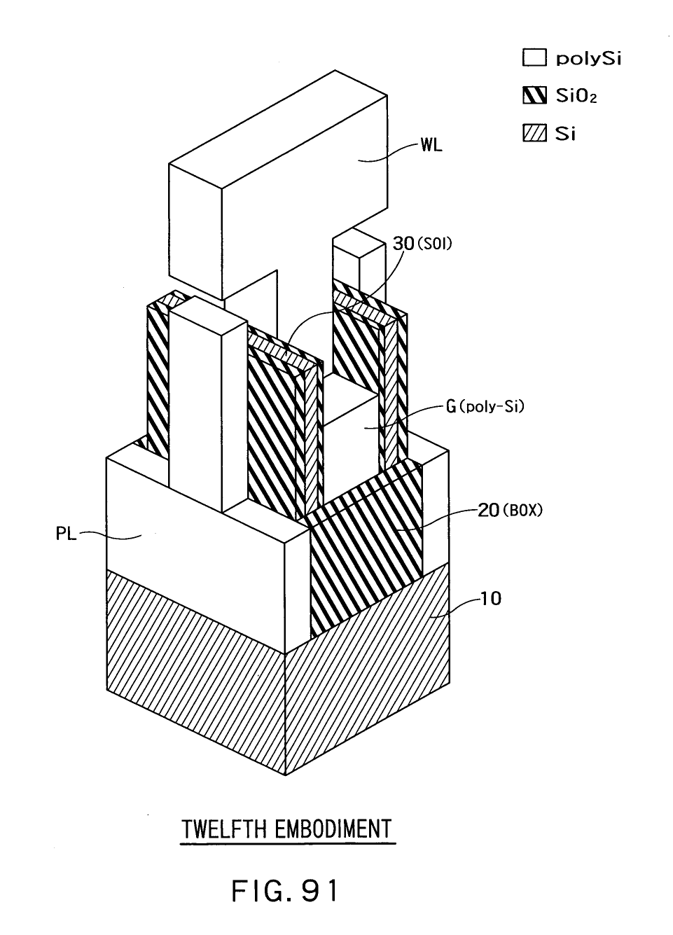

FIG. 91 is a bird's-eye view of an FBC memory device according to a twelfth embodiment of the present invention. In the twelfth embodiment, the SOI layer 30 is formed into a Fin shape. Further, each gate electrode G has an inversed T-shaped cross section in the direction perpendicular to the row direction.

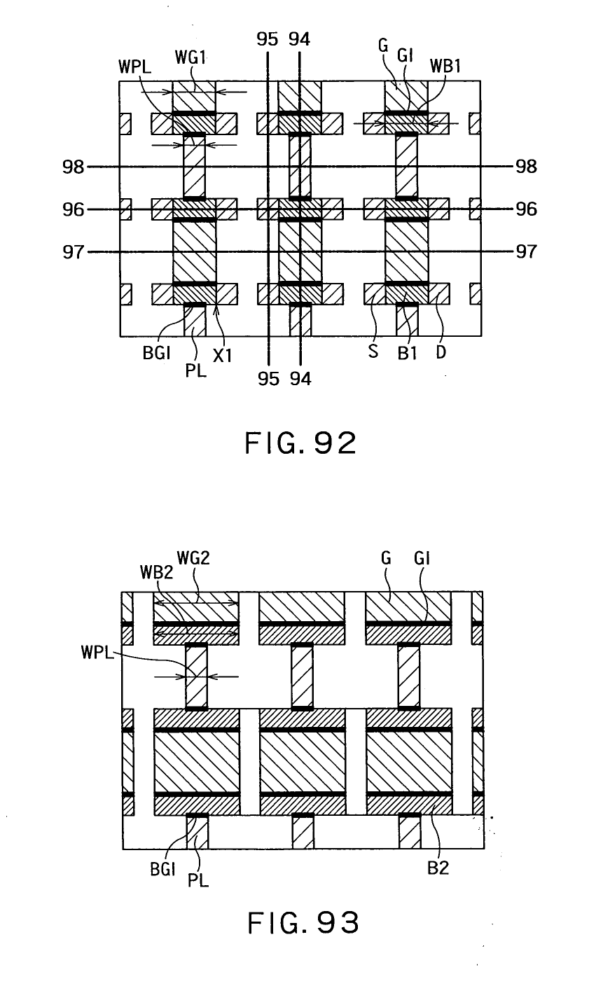

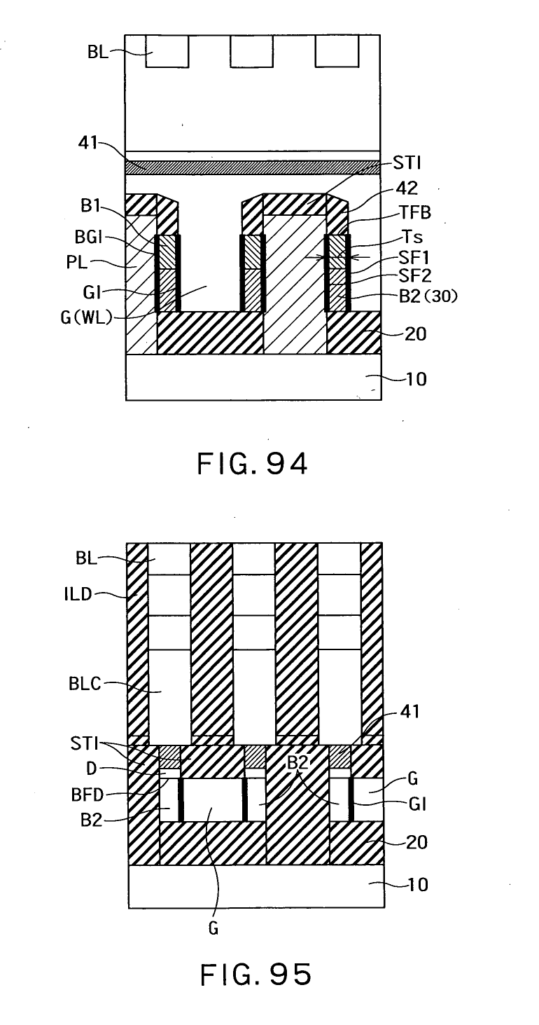

FIG. 92 is a plan view along the top surface of the SOI layer 30. FIG. 93 is a plan view along the bottom surface of the SOI layer 30. Wiring arrangement according to the twelfth embodiment is similar to that shown in FIG. 11. FIGS. 94 to 98 are cross-sectional views taken along lines 94-94, 95-95, 96-96, 97-97, and 98-98 of FIG. 92, respectively.

As is understood from FIG. 92, the sources S, the drains D, and the first body parts B1 are formed on the SOI layer 30. A width WG1 of each gate electrode G in the column direction is almost equal to a width WB1 of each first body part B1 in the column direction. A width WPL of the plate PL in the column direction is smaller than the width WG1 of each gate electrode G in the column direction. Due to this, the influence of the plate potential on the junction between the body B and the drain D of each memory cell MC and that between the body B and the source S thereof (a part indicated by X1 in FIG. 92) is small. Namely, even if a high negative potential is applied to the plate PL to sufficiently accumulate holes in a “1” cell, the electric field on a junction X1 can be set low. It is, therefore, possible to lower the GIDL in the “0” cell in the data retention state and increase the data retention time.

As shown in FIG. 93, the second body parts B2 are formed on the entire SOI layer 30 but the source layers S and the drain layers D do not appear on the SOI layer 30. The width WG2 of one gate electrode G in the column direction is the same as the width WB2 of one second body part B2 in the column direction. The width of the plate PL in the column direction is the same as a width WPL of the top surface of the SOI layer 30. This structure enables the capacitive coupling between the body B and the word line WL to be greater than that between the body B and the plate PL.

As shown in FIG. 94, in the cross section along one word line WL, an entire first side surface (first surface) SF1 of the SOI layer 30 faces the gate electrode G. The top surface of the plate PL is located at a higher position than that of the top surface TFB of the SOI layer 30. Due to this, an entire second side surface (second surface) SF2 of the SOI layer 30 faces the plate PL. Therefore, the number of holes accumulated in the body B can be increased.

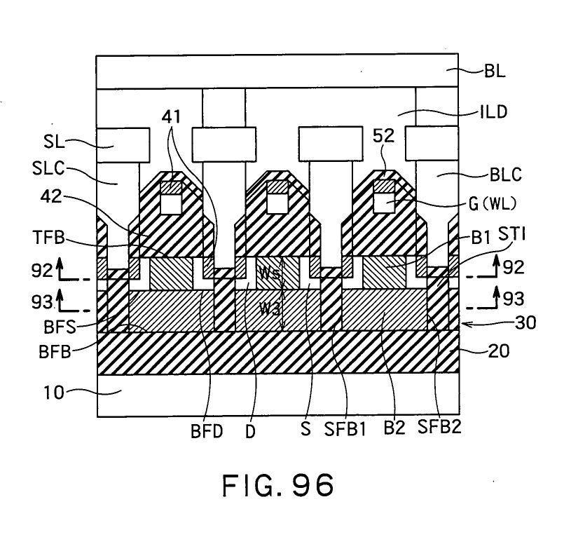

As shown in FIGS. 95 and 96, a bottom surface BFS of each source S and a bottom surface BFD of each drain D do not reach a bottom surface BFB of the SOI layer 30. Out of the body B, a part extending downward of the bottom surface BFS of the source S and the bottom surface BFD of the drain is defined as the second body part B2. The second body part B2 has two side surfaces SFB1 and SFB2 oriented in the column direction and the two side surfaces SFB1 and SFB2 do not form pn junctions with the source S or the drain D. The upper portion of the second body part B2 is adjacent to the source S and the drain D in the perpendicular direction. The second body part B2 is connected to the first body part B1 interposed between the source S and the drain D.

The height Ws of the top surface TFB of the body B with reference to the bottom surface. BFD of the drain D corresponds to a channel width. By setting the height W3 of the second body part B2 large with reference to the bottom surface BFB of the body B, the ratio Cb (WL)/Cb (total) can be set high. The twelfth embodiment can exhibit the same advantages as those described in the seventh embodiment.

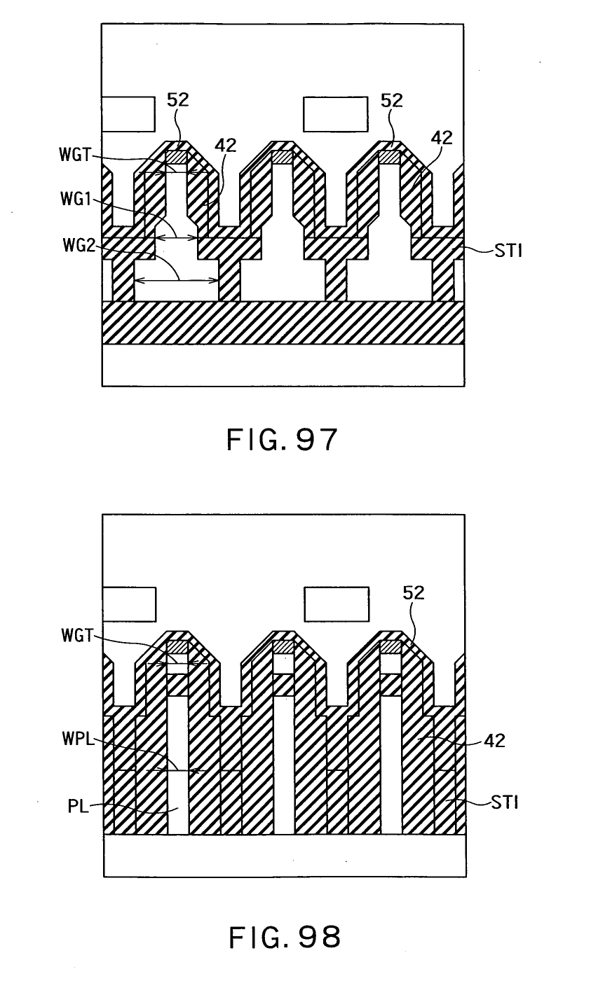

As shown in FIG. 97, in the cross section perpendicular to the row direction, the width of one word line WL is WGT, the width of each gate electrode G facing the first body part B1 is WG1(>WGT), and the width of the gate electrode G facing the second body part B2 is WG2 (>WG1). With the structure according to the eleventh embodiment, the cell size can be reduced while securing the distance between one word line WL and one bit line contact BLC, the distance between one word line WL and one source line contact SLC, and the gate length (width of the first body part B1 in the column direction). As shown in FIG. 98, a width WGT of one word line WL in the column direction is equal to the width WPL of the plate PL in the column direction.

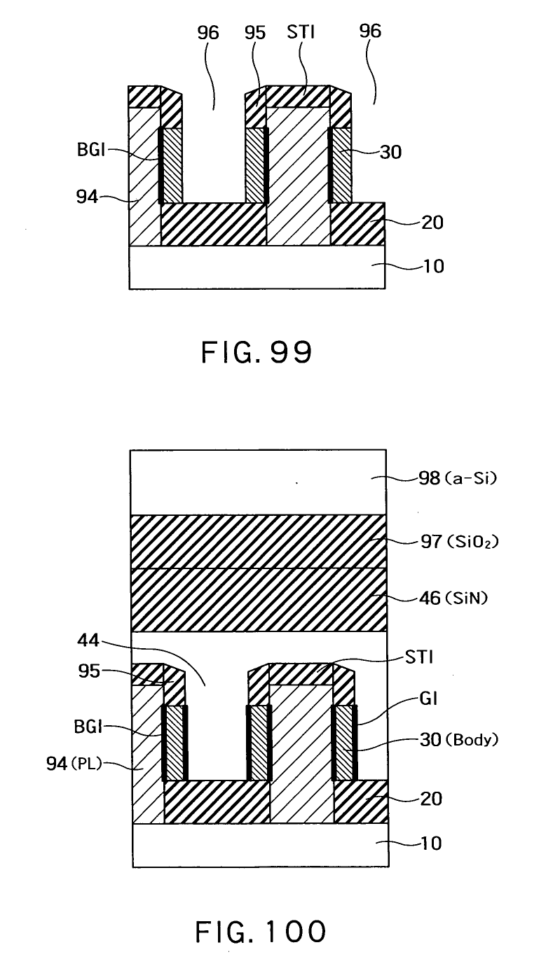

A method of manufacturing the FBC memory device according to the twelfth embodiment is described. First, through similar step to those according to the seventh embodiment, the structure shown in FIG. 76 is obtained. In this state, the silicon oxide film 93 is removed by wet etching. After depositing the N polysilicon 94, the N polysilicon 94 is etched back so that the top surface of the N polysilicon 94 is higher than that of the SOI layer 30 by, for example, 20 nm. Thereafter, similarly to the seventh embodiment, the step of filing up the STI material on the polysilicon 94 in the trenches 92, the step of flattening the STI material by CMP, the step of removing the SiN mask 34 using a hot phosphoric acid solution, the step of removing the silicon oxide film 32, the step of forming the SiN spacer 95, and the step of forming the trenches 96 are executed. FIG. 99 shows a cross section at this stage.

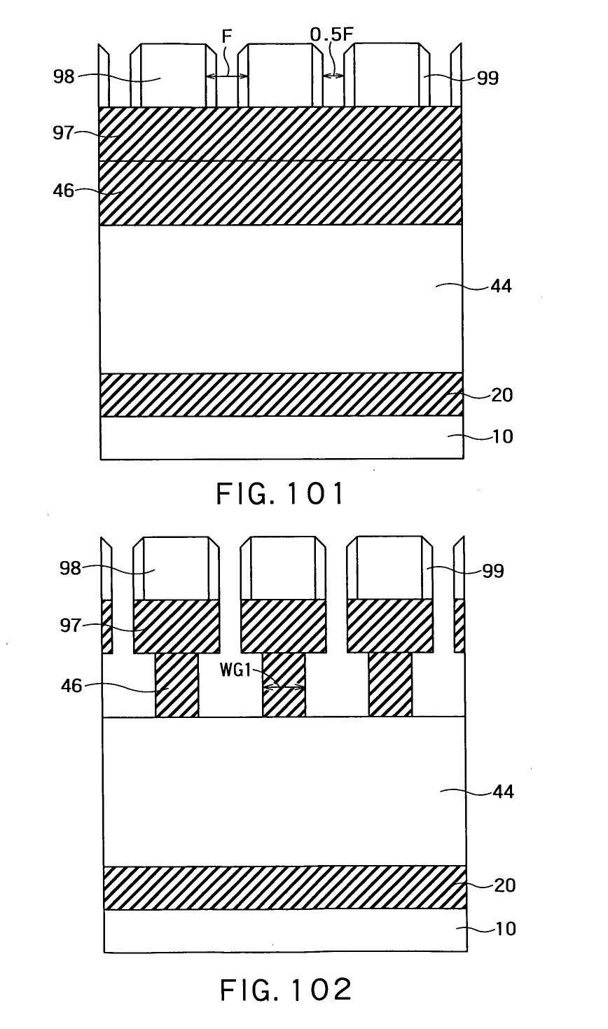

As shown in FIG. 100, the gate dielectric film GI is formed. The N polysilicon 44, the SiN cap 46, a silicon oxide film (SiO2) layer 97, and an amorphous silicon layer 98 are deposited in sequence. FIG. 101 is a cross-sectional view corresponding to FIG. 97. The amorphous silicon layer 98 is patterned as shown in FIG. 101. At this time, spaces each having a width F are formed along formation regions for forming the bit line contacts BLCs and the source line contacts SLCs. An amorphous silicon spacer 99 is formed on a sidewall of the amorphous silicon layer 98. As a result, spaces each having a width 0.5 F are formed.

FIG. 102 is a cross-sectional view subsequent to that shown in FIG. 101. As shown in FIG. 102, using the amorphous silicon layer 98 and the amorphous silicon spacers 99 as a mask, the silicon oxide layer 97 and the SiN cap 46 are anisotropically etched. By etching the SiN cap 46 using the hot phosphoric acid solution, the SiN caps 46 each having the width WG1 are formed. The width WG1 corresponds to the width of each first body part B1 in the column direction.

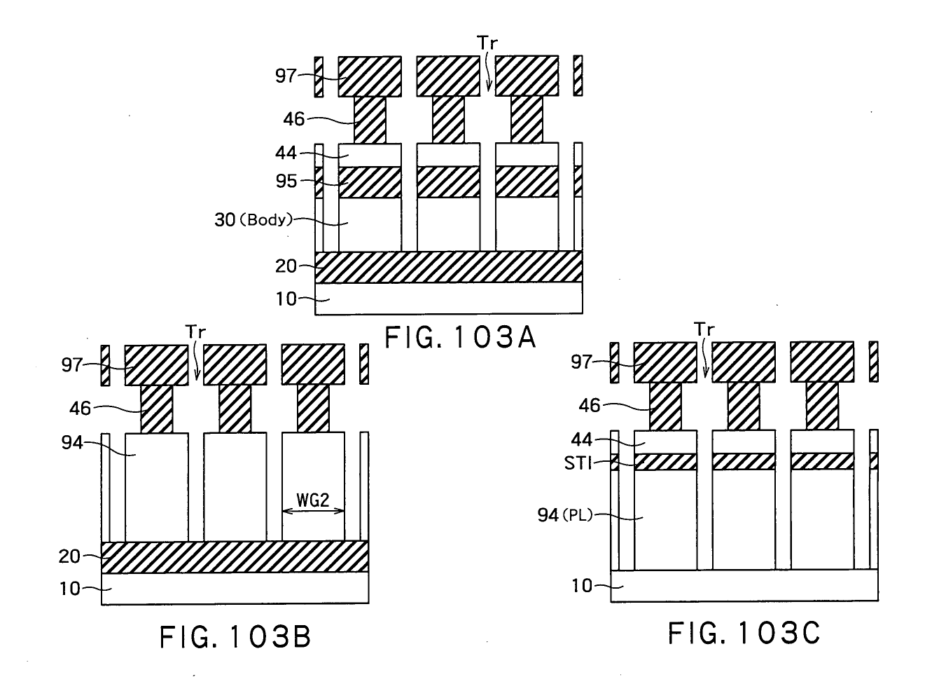

FIGS. 103A to 103C are cross-sectional views subsequent to that shown in FIG. 102 and corresponding to FIGS. 96 to 98, respectively. As shown in FIGS. 103A to 103C, using the silicon oxide film layer 97 as a mask, the plate PL, the gate electrode G, and the SOI layer 30 are anisotropically etched. Memory cells MCs adjacent in the column direction are isolated by trenches Tr, accordingly. Each gate electrode G has the width WG2 in the column direction.

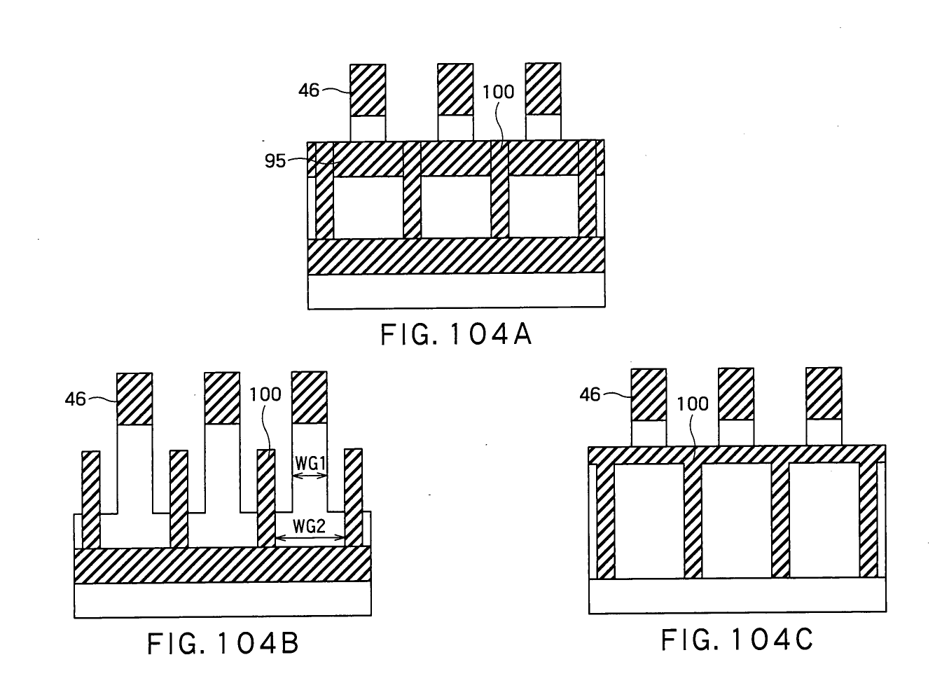

FIGS. 104A to 104C are cross-sectional views subsequent to FIGS. 103A to 103C, respectively. As shown in FIGS. 104A to 104C, the trenches Tr are filled with an oxide film 100. At this time, a top surface of the oxide film 100 is set to be almost equal in height to that of the SiN spacer 95. Using the SiN cap 46 as a mask, the gate electrodes G are anisotropically etched. As a result, inverted-T-shaped gate electrodes G are formed. An upper portion of each of the inverted-T-shaped gate electrodes G has the width WG1 in the column direction and a lower portion thereof has the width WG2 in the column direction. Next, N-impurity ions are implanted obliquely, thereby forming an extension layer in each of source or drain regions in the SOI layer 30. At this stage, the other side surface of the SOI layer 30 is not covered with the plate PL.

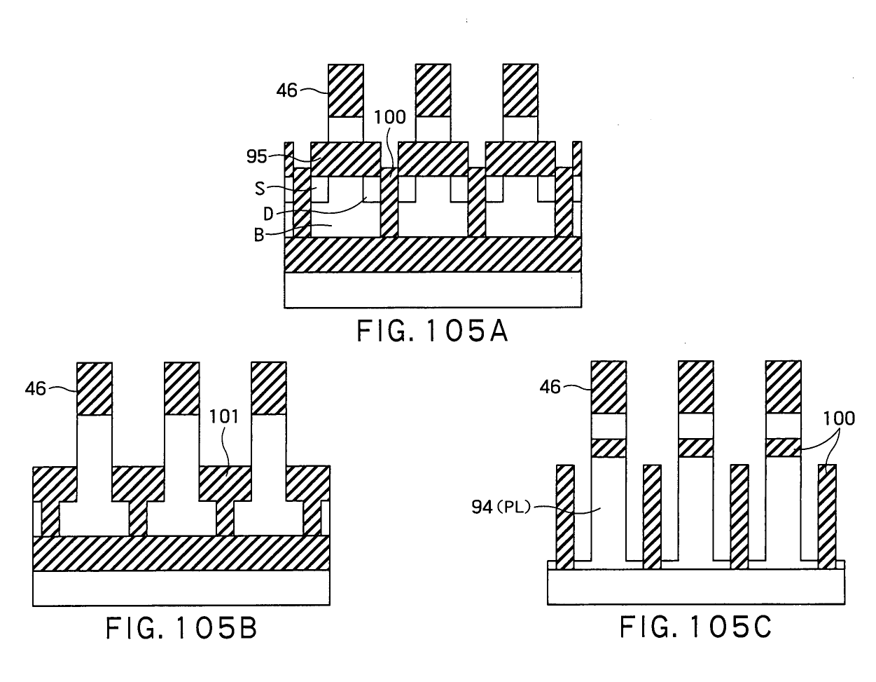

FIGS. 105A to 105C are cross-sectional views subsequent to FIGS. 104A to 104C, respectively. As shown in FIG. 105B, an oxide film 101 is filled up in the element isolation regions. At this time, the oxide film 101 is formed so as to cover up lower portions of the gate electrodes G, that is, portions facing the second body parts B2. Using the SiN cap 46 as a mask, the N polysilicon is anisotropically etched.

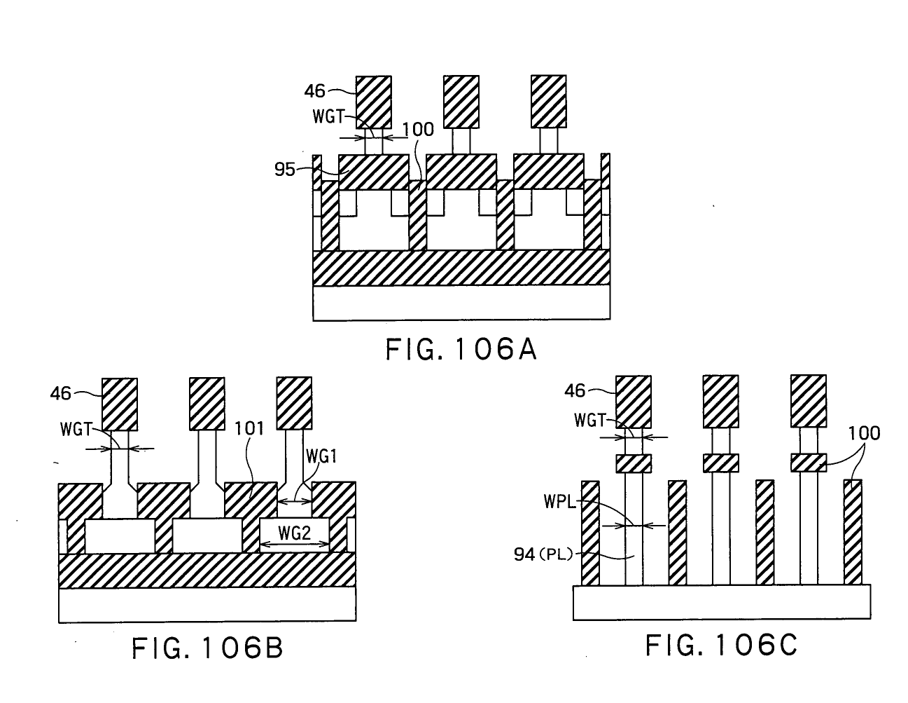

FIGS. 106A to 106C are cross-sectional views continuous to FIGS. 105A to 105C, respectively. As shown in FIG. 106C, by isotropically etching the N polysilicon 94, the width of the plate PL is set to WPL. At the same time, the gate electrode material 44 is isotropically etched, thereby setting the width of each word line WL to WGT. At this time, the width of the lower portion of each gate electrode G remains WG2. After removing the SiN cap 46 and the SIN spacer 95, the steps shown in FIG. 25 and the following according to the third embodiment are executed, thereby completing the FBC memory device according to the twelfth embodiment.

### Thirteenth Embodiment

An FBC memory device according to a thirteenth embodiment of the present invention is structured to be suited for an autonomous refresh operation that is a combination of a charge pumping operation and an impact ionization operation. In the autonomous refresh operation, many memory cells MCs connected to a plurality of columns and a plurality of rows can be refreshed collectively without identifying data stored in each memory cell MC using sense amplifiers S/As. This can reduce power consumption of the FBC memory device.

In the charge pumping process (operation) in the autonomous refresh operation, part of electrons in the inversion layer are trapped by interface states present on an interface between the gate dielectric film GI and the body B of each memory cell MC if the word line WL connected to the memory cell MC is turned on. If the word line WL is returned into an OFF state, the holes accumulated in the body B recombine with the trapped electrons and disappear, whereby charge pumping current flows. The number of holes accumulated in “0” cells and “1” cells decrease by the charge pumping current proportional to the number of interface states. The number of interface states is set so as to be larger than the number of holes increased by either a reverse pn junction leakage current or a band-to-band tunneling leakage current just before the charge pumping operation is performed.

In the impact ionization process (operation) in the autonomous refresh operation, a large potential difference is given between the source S and the drain D of each memory cell MC, thereby forming a high electric field region near the source S or the drain D. An intermediate voltage between the threshold voltage for the “0” cells and that for the “1” cells is applied to the word line WL connected to the memory cell MC. As a result, the drain current difference is generated depending on the number of holes (or body potential) between the “0” cell and that in the “1” cell and the impact ionization current differs between the “0” cells and the “1” cells. More holes than the holes lost by the charge pumping operation are supplied to the “1” cells by the impact ionization. However, no holes are supplied to the “0” cells since impact ionization does not occur in the “0” cells.

Each of the memory cells MCs according to the thirteenth embodiment has 15 interface states in average on the interface between the gate dielectric film GI and the body B on which the gate electrode G faces the body B. The structure according to the thirteenth embodiment can be almost similar to that shown in FIGS. 91 to 98. A nitride film or a compound film of an oxide film and a nitride film is used as the gate dielectric film GI. An area density of interface states is about 1×10¹²/cm². The number of holes accumulated in each “1” cell is set to be sufficiently larger than the average number of interface states, for example, to 200 in average. This is because “1” cells cannot be discriminated from “0” cells if the number of holes accumulated in each “1” cell greatly decreases by the charge pumping operation. As already described above, it is necessary to set the average number of interface states to be sufficiently larger than the number of holes increased by the leakage current in the data retention state. According to the thirteenth embodiment, the number of holes accumulated in each “1” cell and the number of interface states on the interface facing the gate electrode G can be increased without making the cell size larger.

### Modification of Thirteenth Embodiment

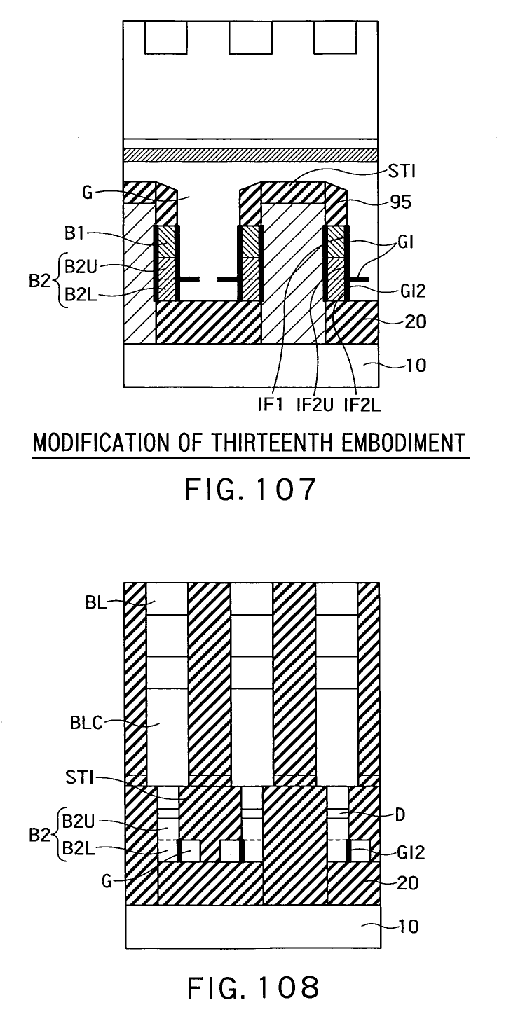

FIGS. 107 to 109 are cross-sectional views of an FBC memory device according to a modification of the thirteenth embodiment of the present invention. FIGS. 107 to 109 correspond to FIGS. 94 to 96, respectively. The gate dielectric film GI is formed on the surface of each first body part B1 and a surface of an upper portion B2U of each second body part B2. A second gate dielectric film GI2 is formed on a surface of a lower portion B2L of the second body part B2. Area densities of interface states on interfaces IF1 and IF2U between the gate dielectric film GI and the body B are lower than that of interface states on an interface IF2L between the second gate dielectric film GI2 and the body B. Although the interface states enable an autonomous refresh operation, the interface states cause deterioration in carrier mobility in the channel and reduction in the drain current difference during the data read operation. In the modification of the thirteenth embodiment, therefore, the area density of interface states of the first body part B1 in which the drain current mainly flows is set relatively low and that of interface states of the second body part B2 in which drain current does not flow is set relatively high. Since the drain current also flows to the upper portion B2U of the second body part B2, the area density of interface states of the upper portion B2U is preferably set low.

To relatively increase the interface states of the lower portion B2L of the second body part B2, an oxide film is used as the first gate dielectric film GI and a nitride film or a compound film of an oxide film and a nitride film is used as the second gate dielectric film GI2. Alternatively, the first body part B1 and the upper portion B2U of the second body part B2 are made of silicon and the lower portion B2L of the second body part B2 is made of silicon germanium SiGe. An oxide film, for example, is formed as the common gate dielectric film GI on the first body part B1 and the surface of the upper portion B2U of the second body part B2.

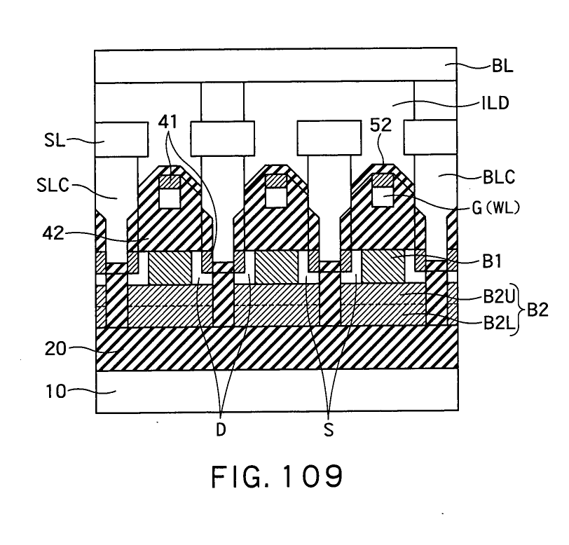

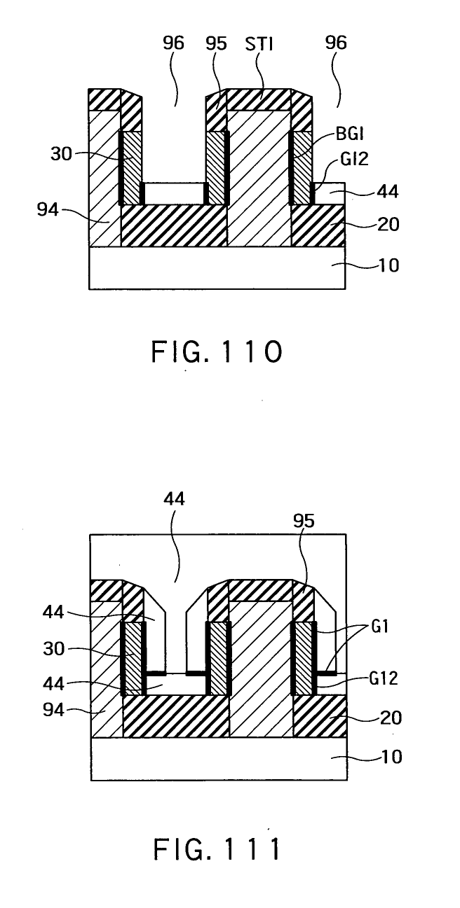

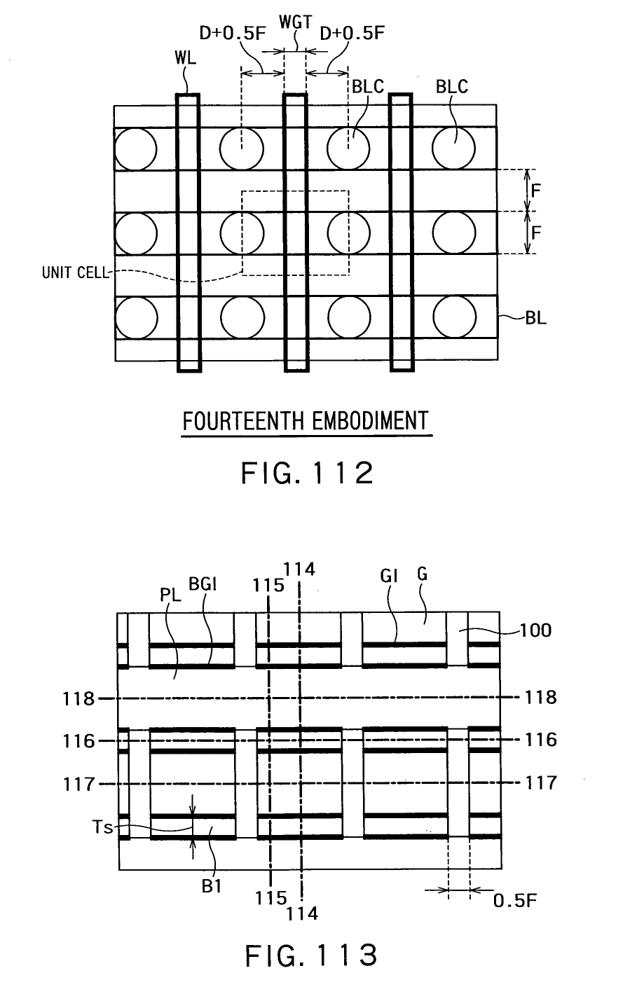

A method of manufacturing the FBC memory device configured as shown in FIGS. 107 to 109 according to the modification of the thirteenth embodiment is described. By executing similar steps to those according to the twelfth embodiment, a structure shown in FIG. 99 is obtained. FIGS. 110 and 111 are cross-sectional views corresponding to FIG. 109. As shown in FIG. 110, the second gate dielectric film GI2 that is the compound film of an oxide film and a nitride film is deposited. After depositing N polysilicon 44, the N polysilicon 44 is etched back. An upper portion of the second gate dielectric film GI2 is removed by etching. As shown in FIG. 111, after forming the gate dielectric film GI by thermal oxidation, the N polysilicon 44 is formed on the sidewall of the SOI layer 30. After removing the gate dielectric film GI in central portions of the trenches 96, the N polysilicon is deposited again. Thereafter, the steps described with reference to FIGS. 100 to 106 are executed.

### Fourteenth Embodiment

A fourteenth embodiment of the present invention differs from all the preceding embodiments in that drain current flows in perpendicular direction. Since an FBC memory device according to the fourteenth embodiment can be manufactured using a bulk substrate, manufacturing cost is reduced.

FIG. 112 is a schematic diagram showing arrangement of wirings of memory cells MCs according to the fourteenth embodiment. FIG. 113 is a plan view of the bodies B. As shown in FIG. 112, there is no need to provide source lines SLs differently from the preceding embodiment. As shown in FIG. 113, the adjacent bodies B are isolated by the insulating film 100 at a width of 0.5 F in the column direction. Each gate electrode G is located so that the gate electrode G exactly overlaps and is aligned to the body B from the top view. The adjacent gate electrodes G are isolated from each other by a width 0.5 F. As described later, isolation regions for the bodies B and isolation regions for the gates G are formed at the same anisotropic etching step. A side surface of the body B oriented in the extension direction of the gate electrode faces the gate electrode G. As shown in FIG. 52 and FIG. 93, the sixth embodiment and the twelfth embodiment have a similar structure to the above mentioned structure. By forming the structure, even if the cell size is small, an area in which one body B faces one gate electrode G can be efficiently increased.

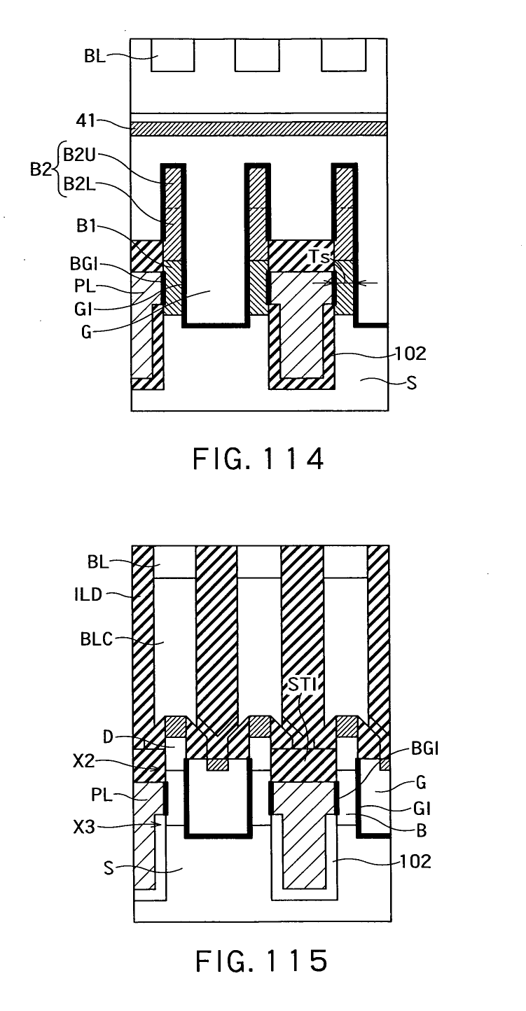

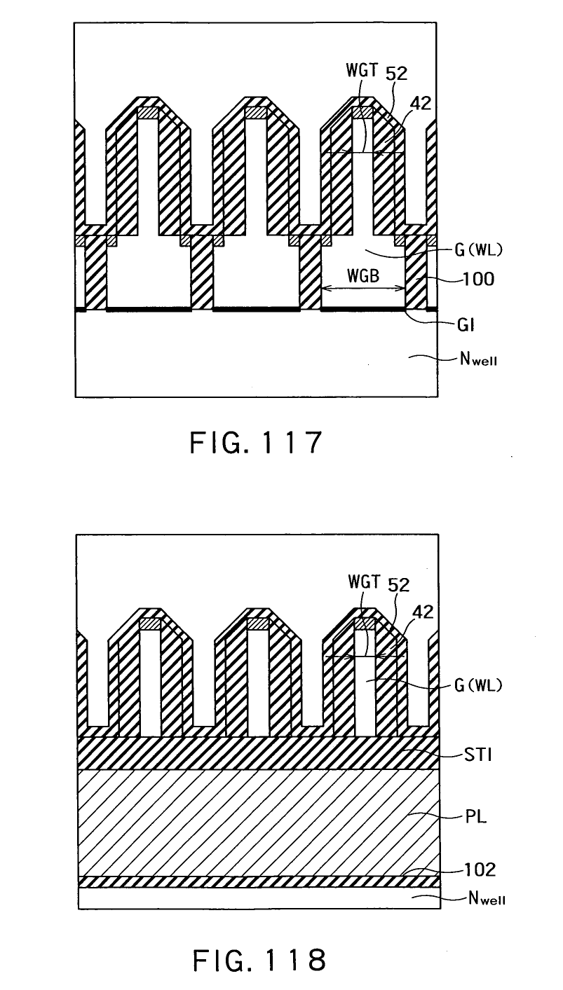

FIGS. 114 to 118 are cross-sectional views taken along lines 114-114, 115-115, 116-116, 117-117, and 118-118 of FIG. 113, respectively. With reference to FIG. 114, similarly to the seventh and eighth embodiments, in the cross section along one word line WL, the second body part B2 extends upward from the first body part B1. The gate electrode G faces the first side surface of the first body part B1 oriented in a word line direction.

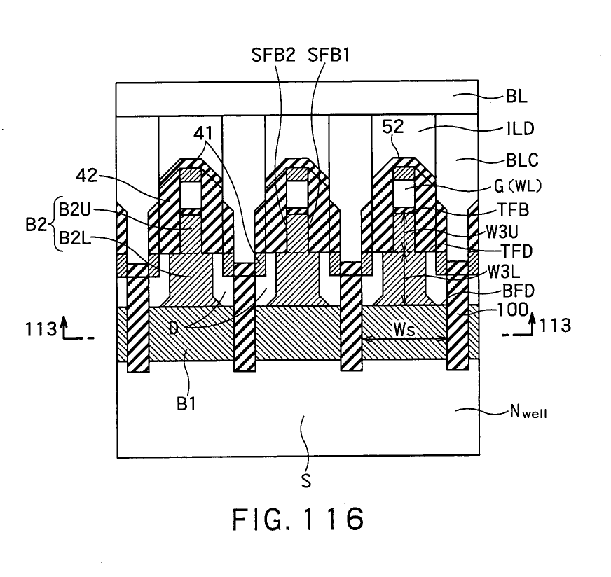

The plate PL faces the second side surface of the first body part B1 oriented in the word line direction. The gate electrode G faces two side surfaces of the second body part B2 oriented in the word line direction. With reference to FIG. 116, the first body part B1 is a region interposed between a source S and drain D. The lower portion of the second body part B2L is a region connected to the top surface of the first body part B1, and extended from the height of the bottom surface of the drain BFD. The lower portion of the second body part B2L is interposed between two drains D. By increasing the height W3L of the top surface of the lower portion of the second body part B2L with reference to the bottom surface of the drain BFD, the ratio Cb (WL)/Cb (total) can be increased, though an area of a pn-junction between the body and the drain is increased. The upper portion of the second body part B2U is a region connected to the top surface of the upper portion of the second body part B2U, and extended upward from the height of the top surface of the drain TFD. The upper portion of the second body part B2U has the two side surfaces SFB1 and SFB2 in the column direction and the two side surfaces SFB1 and SFB2 do not form pn junctions with the source S or the drain D. By increasing the height W3U of the top surface of the upper portion of the second body part B2U with reference to the top surface of the drain TFD, the ratio Cb (WL)/Cb (total) can be increased similarly to the seventh and eighth embodiments. Formation of the upper portion of the second body part B2U can be omitted.

As shown in FIGS. 115 to 116, a common source is formed on the substrate 10. Drains D are formed in an upper portion of the semiconductor layer. Namely, the drains D are formed so that the direction from the source S to the drains D is the perpendicular direction to the surface of the substrate 10. A current between the source S and one drain D flows in a longitudinal direction of the surface of the substrate 10. In case of a planar memory cell of such a type as to form a channel on the upper surface of the semiconductor layer, gate length is smaller if the cell size is smaller. In case of a Fin memory cell of such a type that a channel is formed on the side surface of the semiconductor layer and that a current between the source S and the drain D flows horizontally, gate length is smaller if the cell size is smaller. If the gate length is reduced, an area in which holes are accumulated is reduced and signal difference is, therefore, reduced.

In this respect, in the fourteenth embodiment, even if the cell size is reduced, the distance between the source S and the drain D can be kept. It is, therefore, possible to prevent a signal difference from being reduced by the reduction in gate length.

As shown in FIGS. 114, 115, and 118, the plate PL is buried in element isolation regions and electrically isolated from the word lines WLs and the substrate (N well). The plate PL extends to outside of the cell array and a voltage is applied to the plate PL outside of the cell array.

As shown in FIG. 115, a junction X2 between the drain D and the body B is located at a higher position than that of the top surface of the plate PL. Namely, the junction X2 does not face the plate PL. The conventional vertical FBC has problems that the electric field on the junction X2 is increased by a high negative voltage applied to the plate PL and leakage current increases in the data retention state. According to the fourteenth embodiment, even if a high negative voltage is applied to the plate PL and holes are accumulated in the body B of each memory cell MC, the influence of the plate voltage on the electric field of the junction X2 is small and the leakage current is small in amount in the data retention state. Furthermore, since an insulating film 102 thicker than the back gate dielectric film BGI is formed between the plate PL and a junction X3, the influence of the plate voltage on the junction is small. Therefore, each of the memory cells MCs of the FBC memory device according to the fourteenth embodiment has long data retention time.

The interface IF1 between the gate dielectric film GI and the first body part B1 and the interface IF2L between the gate dielectric film GI and the lower portion B2L of the second body part B2 are lower than the interface between the gate dielectric film GI and the upper portion B2U of the second body part B2 in the area density of interface states. To relatively increase the interface states of the upper portion B2U of the second body part B2, the upper portion B2U of the second body part B2 is made of silicon germanium SiGe. If the silicon germanium SiGe is used for the upper portion B2U of the second body part B2, an autonomous refresh operation can be performed while suppressing deterioration in carrier mobility in the channel in which drain current flows. Furthermore, since the silicon germanium layer is formed to be away from the pn junctions, junction leakage current is small in amount in the data retention state.

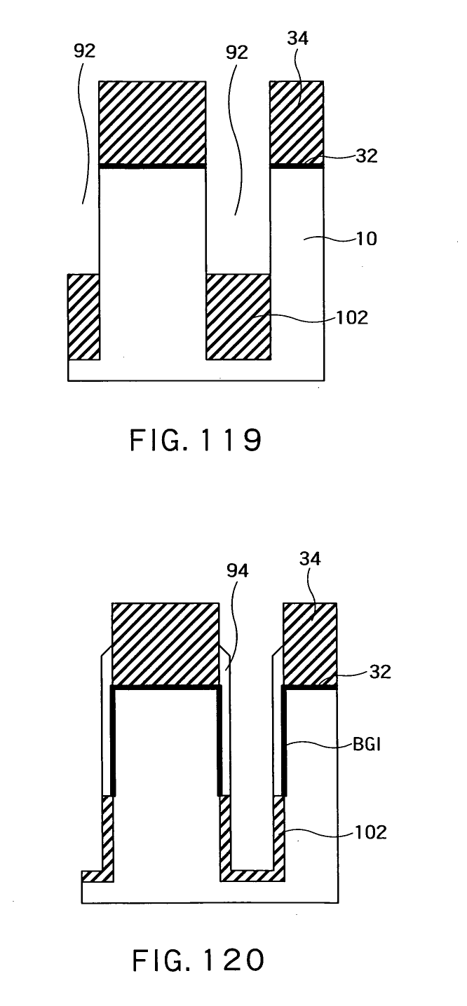

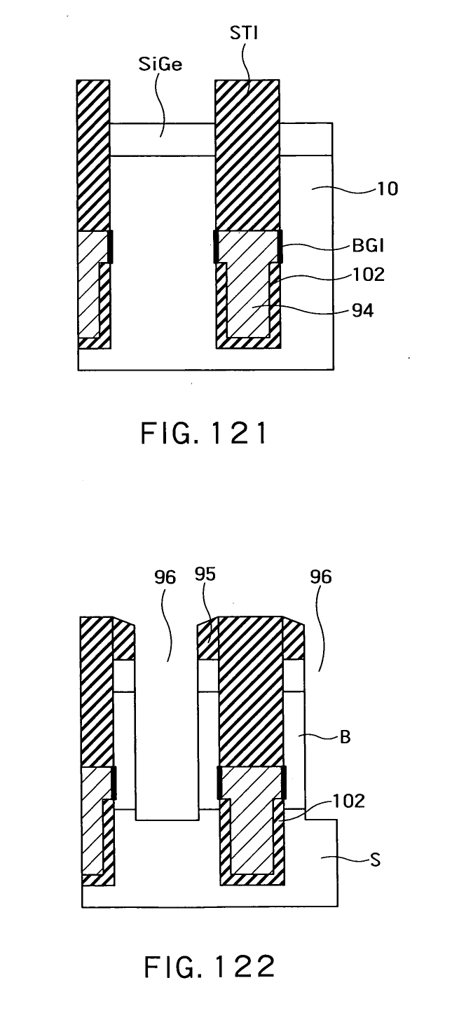

A method of manufacturing the FBC memory device according to the fourteenth embodiment is described. FIGS. 119 to 122 are cross-sectional views corresponding to FIG. 114. First, as shown in FIG. 119, a mask material made of the oxide film 32 and the SiN mask 34 is deposited on the substrate 10 and the mask material and the silicon layer 10 in plate formation regions are anisotropically etched to form trenches 92. An HDP 101 is buried in a lower portion of each trench 92.

As shown in FIG. 120, the back gate dielectric film BGI is formed on one surface (first side surface) of the silicon layer 10 by thermal oxidation. The N polysilicon 94 so thin as not to fill the trenches 92 with the N polysilicon 94 is deposited and then anisotropically etched. The HDP 102 is anisotropically etched.

Similarly to the seventh embodiment, the step of depositing the N polysilicon 94 to fill up in the trenches 92, the step of etching back the N polysilicon 94 so that the top surface of the N polysilicon 94 is lower in height than the top surface of the silicon layer 10, the step of filling up the STI material on the N polysilicon 94 in the trenches 92, the step of flattening the STI material by CMP, the step of removing the SiN mask 34 using a hot phosphoric acid solution, and the step of removing the silicon oxide film 32 are executed. Next, as shown in FIG. 21, the silicon germanium layer SiGE is deposited on the silicon layer 10 by selective epitaxial growth.

As shown in FIG. 122, the SiN spacer 95 is formed. Using the SiN spacer 95 and the STI material as a mask, the silicon layer 10 is anisotropically etched, thereby forming trenches 96. P-impurity ions are implanted into the bodies B by oblique ion implantation. Further, N-impurity ions are implanted into the substrate 10 by vertical ion implantation. An N well and the source S are thereby formed.

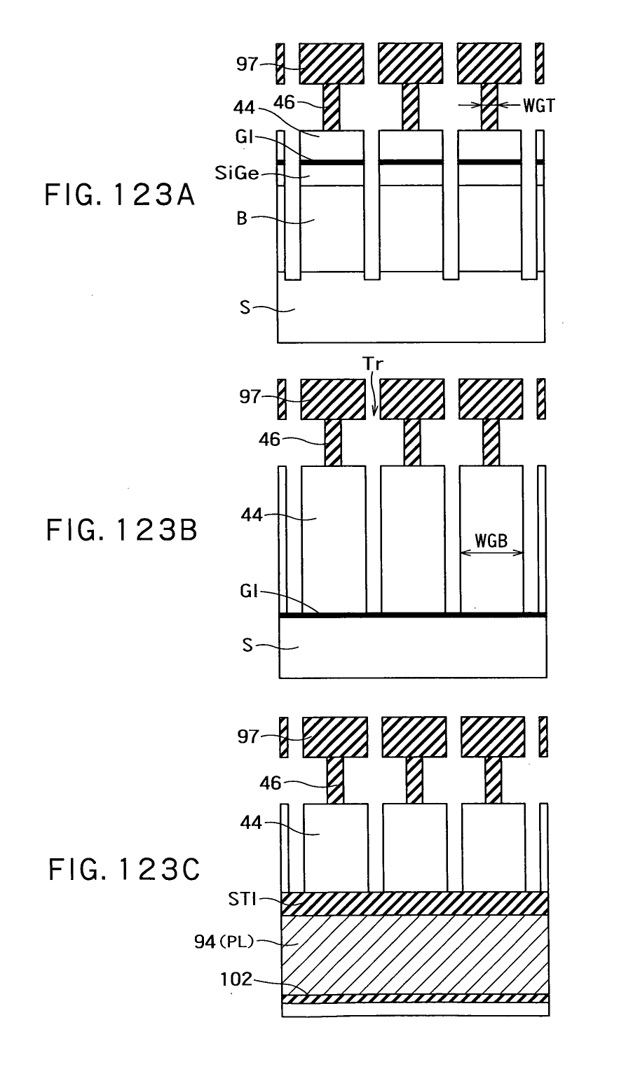

Similarly to the thirteenth embodiment, the step of forming the gate dielectric film GI, the step of depositing the N polysilicon 44, the SiN cap 46, and the silicon oxide film (SiO₂) layer 97, the step of forming the amorphous silicon layer 98 and the amorphous silicon spacer 99, and the step of forming the SiN cap 46 having the width of WGT using the amorphous silicon layer 98 and the amorphous silicon spacer 99 are executed. FIGS. 123A to 123C are cross-sectional views corresponding to FIGS. 116 to 118, respectively and showing manufacturing steps. As shown in FIGS. 123A to 123C, the gate electrode G and the silicon layer 10 are etched using the silicon oxide film layer 97 as a mask. The memory cells MCs adjacent in the column direction are isolated by the trenches Tr. Each of the gate electrodes G has the width of WBG in the column direction.

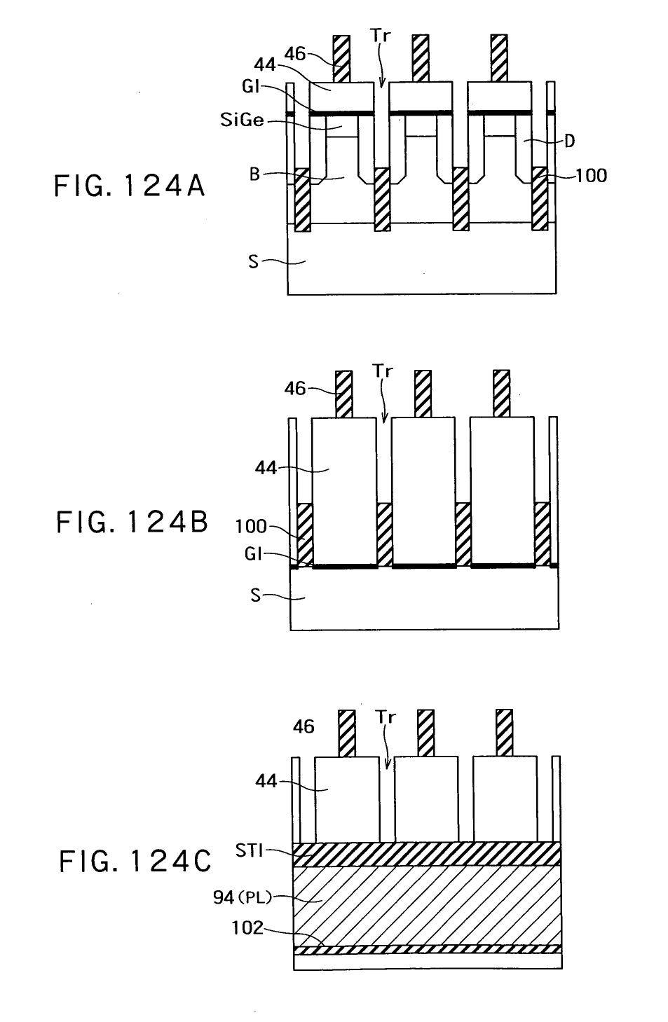

FIGS. 124A to 124C are cross-sectional views subsequent to FIGS. 123A to 123C, respectively. As shown in FIGS. 124A to 124C, the HDP 100 is deposited and then etched back, thereby filling the trenches Tr with the HDP 100. N-impurities are introduced into the silicon layer 10 by plasma doping, thereby forming the drains D.

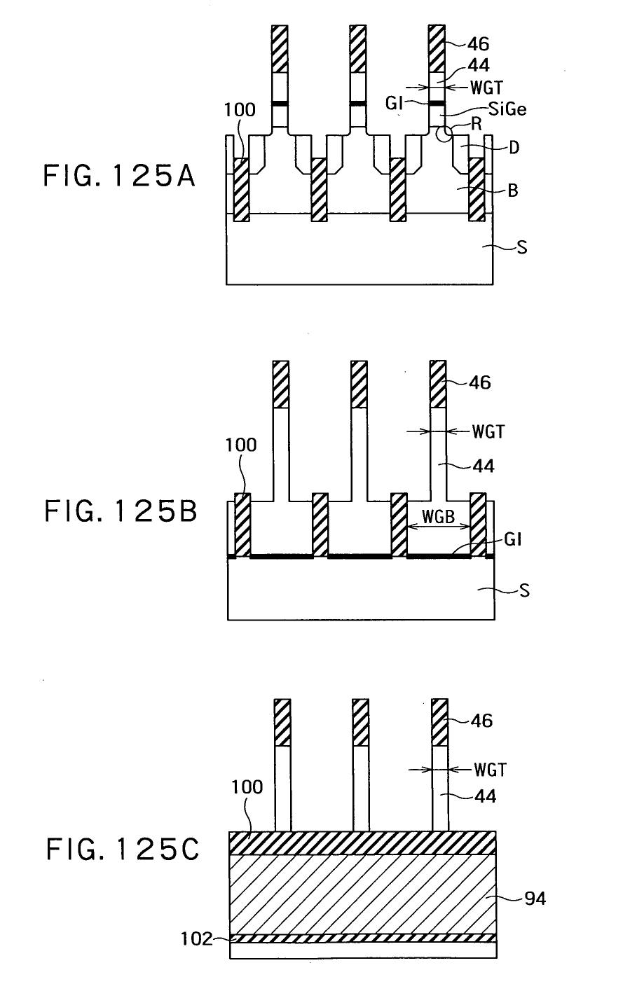

FIGS. 125A to 125C are cross-sectional views subsequent to FIGS. 124A to 124C, respectively. As shown in FIGS. 125A to 125C, the N polysilicon 144, the gate dielectric film GI, and the silicon germanium layer SiGe are etched using the SiN mask 46 as a mask and the semiconductor layer 10 is etched halfway. As a result, the second body parts B2 are formed in a self-aligned fashion with the upper portion of the gate electrodes G. At this time, if an angle of a connected portion R in which each second body part B2 is connected to each first body part B1 is right angle, the electric field can be possibly high in the connected portion in the data retention state. It is, therefore, preferable to form the connected portion R between the second body part B2 and the first body part B1 to have obtuse angle or to be rounded. Further, as shown in FIG. 125B, inverted-T-shaped gate electrodes G are formed concurrently. The width of the upper portion of each gate electrode G in the column direction is WGT and that of the lower portion thereof in the column direction is WGB (>WGT).

Thereafter, similarly to the third embodiment, the SiN spacer 42 is formed and the silicide 41 is formed on the gate electrodes G, the source S, and the drains D. Moreover, after the interlayer dielectric film ILD is deposited, the source line contacts SLCs, the bit line contacts BLCs, the source lines SLs, and the bit lines BLs are formed. As a result, the FBC memory device according to the fourteenth embodiment is completed.

### Fifteenth Embodiment

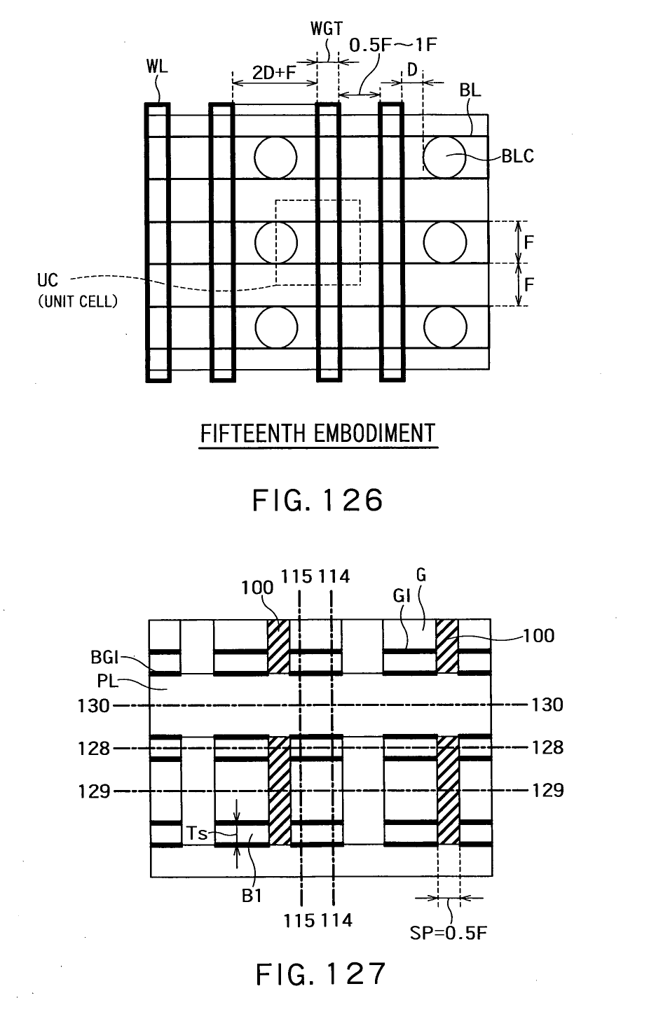

An FBC memory device according to a fifteenth embodiment of the present invention differs from that according to the fourteenth embodiment in that one bit line contact BLC corresponds to the two adjacent memory cells MCs. FIG. 126 is a schematic diagram showing arrangement of wirings of memory cells MCs according to the fifteenth embodiment. FIG. 127 is a plan view of the bodies B. As shown in FIG. 126, one bit line contact BLC corresponds to the two adjacent word lines WLs. The width WGT of each word line WL in the column direction is smaller than F. This is because the width WGT is defined by the thickness of a sidewall spacer as will be described later. Therefore, the cell size of each of the memory cells MCs of the FBC memory device according to the fifteenth embodiment can be easily reduced.

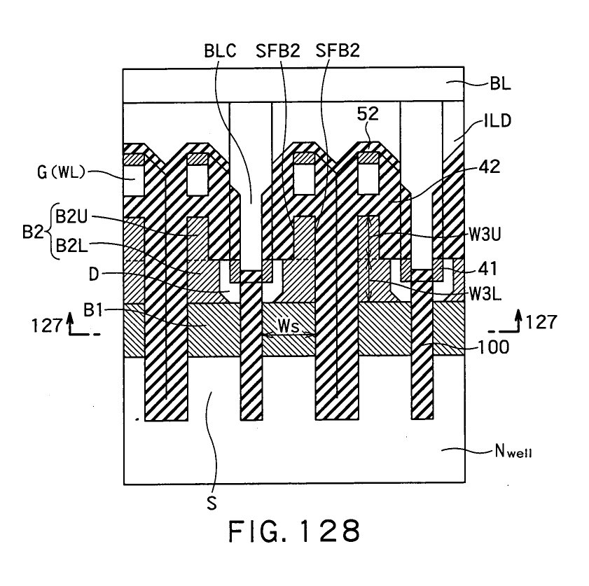

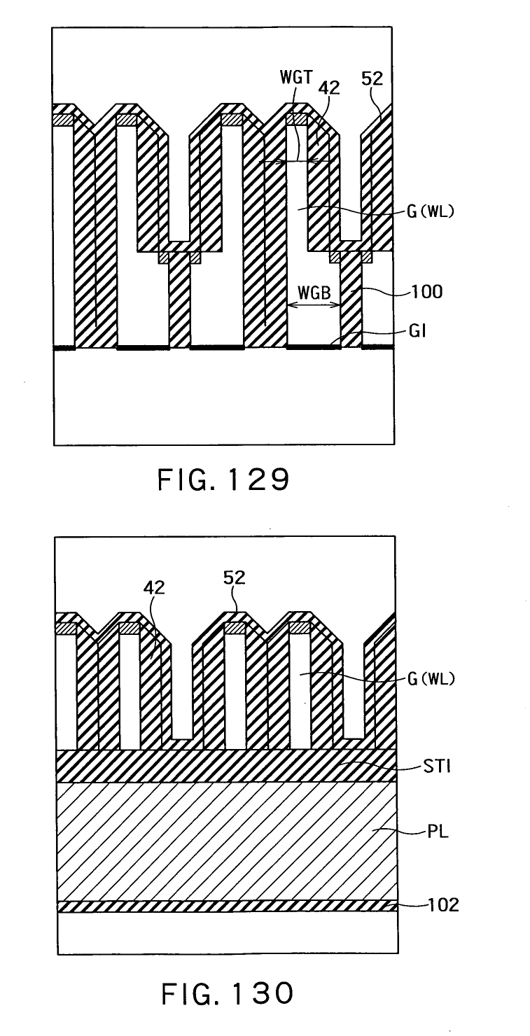

FIGS. 128, 129, and 130 are cross-sectional views taken along lines 128-128, 129-129, and 130-130 of FIG. 127, respectively. As shown in FIG. 129, each gate electrode G is L shaped, the width of the upper portion of the gate electrode G in the column direction is WGT, and the width of the lower portion thereof in the column direction is WGB. The memory cells MCs of the FBC memory device according to the fifteenth embodiment exhibit the same advantages as those according to the fourteenth embodiment.

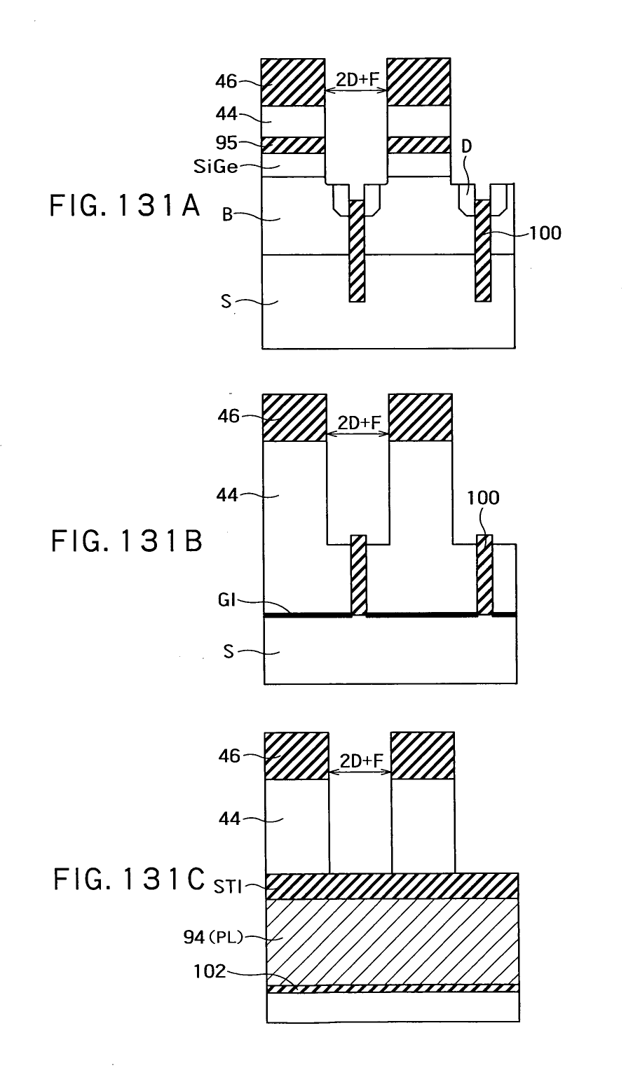

A method of manufacturing the FBC memory device according to the fifteenth embodiment is described. The inverted-T-shaped gate electrodes G are formed by the step described in the fourteenth embodiment with reference to FIG. 125. FIGS. 131A to 131C are cross-sectional views corresponding to FIGS. 128, 129, and 130, respectively. At this stage, one inverted T-shaped gate electrode G is formed to be common to two memory cells MCs.

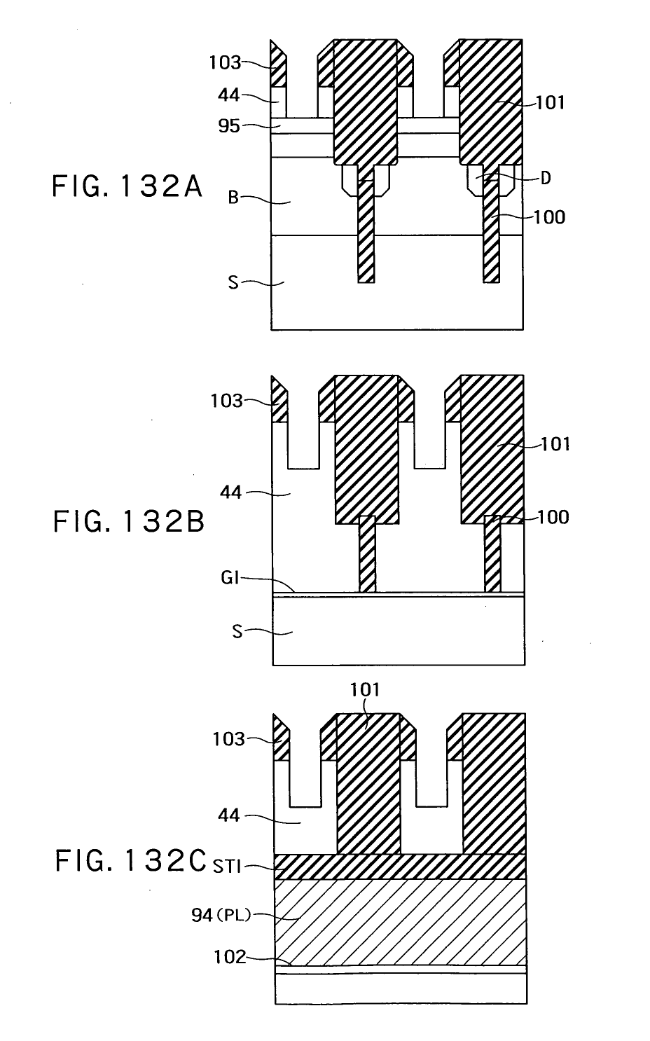

FIGS. 132A to 132C are cross-sectional views continuous to FIGS. 131A to 131C, respectively. As shown in FIGS. 132A to 132C, the HDP 101 is deposited and flattened by CMP, thereby filling the trenches Tr with the HDP 101. The SiN mask 46 is removed by a hot phosphoric acid solution. SiN 103 is deposited and then anisotropically etched, thereby forming an SiN cap 103 on a sidewall of the HDP 101. The thickness of the SiN cap 103 defines the width WGT of one word line WL. Therefore, word lines WLs the width of each of which is smaller than a minimum size of a resist by lithography. Using the SiN cap 103 and the HDP 101 as a mask, the N polysilicon 44 is anisotropically etched halfway.

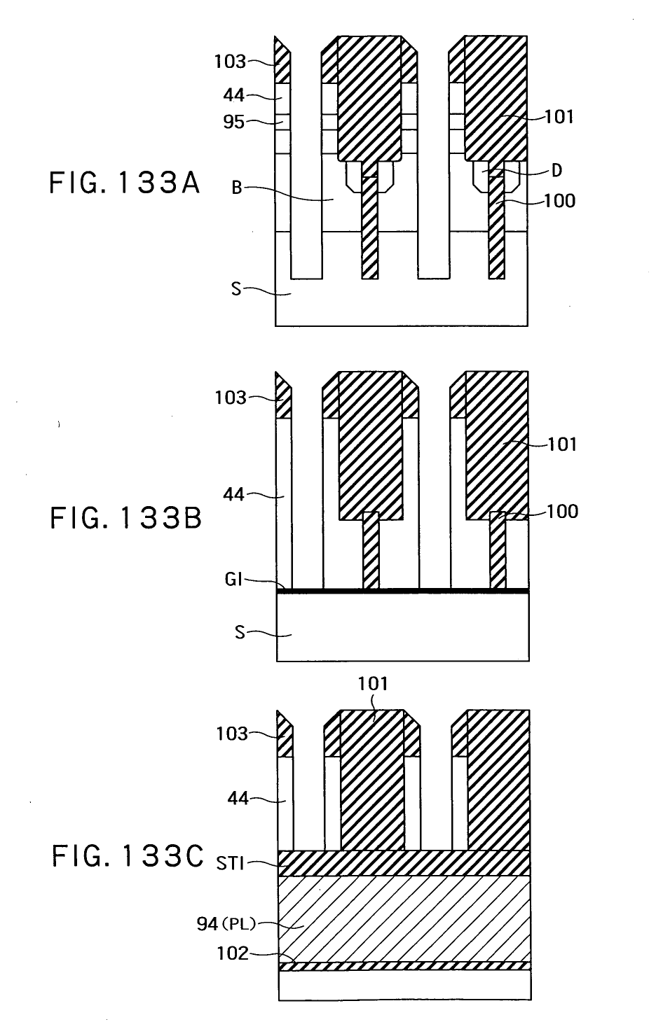

As shown in FIGS. 133A to 133C, using the SiN cap 103 and the HDP 101 as a mask, the SiN spacer 95, the silicon layer 10, and the N polysilicon 44 are anisotropically etched simultaneously. As a result, as shown in FIG. 133B, the gate electrodes G are isolated to correspond to the memory cells MCs. As shown in FIG. 133A, the P bodies B are isolated to correspond to the memory cells MCs.

Thereafter, similarly to the third embodiment, the SiN spacer 42 is formed and the silicide 41 is formed on the gate electrodes G, the source S, and the drains D. Moreover, after the interlayer dielectric film ILD is deposited, the source line contacts SLCs, the bit line contacts BLCs, the source lines SLs, and the bit lines BLs are formed. As a result, the FBC memory device according to the fifteenth embodiment is completed.

### Modification of Fifteenth Embodiment

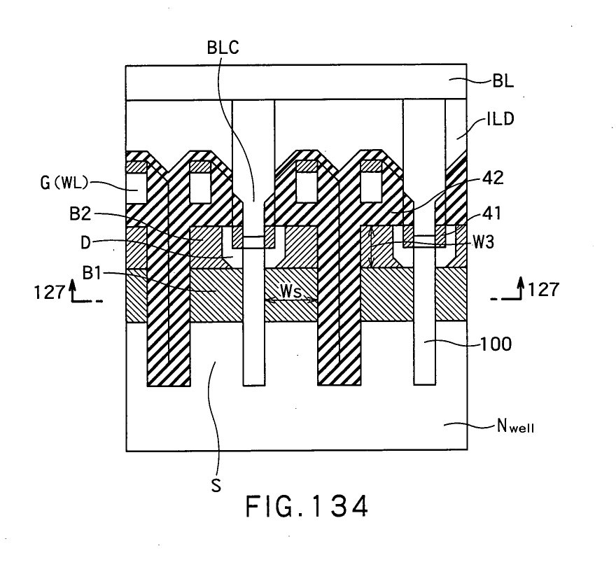

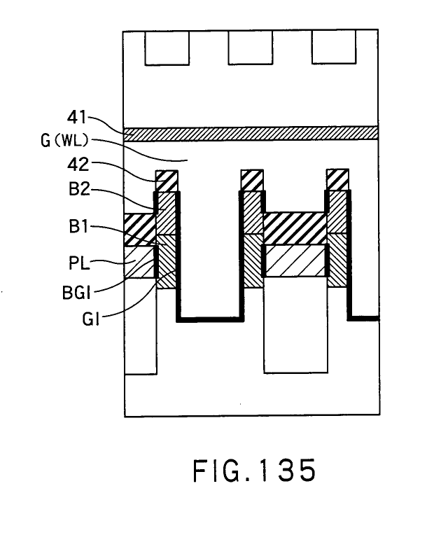

FIGS. 134 and 135 are cross-sectional views showing a configuration of an FBC memory device according to a modification of the fifteenth embodiment. In the modification of the fifteenth embodiment, the upper portion B2U of each second body part B2 is not provided and only the portion corresponding to the lower portion B2L of the second body part B2 is provided as the second body part B2. Other constituent elements of the FBC memory device according to the modification of the fifteenth embodiment can be configured similarly to those according to the fifteenth embodiment. This modification can exhibit the same advantages as those of the fifteenth embodiment.

1. A method of driving a semiconductor memory device, the semiconductor memory device including a plurality of memory cells including sources, drains, and floating bodies in an electrically floating state, the memory cells storing logic data according to number of carriers accumulated in the floating body; a plurality of bit lines connected to the drains; a plurality of word lines intersecting the bit lines and serving as gates; a plurality of source lines intersecting the bit lines and connected to the sources, each of the source lines being shared by two cells adjacent along the bit line direction; and a sense amplifier reading data stored in a selected memory cell connected to a selected bit line among the plurality of bit lines and connected to a selected word line among the plurality of word lines, or the sense amplifier writing data to the selected memory cell, the method comprising:
executing, during a data write operation, a first cycle of applying a first potential to the bit lines corresponding to the first selected memory cells and of applying a second potential to the selected word line so as to write first logic data indicating that the number of the carriers Is large to the first selected memory cells;
executing, during the data write operation, a second cycle of applying a third potential to the bit lines corresponding to a second selected memory cell selected by the bit lines among the first selected memory cells and of applying a fourth potential to the selected word line so as to write second logic data indicating that the number of the carriers is small to the second selected memory cell, the second cycle being carried out after the first cycle, characterized in that
in the first cycle, the second potential is a potential biased to a polarity opposite to the polarity of the carriers with reference to a potential of the source and a potential of the first potential,
in the second cycle, the fourth potential is a potential biased to same polarity as the polarity of the carriers with reference to the potential of the source and the potential of the third potential, and
the potential of the source being closer to the second potential than the first potential, or the potential of the source being equal to the first potential.

2. The method of driving a semiconductor memory device according to claim 1, wherein
in the second cycle, a fifth potential is applied to the bit lines corresponding to the first selected memory cells other than the second selected memory cell, and
in the second cycle, the third potential is a potential biased to the polarity opposite to the polarity of the carriers with reference to the potential of the source, and the fifth potential is a potential closer to the potential of the source than the third potential.

3. The method of driving a semiconductor memory device according to claim 1, wherein
the semiconductor memory device further includes a plate provided to be common to the plurality of memory cells,
a potential of the source, a potential of the bit lines, a potential of the word lines, and a potential of the plate in a data retention state are biased to a polarity opposite to the polarity of the carriers with reference to the potential of the source in a data write operation and a data read operation, and
among the potential of the source, the potential of the bit lines, the potential of the word lines, and the potential of the plate in the data retention state, the potential of the plate is a potential furthest from the potential of the source in the data write operation and the data read operation, and the potential of the word lines is second furthest from the potential of the source in the data write operation and the data read operation.

4. A semiconductor memory device comprising:
a supporting substrate;
a semiconductor layer provided above the supporting substrate;
a source layer provided in the semiconductor layer;
a drain layer provided in the semiconductor layer;
a body including a first body part provided in the semiconductor layer between the source layer and the drain layer, the body being in an electrically floating state and accumulating or emitting charges to store logic data;
a first gate electrode coupled to the first body part through a first gate dielectric film, characterized in that
the body further includes a second body part,
a second gate dielectric film is provided on a side surface of the second body part,
a second gate electrode is provided on the second gate dielectric film, the second gate electrode being connected to the first gate electrode,
the second body part extends from the first body part in a direction perpendicular to the surface of the supporting substrate, and
a side surface of the second body part does not form a pn-junction with the source layer and the drain layer.

5. The semiconductor memory device according to claim 4 further comprising:
a back gate dielectric film provided between a top surface of the supporting substrate and a bottom surface of the semiconductor layer, wherein
the first gate electrode is coupled to a top surface of the first body part; and
the second body part is fully-depleted when a voltage is applied to the second gate electrode to read logic data.

6. The semiconductor memory device according to claim 4, wherein
the first gate electrode is coupled to a first side surface of the first body part: and the second body part is fully-depleted when a voltage is applied to the second gate electrode to read logic data, the memory device further comprising:
a back gate dielectric film provided on a second side surface of the first body part opposite to the first side surface;
a plate provided so as to face the back gate dielectric film.

7. (canceled)

8. The semiconductor memory device according to claim 4, wherein
two side surfaces of the second body part, which side surfaces are directed toward an extending direction of the gate electrode, face the second gate electrode via the second gate dielectric film.

9. The semiconductor memory device according to claim 4, wherein
a plurality of memory cells each including the source layer, the drain layer, and the body are arranged,
the memory cells arranged in a first direction are isolated from one another in the source layer and the drain layer, the first direction being a direction from the source layer to the drain layer,
two source layers of two memory cells among the memory cells adjacent to each other in the first direction are connected to each other by a first contact formed into an elliptic shape having a major axis in the first direction, and
two drain layers of two memory cells among the memory cells adjacent to each other in the first direction are connected to each other by a second contact formed into an elliptic shape having a major axis in the first direction.

10. The semiconductor memory device according to claim 6, wherein
a facing area of the second gate electrode with the second body part is larger than a facing area of the plate with the second body part.

11. The semiconductor memory device according to claim 6, wherein
a width of the first gate electrode facing the first body part in a first direction from the source layer to the drain layer is equal to a width of the first body part in the first direction,
the width of the first gate electrode is larger than a width of the plate in the first direction.

12. The semiconductor memory device according to claim 4, wherein
the second gate dielectric film is a nitride film or a compound film including an oxide film and the nitride film.

13. The semiconductor memory device according to claim 4, wherein the first gate dielectric film is formed on the side surface of the first body part and the second gate dielectric film is formed on the side surface of the second body part, and an interface between the side surface of the first body part and the first gate dielectric film is lower in a density of interface states than an interface between the side surface of the second body part and the second gate dielectric film.

14. The semiconductor memory device according to claim 6, wherein the drain layer and the source layer are connected to an upper part and a lower part of the body extending in a direction perpendicular to a surface of the semiconductor substrate.

15. The semiconductor memory device according to claim 4, wherein the second body part is higher in impurity concentration than the first body part.

16. A semiconductor memory device comprising:
a semiconductor substrate;
a semiconductor layer provided above the semiconductor substrate;
a source layer provided in the semiconductor layer;
a drain layer provided in the semiconductor layer;
a body including a first body part provided in the semiconductor layer between the source layer and the drain layer and a second body part extending from the first body part in a direction perpendicular to a surface of the semiconductor substrate, the body being in an electrically floating state and accumulating or emitting charges to store logic data
a gate dielectric film provided on a first side surface of the body part;
a gate electrode provided to face the gate dielectric film;
a plurality of memory cells each including the gate electrode, the source layer, the drain layer, and the body; a plurality of bit lines extending in a first direction; and
a plurality of isolations put between two semiconductor layers adjacent to each other in the first direction, wherein;
characterized in that
the gate electrode includes a lower gate electrode part and an upper gate electrode part provided over the lower gate electrode part, and
a distance between two isolations adjacent to each other in the first direction is equal to a width of the lower gate electrode part in the first direction.

17. The semiconductor memory device according to claim 16 further comprising:
a back gate dielectric film provided on a second side surface of the first body part opposite to the first side surface;
a plate provided so as to face the back gate dielectric film, wherein the second body part is fully-depleted when a voltage is applied to the gate electrode to read logic data.

18. The semiconductor memory device according to claim 16, wherein
the second body part extends downward of the first body part, and
a width of the second body part in the first direction is equal to the width of the lower gate electrode part in the first direction, the lower gate electrode part facing the second body part.

19. The semiconductor memory device according to claim 16, wherein the drain layer and the source layer are connected to an upper portion and a lower portion of the body extending in the perpendicular direction to the surface of the semiconductor substrate, the gate electrode faces the first side surface of the body oriented in an extension direction of the gate electrode, and a width of the first body part put between the source layer and the drain layer in the first direction is equal to a width of the lower gate electrode part facing the first body part in the first direction.

20. The semiconductor memory device according to claim 16, wherein two memory cells out of the plurality of memory cells adjacent to each other in the first direction share a contact connected to the drain layer of each of the two memory cells.
